(19) United States
(12) Patent Application Publication
(10) Pub. No.: US 2015/0359105 A1
(43) Pub. Date: Dec. 10, 2015

(54) PATTERNED TRANSPARENT CONDUCTORS AND RELATED COMPOSITIONS AND MANUFACTURING METHODS

(71) Applicant: Iinnova Dynamics, Inc., San Francisco, CA (US)

(72) Inventors: Hichang Yoon, Pleasanton, CA (US); James Kundrat, San Francisco, CA (US); Andrew Loxley, San Francisco, CA (US); Arjun D. Srinivas, San Francisco, CA (US); J. Russell Renzas, San Bruno, CA (US); James W. Borchert, San Francisco, CA (US); Sheng Peng, San Mateo, CA (US); Vyankat Sindphale, San Francisco, CA (US); Ralph E. Korenbrekke, Placitas, NM (US); Christopher L. Anderson, San Francisco, CA (US)

(21) Appl. No.: 14/733,783

(22) Filed: Jun. 8, 2015

Related U.S. Application Data
(60) Provisional application No. 62/009,101, filed on Jun. 6, 2014.
(60) Provisional application No. 62/012,241, filed on Jun. 13, 2014.
(60) Provisional application No. 62/157,817, filed on May 6, 2015.

(51) Int. Cl. H05K 3/06; H05K 1/02; C09D 5/00; C09D 7/12; C09D 129/04; C09D 139/02

(52) U.S. Cl. CPC H05K 3/067; C09D 129/04; C09D 139/02; C09D 5/00; C09D 7/1233; C09D 7/125; H05K 1/0213; H05K 3/061; C08K 5/17

(57) ABSTRACT

A manufacturing method of a patterned transparent conductor includes: (1) providing a transparent conductor including nanowires formed of a metal; and (2) applying a percolation-inhibition composition to a portion of the transparent conductor to partially degrade nanowires included in the portion. The percolation-inhibition composition includes a complexing agent for the metal.

### CROSS REFERENCE TO RELATED APPLICATIONS

This application claims the benefit of U.S. Provisional Application No. 62/009,101, filed on Jun. 6, 2014, U.S. Provisional Application No. 62/012,241, filed on Jun. 13, 2014, and U.S. Provisional Application No. 62/157,817, filed on May 6, 2015, the disclosures of which are incorporated herein by reference in their entirety.

### TECHNICAL FIELD

This disclosure relates generally to devices incorporating conductive structures. More particularly, this disclosure relates to patterned transparent conductors incorporating conductive structures to impart functionality such as electrical conductivity and low visibility patterning.

### BACKGROUND

A transparent conductor permits the transmission of light while providing a conductive path for an electric current to flow through a device including the transparent conductor. Traditionally, a transparent conductor is formed as a coating of a doped metal oxide, such as tin-doped indium oxide (or ITO), which is disposed on top of a glass or plastic substrate. ITO coatings are typically formed through the use of a dry process, such as through the use of specialized physical vapor deposition (e.g., sputtering) or specialized chemical vapor deposition techniques. The resulting coating can exhibit good electrical conductivity. However, drawbacks to techniques for forming ITO coatings include high cost, high process complexity, intensive energy requirements, high capital expenditures for equipment, and poor productivity.

For some applications, patterning of a transparent conductor is desirable to form conductive traces and insulating gaps between the traces. In the case of ITO coatings, patterning is typically accomplished via photolithography. However, removing material via photolithography and related masking and etching processes further exacerbates the process complexity, the energy requirements, the capital expenditures, and the poor productivity for patterning ITO-based transparent conductors. Also, low visibility of patterned transparent conductors is desirable for certain applications, such as touch screens. Conventional patterning techniques for ITO coatings typically result in patterns that are visible to the eye, which can be undesirable for those applications.

It is against this background that a need arose to develop the transparent conductors and related compositions and manufacturing methods described herein.

### SUMMARY

In some embodiments, a manufacturing method of a patterned transparent conductor includes: (1) providing a transparent conductor including nanowires formed of a metal; and (2) applying a percolation-inhibition composition to a portion of the transparent conductor to partially degrade nanowires included in the portion. The percolation-inhibition composition includes a complexing agent for the metal.

In additional embodiments, a percolation-inhibition composition is configured for application to conductive structures formed of a metal, and includes: (1) a complexing agent for the metal; (2) a polymer binder; and (3) a solvent. The complexing agent has the formula:

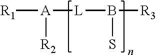

where R₁, R₂, R₃, and S are independently selected from hydride groups, alkyl groups, alkenyl groups, alkynyl groups, aryl groups, poly(alkylene oxide) groups, siloxane groups, and polysiloxane groups, L is selected from alkylene groups, alkenylene groups, alkynylene groups, arylene groups, poly(alkylene oxide) groups, siloxane groups, and polysiloxane groups, A and B are independently selected from nitrogen, phosphorus, arsenic, antimony, and bismuth, and n is an integer≧0, and

where for n>1:
L in different ones of the n units can be the same or different, and are independently selected from alkylene groups, alkenylene groups, alkynylene groups, arylene groups, poly(alkylene oxide) groups, siloxane groups, and polysiloxane groups,
S in different ones of the n units can be the same or different, and are independently selected from hydride groups, alkyl groups, alkenyl groups, alkynyl groups, aryl groups, poly(alkylene oxide) groups, siloxane groups, and polysiloxane groups, and
B in different ones of the n units can be the same or different, and are independently selected from nitrogen, phosphorus, arsenic, antimony, and bismuth.

In additional embodiments, a percolation-inhibition composition is configured for application to conductive structures formed of a metal, and includes: (1) a complexing agent for the metal; (2) a reducing agent for the metal; (3) a polymer binder; and (4) a solvent.

In further embodiments, a patterned transparent conductor includes: (1) a substrate; (2) first conductive structures disposed within a first area of the substrate corresponding to a lower conductance portion; and (3) second conductive structures disposed within a second area of the substrate corresponding to a higher conductance portion. A sheet resistance of the lower conductance portion is at least 100 times a sheet resistance of the higher conductance portion, and a surface area coverage of the first conductive structures in the lower conductance portion is less than and is at least 20% of a surface area coverage of the second conductive structures in the higher conductance portion.

### BRIEF DESCRIPTION OF THE DRAWINGS

For a better understanding of the nature and objects of some embodiments of this disclosure, reference should be made to the following detailed description taken in conjunction with the accompanying drawings.

FIG. 1A and FIG. 1B illustrate examples of transparent conductors implemented in accordance with embodiments of this disclosure.

FIG. 1C illustrates an additional example of a transparent conductor implemented in accordance with an embodiment of this disclosure.

FIG. 2A and FIG. 2B illustrate examples of manufacturing methods for surface embedding structures into dry compositions, according to embodiments of this disclosure.

FIG. 2C illustrates a manufacturing method for surface embedding structures into a wet composition, according to an embodiment of this disclosure.

FIG. 2D illustrates a manufacturing method for incorporating structures into a wet composition, according to an embodiment of this disclosure.

FIG. 3 illustrates an example of modeling a cleaving mechanism for nanowires, according to an embodiment of this disclosure.

FIG. 4 illustrates an example schematic of metallic nanowires subjected to a chopping or cleaving mechanism or action, according to an embodiment of this disclosure.

FIG. 5 illustrates another example schematic of metallic nanowires subjected to a chopping or cleaving mechanism or action, according to an embodiment of this disclosure.

FIG. 6 illustrates another example schematic of metallic nanowires subjected to a chopping or cleaving mechanism or action, according to an embodiment of this disclosure.

FIG. 7A, FIG. 7B, FIG. 7C, FIG. 8A, FIG. 8B, FIG. 8C, FIG. 9A, FIG. 9B, and FIG. 9C illustrate manufacturing methods of patterned transparent conductors, according to embodiments of this disclosure.

FIG. 10A, FIG. 10B, FIG. 10C, FIG. 11A, FIG. 11B, FIG. 11C, FIG. 12A, FIG. 12B, FIG. 12C, FIG. 13A, FIG. 13B, FIG. 13C, FIG. 14A, FIG. 14B, and FIG. 14C illustrate manufacturing methods of patterned transparent conductors, according to embodiments of this disclosure.

FIG. 15 illustrates an example of a projected capacitive touch sensor device according to an embodiment of this disclosure.

FIG. 16 is a scanning electron microscopy (or SEM) image of a network of silver nanowires embedded in a substrate, without or prior to application of an electrical conductivity modifying agent, according to an embodiment of this disclosure.

FIG. 17 is a SEM image of a silver nanowire-embedded substrate subsequent to application of hydrogen peroxide, according to an embodiment of this disclosure.

FIG. 18 is a SEM image of a silver nanowire-embedded substrate subsequent to application of ammonia, according to an embodiment of this disclosure.

FIG. 19 is a SEM image of a silver nanowire-embedded substrate subsequent to application of polyethylenimine, according to an embodiment of this disclosure.

FIG. 20 is a SEM image of a silver nanowire-embedded substrate subsequent to application of bis(hexamethylene)triamine, according to an embodiment of this disclosure.

FIG. 21A is a SEM image of a substrate embedded with silver nanowires containing about 0.6 wt. % of silver chloride, subsequent to application of bis(hexamethylene)triamine, and FIG. 21B is a SEM image of a substrate embedded with silver nanowires containing about 3.41 wt. % of silver chloride, subsequent to application of bis(hexamethylene)triamine, according to an embodiment of this disclosure.

FIG. 22 (top panel) is a SEM image of silver nanowires treated with 100 vol. % diethylenetriamine (or DETA), and FIG. 22 (bottom panel) is a SEM image of silver nanowires treated with 50 vol. % DETA in isopropyl alcohol (or IPA), according to an embodiment of this disclosure.

FIG. 23 is a SEM image of silver nanowires treated with octylamine, according to an embodiment of this disclosure.

FIG. 24 is a SEM image of silver nanowires treated with decylamine, according to an embodiment of this disclosure.

FIG. 25 is a SEM image of silver nanowires treated with triethylenetetramine, according to an embodiment of this disclosure.

FIG. 26 (top panel) is a SEM image of silver nanowires treated with N-methylethylenediamine, and FIG. 26 (bottom panel) is a magnified view of the image, according to an embodiment of this disclosure.

FIG. 27 is a SEM image of silver nanowires treated with N,N′-dimethylethylenediamine, according to an embodiment of this disclosure.

FIG. 28 is a SEM image of silver nanowires treated with N,N′-diisopropylethylenediamine, according to an embodiment of this disclosure.

FIG. 29 is a SEM image of silver nanowires treated with sodium thiosulfate, according to an embodiment of this disclosure.

FIG. 30 is a SEM image of untreated silver nanowires, FIG. 31 is a SEM image of silver nanowires treated with bis(hexamethylene)triamine, and FIG. 32 is a SEM image of silver nanowires treated with sodium thiosulfate, according to an embodiment of this disclosure.

FIG. 33 sets forth results of measurements of lengths of silver nanowires in a sample of a patterned transparent conductor, according to an embodiment of this disclosure.

FIG. 34 is a SEM image of silver nanowires treated with a percolation-inhibition composition composed of about 5 wt. % of sodium thiocyanate and 0 wt. % of ascorbic acid, according to an embodiment of this disclosure.

FIG. 35 is a SEM image of silver nanowires treated with a percolation-inhibition composition composed of about 5 wt. % of sodium thiocyanate and about 0.1 wt. % of ascorbic acid, according to an embodiment of this disclosure.

FIG. 36 is a SEM image of silver nanowires treated with a percolation-inhibition composition composed of about 5 wt. % of sodium thiocyanate and about 0.5 wt. % of ascorbic acid, according to an embodiment of this disclosure.

FIG. 37 is a SEM image of silver nanowires treated with a percolation-inhibition composition composed of about 5 wt. % of sodium thiocyanate and about 1 wt. % of ascorbic acid, according to an embodiment of this disclosure.

FIG. 38 is a SEM image of silver nanowires treated with a percolation-inhibition composition composed of about 5 wt. % of sodium thiocyanate and about 5 wt. % of ascorbic acid, according to an embodiment of this disclosure.

FIG. 39 is a SEM image of silver nanowires treated with a percolation-inhibition composition composed of about 5 wt. % of sodium thiocyanate and about 10 wt. % of ascorbic acid, according to an embodiment of this disclosure.

### DETAILED DESCRIPTION

### Definitions

The following definitions apply to some of the aspects described with regard to some embodiments of this disclosure. These definitions may likewise be expanded upon herein.

As used herein, the singular terms “a,” “an,” and “the” include plural referents unless the context clearly dictates otherwise. Thus, for example, reference to an object can include multiple objects unless the context clearly dictates otherwise.

As used herein, the term “set” refers to a collection of one or more objects. Thus, for example, a set of objects can include a single object or multiple objects. Objects of a set can also be referred to as members of the set. Objects of a set can be the same or different. In some instances, objects of a set can share one or more common characteristics.

As used herein, the term “adjacent” refers to being near or adjoining. Adjacent objects can be spaced apart from one another or can be in actual or direct contact with one another. In some instances, adjacent objects can be connected to one another or can be formed integrally with one another.

As used herein, the terms “connect,” “connected,” and “connection” refer to an operational coupling or linking. Connected objects can be directly coupled to one another or can be indirectly coupled to one another, such as via another set of objects.

As used herein, the terms “substantially,” “substantial,” and “about” are used to describe and account for small variations. When used in conjunction with an event or circumstance, the terms can refer to instances in which the event or circumstance occurs precisely as well as instances in which the event or circumstance occurs to a close approximation. When used in conjunction with a numerical value, the terms can refer to less than or equal to ±10%, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%.

As used herein, the terms “optional” and “optionally” mean that the subsequently described event or circumstance may or may not occur and that the description includes instances where the event or circumstance occurs and instances in which it does not.

As used herein, relative terms, such as “inner,” “interior,” “outer,” “exterior,” “top,” “bottom,” “front,” “rear,” “back,” “upper,” “upwardly,” “lower,” “downwardly,” “vertical,” “vertically,” “lateral,” “laterally,” “above,” and “below,” refer to an orientation of a set of objects with respect to one another, such as in accordance with the drawings, but do not require a particular orientation of those objects during manufacturing or use.

As used herein, the term “nanometer range” or “nm range” refers to a range of dimensions from about 1 nanometer (“nm”) to about 1 micrometer (“nm”). The nm range includes the “lower nm range,” which refers to a range of dimensions from about 1 nm to about 10 nm, the “middle nm range,” which refers to a range of dimensions from about 10 nm to about 100 nm, and the “upper nm range,” which refers to a range of dimensions from about 100 nm to about 1 μm.

As used herein, the term “micrometer range” or “μm range” refers to a range of dimensions from about 1 μm to about 1 millimeter (“mm”). The μm range includes the “lower μm range,” which refers to a range of dimensions from about 1 μm to about 10 μm, the “middle μm range,” which refers to a range of dimensions from about 10 μm to about 100 μm, and the “upper μm range,” which refers to a range of dimensions from about 100 μm to about 1 mm.

As used herein, the term “aspect ratio” refers to a ratio of a largest dimension or extent of an object and a remaining dimension or extent of the object (or an average of remaining dimensions or extents of the object). In some instances, remaining dimensions of an object can be substantially the same, and an average of the remaining dimensions can substantially correspond to either of the remaining dimensions. In some instances, a largest dimension or extent of an object can be aligned with, or can extend along, a major axis of the object, while remaining dimensions of the object can be aligned with, or can extend along, respective minor axes of the object. For example, an aspect ratio of a cylinder refers to a ratio of a length of the cylinder and a cross-sectional diameter of the cylinder. As another example, an aspect ratio of a spheroid refers to a ratio of dimension along a major axis of the spheroid and a dimension along a minor axis of the spheroid.

As used herein, the term “nano-sized” object refers to an object that has at least one dimension in the nm range. A nano-sized object can have any of a wide variety of shapes, and can be formed of a wide variety of materials. Examples of nano-sized objects include nanowires, nanotubes, nanoplatelets, nanoparticles, and other nanostructures.

As used herein, the term “nanowire” refers to an elongated, nano-sized object that is substantially solid. Typically, a nanowire has a lateral dimension (e.g., a cross-sectional dimension in the form of a width, a diameter, or a width or diameter that represents an average across orthogonal directions) in the nm range, a longitudinal dimension (e.g., a length) in the μm range, and an aspect ratio that is about 3 or greater, such as about 10 or greater.

As used herein, the term “nanoplatelet” refers to a planar-like, nano-sized object that is substantially solid.

As used herein, the term “nanotube” refers to an elongated, hollow, nano-sized object. Typically, a nanotube has a lateral dimension (e.g., a cross-sectional dimension in the form of a width, an outer diameter, or a width or outer diameter that represents an average across orthogonal directions) in the nm range, a longitudinal dimension (e.g., a length) in the μm range, and an aspect ratio that is about 3 or greater, such as about 10 or greater.

As used herein, the term “nanoparticle” refers to a nano-sized object that is generally or substantially spherical or spheroidal. Typically, each dimension (e.g., a cross-sectional dimension in the form of a width, a diameter, or a width or diameter that represents an average across orthogonal directions) of a nanoparticle is in the nm range, and the nanoparticle has an aspect ratio that is less than about 3, such as about 1.

As used herein, the term “micron-sized” object refers to an object that has at least one dimension in the μm range. Typically, each dimension of a micron-sized object is in the μm range or beyond the μm range. A micron-sized object can have any of a wide variety of shapes, and can be formed of a wide variety of materials. Examples of micron-sized objects include microwires, microtubes, microparticles, and other microstructures.

As used herein, the term “microwire” refers to an elongated, micron-sized object that is substantially solid. Typically, a microwire has a lateral dimension (e.g., a cross-sectional dimension in the form of a width, a diameter, or a width or diameter that represents an average across orthogonal directions) in the μm range and an aspect ratio that is about 3 or greater, such as about 10 or greater.

As used herein, the term “microtube” refers to an elongated, hollow, micron-sized object. Typically, a microtube has a lateral dimension (e.g., a cross-sectional dimension in the form of a width, an outer diameter, or a width or outer diameter that represents an average across orthogonal directions) in the μm range and an aspect ratio that is about 3 or greater, such as about 10 or greater.

As used herein, the term “microparticle” refers to a micron-sized object that is generally or substantially spherical or spheroidal. Typically, each dimension (e.g., a cross-sectional dimension in the form of a width, a diameter, or a width or diameter that represents an average across orthogonal directions) of a microparticle is in the μm range, and the microparticle has an aspect ratio that is less than about 3, such as about 1.

Additionally, concentrations, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified. For example, a ratio in the range of about 1 to about 200 should be understood to include the explicitly recited limits of about 1 and about 200, but also to include individual ratios such as about 2, about 3, and about 4, and sub-ranges such as about 10 to about 50, about 20 to about 100, and so forth.

### Transparent Conductors

Embodiments of this disclosure relate to conductive structures, such as metallic nanowires, which are incorporated in single-layered or multi-layered substrates for use as transparent conductors or other types of devices. Embodiments of transparent conductors exhibit improved performance (e.g., higher electrical and thermal conductivity and higher light transmittance), as well as cost benefits arising from their composition and manufacturing methods. In some embodiments, transparent conductors can be manufactured by a surface embedding process in which conductive structures are physically embedded into a substrate, while preserving desired characteristics of the host material (e.g., transparency) and imparting additional desired characteristics to the resulting transparent conductors (e.g., electrical conductivity). In other embodiments, transparent conductors can be manufactured by another process, such as an over-coating process. In some embodiments, transparent conductors can be patterned so as to include a first set of portions having a first sheet conductance and a second set of portions having a second sheet conductance lower than the first sheet conductance. The first set of portions can correspond to higher sheet conductance (or lower sheet resistance) portions that function as conductive traces or grids, while the second set of portions can correspond to lower sheet conductance (or higher sheet resistance) portions that function as gaps for electrically isolating the conductive traces. Conductive structures can be surface-embedded or incorporated in areas of a substrate corresponding to either, or both, of the portions.

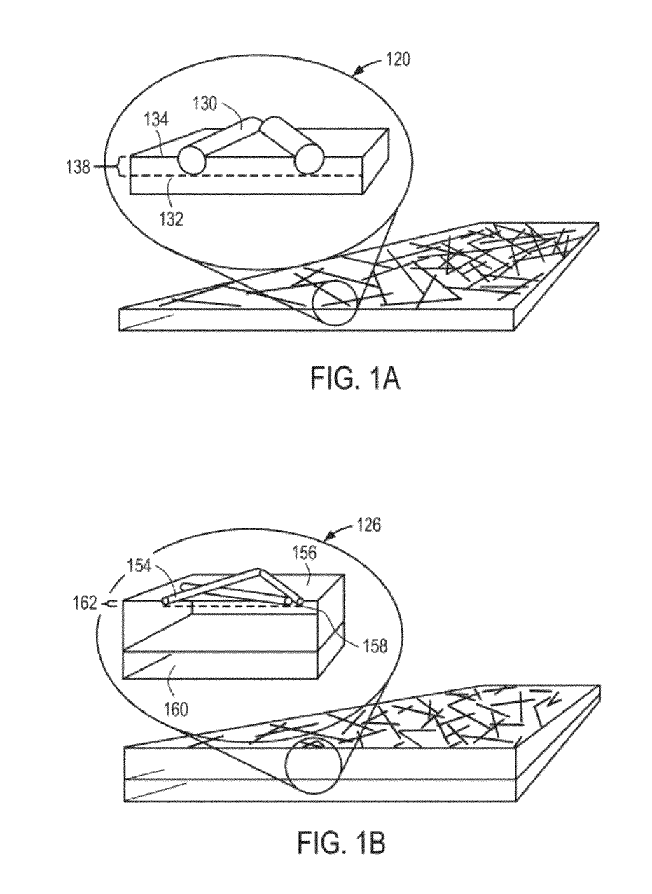

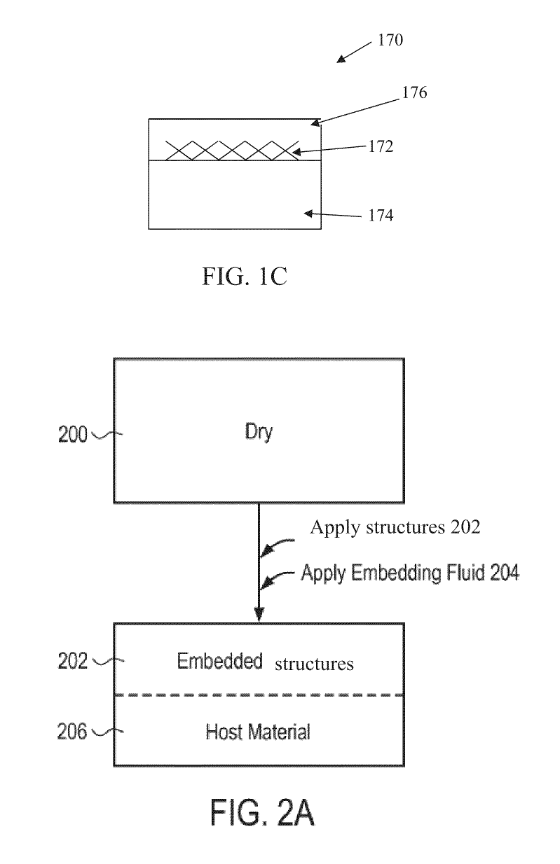

FIG. 1A and FIG. 1B illustrate examples of transparent conductors 120 and 126 implemented in accordance with embodiments of this disclosure. Specifically, FIG. 1A is a schematic of surface-embedded nanowires 130 that form a percolating network that is partially exposed and partially buried into a top, embedding surface 134 of a substrate 132. The embedding surface 134 also can be a bottom surface of the substrate 132, or multiple surfaces (e.g., both top and bottom surfaces) on different sides of the substrate 132 can be embedded with the same or different nanowires. As illustrated in FIG. 1A, the network of the nanowires 130 is localized adjacent to the embedding surface 134 and within an embedded region 138 of the substrate 132, with a remainder of the substrate 132 largely or substantially devoid of the nanowires 130. In the illustrated embodiment, the embedded region 138 is relatively thin (e.g., having a thickness less than or much less than an overall thickness of the substrate 132, or having a thickness comparable to a characteristic dimension of the nanowires 130), and, therefore, can be referred to as “planar” or “planar-like.” The transparent conductor 120 can be patterned, such that FIG. 1A can represent a view of a particular portion of the patterned transparent conductor 120, such as a higher sheet conductance portion. FIG. 1A also can represent a view of a lower sheet conductance portion, in which the network of the nanowires 130 is treated or otherwise processed to result in reduced electrical conductivity.

FIG. 1B is a schematic of surface-embedded nanowires 154 that form a percolating network that is partially exposed and partially buried into a top, embedding surface 156 of a coating or a top layer 158 that is disposed on top of a bottom layer 160, and which together constitute a two-layered substrate. As illustrated in FIG. 1B, the network of the nanowires 154 can be localized adjacent to the embedding surface 156 and within an embedded region 162 of the coating 158, with a remainder of the coating 158 largely or substantially devoid of the nanowires 154. It is also contemplated that the nanowires 154 can be distributed throughout a larger volume fraction within the coating 158, such as in the case of a relatively thin coating having a thickness comparable to a characteristic dimension of the nanowires 154. In the illustrated embodiment, the embedded region 162 is relatively thin, and, therefore, can be referred to as “planar” or “planar-like.” The transparent conductor 126 can be patterned, such that FIG. 1B can represent a view of a particular portion of the patterned transparent conductor 126, such as a higher sheet conductance portion. FIG. 1B also can represent a view of a lower sheet conductance portion, in which the network of the nanowires 154 is treated or otherwise processed to result in reduced electrical conductivity.

FIG. 1C illustrates an additional example of a transparent conductor 170 implemented in accordance with an embodiment of this disclosure. Specifically, FIG. 1C is a schematic of nanowires 172 that form a percolating network that is disposed on top of a bottom layer 174, and is at least partially incorporated in and surrounded by an over-coating or a top layer 176 that is disposed on top of the bottom layer 174 and the nanowires 172. As illustrated in FIG. 1C, the network of the nanowires 172 can be localized adjacent to the bottom layer 174 and within a bottom region of the over-coating 176, with a remainder of the over-coating 176 largely or substantially devoid of the nanowires 172. It is also contemplated that the nanowires 172 can be distributed throughout a larger volume fraction within the over-coating 176, such as in the case of a relatively thin over-coating having a thickness comparable to a characteristic dimension of the nanowires 172. In the case of a relatively thin over-coating, at least some of the nanowires 172 can be partially exposed at a top surface of the over-coating 176. The transparent conductor 170 can be patterned, such that FIG. 1C can represent a view of a particular portion of the patterned transparent conductor 170, such as a higher sheet conductance portion. FIG. 1C also can represent a view of a lower sheet conductance portion, in which the network of the nanowires 172 is treated or otherwise processed to result in reduced electrical conductivity. It is also contemplated that the nanowires 172 can be partially embedded into the bottom layer 174 (e.g., similar to the implementation of FIG. 1A), and then coated with the over-coating 176.

One aspect of certain transparent conductors described herein is the provision of a vertical concentration gradient or profile of conductive structures, such as metallic nanowires, within at least a portion of a substrate, namely a gradient or profile along a thickness direction of the substrate. Bulk incorporation within a substrate or a coating aims to provide a relatively uniform concentration profile throughout the substrate or the coating. In contrast, certain transparent conductors described herein allow for variable, controllable concentration profile, in accordance with a localization of conductive structures within an embedded region of at least a portion of a substrate. For certain implementations, the extent of localization of conductive structures within a set of embedded regions is such that at least a majority (by weight, volume, or number density) of the structures are included within the embedded regions, such as at least about 60% (by weight, volume, or number density) of the structures are so included, at least about 70% (by weight, volume, or number density) of the structures are so included, at least about 80% (by weight, volume, or number density) of the structures are so included, at least about 90% (by weight, volume, or number density) of the structures are so included, or at least about 95% (by weight, volume, or number density) of the structures are so included. For example, substantially all of the structures can be localized within the embedded regions, such that a remainder of the substrate is substantially devoid of the structures. In the case of a patterned transparent conductor, localization of conductive structures can vary according to a horizontal concentration gradient or profile in a substrate, or can vary across multiple layers included in the patterned transparent conductor.

Conductive structures, such as the nanowires 130, 154, and 172, can be formed of a variety of electrically conducive or semiconducting materials, including metals (e.g., silver (or Ag), nickel (or Ni), palladium (or Pd), platinum (or Pt), copper (or Cu), and gold (or Au)), metal alloys, semiconductors (e.g., silicon (or Si), indium phosphide (or InP), and gallium nitride (or GaN)), metalloids (e.g., tellurium (or Te)), conductive oxides and chalcogenides that are optionally doped and transparent (e.g., metal oxides and chalcogenides that are optionally doped and transparent such as zinc oxide (or ZnO)), electrically conductive polymers (e.g., poly(aniline), poly(acetylene), poly(pyrrole), poly(thiophene), poly(p-phenylene sulfide), poly(p-phenylene vinylene), poly(3-alkylthiophene), olyindole, poly(pyrene), poly(carbazole), poly(azulene), poly(azepine), poly(fluorene), poly(naphthalene), melanins, poly(3,4-ethylenedioxy thiophene) (or PEDOT), poly(styrenesulfonate) (or PSS), PEDOT-PSS, PEDOT-poly(methacrylic acid), poly(3-hexylthiophene), poly(3-octylthiophene), poly(C-61-butyric acid-methyl ester), and poly[2-methoxy-5-(2′-ethyl-hexyloxy)-1,4-phenylene vinylene]), and any combination thereof. In the case of a nanowire formed of a metal or a metal alloy, a particular example of such a metallic nanowire is a silver nanowire. Nanowires can have a core-shell configuration or a core-multi-shell configuration, and can incorporate a metal halide shell or a metal oxide shell, or other metal halide or metal oxide portions.

Although certain embodiments are described in the context of nanowires, additional embodiments can include other types of nano-sized structures (or nanostructures) in place of, or in combination with, nanowires. Further embodiments can be implemented to include micron-sized structures (or microstructures) in place of, or in combination with, nanowires. In general, nanostructures and microstructures can be formed of a variety of materials, including metals, metal alloys, semiconductors, metalloids, conductive oxides and chalcogenides that are optionally doped and transparent, electrically conductive polymers, insulators, and any combination thereof. To impart electrical conductivity, nanostructures and microstructures can include an electrically conductive material, a semiconductor, or a combination thereof

Examples of electrically conductive materials include metals (e.g., silver, copper, and gold in the form of silver nanowires, copper nanowires, and gold nanowires), silver-nickel, silver oxide, silver with a polymeric capping agent, silver-copper, copper-nickel, carbon-based materials (e.g., in the form of carbon nanotubes, graphene, and buckyballs), conductive ceramics (e.g., conductive oxides and chalcogenides that are optionally doped and transparent), electrically conductive polymers, and any combination thereof

Examples of semiconductors include semiconducting polymers, Group IVB elements (e.g., carbon (or C), silicon (or Si), and germanium (or Ge)), Group IVB-IVB binary alloys (e.g., silicon carbide (or SiC) and silicon germanium (or SiGe)), Group IIB-VIB binary alloys (e.g., cadmium selenide (or CdSe), cadmium sulfide (or CdS), cadmium telluride (or CdTe), zinc oxide (or ZnO), zinc selenide (or ZnSe), zinc telluride (or ZnTe), and zinc sulfide (or ZnS)), Group IIB-VIB ternary alloys (e.g., cadmium zinc telluride (or CdZnTe), mercury cadmium telluride (or HgCdTe), mercury zinc telluride (or HgZnTe), and mercury zinc selenide (or HgZnSe)), Group IIIB-VB binary alloys (e.g., aluminum antimonide (or AlSb), aluminum arsenide (or AlAs), aluminium nitride (or MN), aluminium phosphide (or AlP), boron nitride (or BN), boron phosphide (or BP), boron arsenide (or BAs), gallium antimonide (or GaSb), gallium arsenide (or GaAs), gallium nitride (or GaN), gallium phosphide (or GaP), indium antimonide (or InSb), indium arsenide (or InAs), indium nitride (or InN), and indium phosphide (or InP)), Group IIIB-VB ternary alloys (e.g., aluminium gallium arsenide (or AlGaAs or AlₓGa₁₋ₓAs), indium gallium arsenide (or InGaAs or InₓGa₁₋ₓAs), indium gallium phosphide (or InGaP), aluminium indium arsenide (or AlInAs), aluminium indium antimonide (or AlInSb), gallium arsenide nitride (or GaAsN), gallium arsenide phosphide (or GaAsP), aluminium gallium nitride (or AlGaN), aluminium gallium phosphide (or AlGaP), indium gallium nitride (or InGaN), indium arsenide antimonide (or InAsSb), and indium gallium antimonide (or InGaSb)), Group IIIB-VB quaternary alloys (e.g., aluminium gallium indium phosphide (or AlGaInP), aluminium gallium arsenide phosphide (or AlGaAsP), indium gallium arsenide phosphide (or InGaAsP), aluminium indium arsenide phosphide (or AlInAsP), aluminium gallium arsenide nitride (or AlGaAsN), indium gallium arsenide nitride (or InGaAsN), indium aluminium arsenide nitride (or InAlAsN), and gallium arsenide antimonide nitride (or GaAsSbN)), and Group IIIB-VB quinary alloys (e.g., gallium indium nitride arsenide antimonide (or GaInNAsSb) and gallium indium arsenide antimonide phosphide (or GaInAsSbP)), Group IB-VIIB binary alloys (e.g., cupruous chloride (or CuCl)), Group IVB-VIB binary alloys (e.g., lead selenide (or PbSe), lead sulfide (or PbS), lead telluride (or PbTe), tin sulfide (or SnS), and tin telluride (or SnTe)), Group IVB-VIB ternary alloys (e.g., lead tin telluride (or PbSnTe), thallium tin telluride (or Tl₂SnTe₅), and thallium germanium telluride (or Tl₂GeTe₅)), Group VB-VIB binary alloys (e.g., bismith telluride (or Bi₂Te₃)), Group IIB-VB binary alloys (e.g., cadmium phosphide (or Cd₃P₂), cadmium arsenide (or Cd₃As₂), cadmium antimonide (or Cd₃Sb₂), zinc phosphide (or Zn₃P₂), zinc arsenide (or Zn₃As₂), and zinc antimonide (or Zn₃Sb₂)), and other binary, ternary, quaternary, or higher order alloys of Group IB (or Group 11) elements, Group IIB (or Group 12) elements, Group IIIB (or Group 13) elements, Group IVB (or Group 14) elements, Group VB (or Group 15) elements, Group VIB (or Group 16) elements, and Group VIIB (or Group 17) elements, such as copper indium gallium selenide (or CIGS), as well as any combination thereof

Nanostructures and microstructures can include, for example, metallic or semiconducting nanoparticles, metallic or semiconducting nanowires (e.g. silver, copper, or zinc), metallic or semiconducting nanoplatelets, metallic or semiconducting nanorods, nanotubes (e.g., carbon nanotubes, multi-walled nanotubes (“MWNTs”), single-walled nanotubes (“SWNTs”), double-walled nanotubes (“DWNTs”), and graphitized or modified nanotubes), fullerenes, buckyballs, graphene, microparticles, microwires, microtubes, core-shell nanoparticles or microparticles, core-multi-shell nanoparticles or microparticles, core-shell nanowires, and other nano-sized or micron-sized structures having shapes that are generally or substantially tubular, cubic, spherical, or pyramidal, and characterized as amorphous, single or poly-crystalline, tetragonal, hexagonal, trigonal, orthorhombic, monoclinic, or triclinic, or any combination thereof

Examples of core-shell nanoparticles and core-shell nanowires include those with a ferromagnetic core (e.g., iron, cobalt, nickel, manganese, as well as their oxides and alloys formed with one or more of these elements), with a shell formed of a metal, a metal alloy, a metal oxide, carbon, or any combination thereof (e.g., silver, copper, gold, platinum, a conductive oxide or chalcogenide, graphene, and other materials listed as suitable materials herein). A particular example of a core-shell nanowire is one with a silver core and a gold shell (or a platinum shell or another type of shell) surrounding the silver core to reduce or prevent oxidation of the silver core. Another example of a core-shell nanowire is one with a silver core (or a core formed of another metal or other electrically conductive material), with a shell or other coating formed of one or more of the following: (a) electrically conductive polymers, such as poly(3,4-ethylenedioxythiophene) (or PEDOT) and polyaniline (or PANI); (b) conductive oxides, chalcogenides, and ceramics (e.g., deposited by sol-gel, chemical vapor deposition, physical vapor deposition, plasma-enhanced chemical vapor deposition, or chemical bath deposition); (c) insulators in the form of ultra-thin layers, such as polymers, SiO₂, BaTiO, and TiO₂; and (d) thin layers of metals, such as gold, copper, nickel, chromium, molybdenum, and tungsten. Such coated or core-shell form of nanowires can be desirable to impart electrical conductivity, while avoiding or reducing adverse interactions with a host material of a substrate, such as potential yellowing or other discoloration in the presence of a metal such as silver, oxidation (e.g., a silver/gold core/shell nanowires can have substantially lower oxidation due to the gold shell), and sulfidation (e.g., a silver/platinum core/shell nanowire can have substantially lower sulfidation due to the platinum shell).

For certain implementations, high aspect ratio nanostructures are desirable, such as in the form of nanowires, nanotubes, and combinations thereof. For example, desirable nanostructures include nanotubes formed of carbon or other materials (e.g., MWNTs, SWNTs, graphitized MWNTs, graphitized SWNTs, modified MWNTs, modified SWNTs, and polymer-containing nanotubes), nanowires formed of a metal, a metal oxide, a metal alloy, or other materials (e.g., silver nanowires, copper nanowires, zinc oxide nanowires (undoped or doped by, for example, aluminum, boron, fluorine, and others), tin oxide nanowires (undoped or doped by, for example, fluorine), cadmium tin oxide nanowires, ITO nanowires, polymer-containing nanowires, and gold nanowires), as well as other materials that are electrically conductive or semiconducting and having a variety of shapes, whether cylindrical, spherical, pyramidal, or otherwise. Additional examples of suitable conductive structures include those formed of activated carbon, graphene, carbon black, or ketjen black, and nanoparticles formed of a metal, a metal oxide, a metal alloy, or other materials (e.g., silver nanoparticles, copper nanoparticles, zinc oxide nanoparticles, ITO nanoparticles, and gold nanoparticles).

A host material, within which conductive structures are surface-embedded or otherwise at least partially incorporated, can have a variety of shapes and sizes, can be transparent, translucent, or opaque, can be flexible, bendable, foldable, stretchable, or rigid, can be electromagnetically opaque or electromagnetically transparent, and can be electrically conductive, semiconducting, or insulating. A host material can be in the form of a layer, a film, or a sheet serving as a substrate, or can be in the form of a coating or multiple coatings disposed on top of a bottom layer that together constitute a multi-layered substrate. A host material can be patterned or unpatterned. For example, a host material can be formed as a patterned layer that covers certain areas of a bottom layer while leaving remaining areas of the bottom layer exposed. As another example, a first host material can be formed as a first patterned layer overlying certain areas of a bottom layer, and a second host material (which can differ from the first host material in some manner) can be formed as a second patterned layer that covers remaining areas of the bottom layer. In such manner, the first host material can provide a first pattern, and the second host material can provide a second pattern that is an “inverse” of the first pattern. Stated in another way, the first host material can provide “positive” portions of a pattern, and the second host material can provide “negative’ portions of the pattern.

Examples of suitable host materials include organic materials, inorganic materials, and hybrid organic-inorganic materials. For example, a host material can include a thermoplastic polymer, a thermoset polymer, an elastomer, or a copolymer or other combination thereof, such as selected from polyolefins (e.g., polyethylene (or PE), polypropylene (or PP), polybutene, and polyisobutene), acrylate polymers (e.g., poly(methyl methacrylate) (or PMMA) type 1 and type 2), polymers based on cyclic olefins (e.g., cyclic olefin polymers (or COPs) and copolymers (or COCs), such as available under the trademark ARTON® and ZeonorFilm®), aromatic polymers (e.g., polystyrene), polycarbonate (or PC), ethylene vinyl acetate (or EVA), ionomers, polyvinyl butyral (or PVB), polyesters, polysulphones, polyamides, polyimides, polyurethanes, vinyl polymers (e.g., polyvinyl chloride (or PVC)), fluoropolymers, polysulfones, polylactic acid, polymers based on allyl diglycol carbonate, nitrile-based polymers, acrylonitrile butadiene styrene (or ABS), cellulose triacetate (or TAC), phenoxy-based polymers, phenylene ether/oxide, a plastisol, an organosol, a plastarch material, a polyacetal, aromatic polyamides, polyamide-imide, polyarylether, polyetherimide, polyarylsulfones, polybutylene, polyketone, polymethylpentene, polyphenylene, polymers based on styrene maleic anhydride, polymers based on polyallyl diglycol carbonate monomer, bismaleimide-based polymers, polyallyl phthalate, thermoplastic polyurethane, high density polyethylene, low density polyethylene, copolyesters (e.g., available under the trademark Tritan™), polyethylene terephthalate glycol (or PETG), polyethylene terephthalate (or PET), epoxy, epoxy-containing resin, melamine-based polymers, silicone and other silicon-containing polymers (e.g., polysilanes and polysilsesquioxanes), polymers based on acetates, poly(propylene fumarate), poly(vinylidene fluoride-trifluoroethylene), poly-3-hydroxybutyrate polyesters, polycaprolactone, polyglycolic acid (or PGA), polyglycolide, polyphenylene vinylene, electrically conductive polymers, liquid crystal polymers, poly(methyl methacrylate) copolymer, tetrafluoroethylene-based polymers, sulfonated tetrafluoroethylene copolymers, fluorinated ionomers, polymer corresponding to, or included in, polymer electrolyte membranes, ethanesulfonyl fluoride-based polymers, polymers based on 2-[1-[difluoro-[(trifluoroethenyl)oxy]methyl]-1,2,2,2-tetrafluoroethoxy]-1,1,2,2,-tetrafluoro-, with tetrafluoro ethylene, tetrafluoroethylene-perfluoro-3,6-dioxa-4-methyl-7-octenesulfonic acid copolymer, polyisoprene, polyglycolide, polyglycolic acid, polycaprolactone, polymers based on vinylidene fluoride, polymers based on trifluoroethylene, poly(vinylidene fluoride-trifluoroethylene), poly(phenylene vinylene), polymers based on copper phthalocyanine, cellophane, cuprammonium-based polymers, rayon, and biopolymers (e.g., cellulose acetate (or CA), cellulose acetate butyrate (or CAB), cellulose acetate propionate (or CAP), cellulose propionate (or CP), polymers based on urea, wood, collagen, keratin, elastin, nitrocellulose, plastarch, celluloid, bamboo, bio-derived polyethylene, carbodiimide, cartilage, cellulose nitrate, cellulose, chitin, chitosan, connective tissue, copper phthalocyanine, cotton cellulose, elastin, glycosaminoglycans, linen, hyaluronic acid, nitrocellulose, paper, parchment, plastarch, starch, starch-based plastics, vinylidene fluoride, and viscose), or any monomer, copolymer, blend, or other combination thereof. Additional examples of suitable host materials include ceramics, such as dielectric or non-conductive ceramics (e.g., SiO₂-based glass; SiOₓ-based glass; TiOₓ-based glass; other titanium, cerium, magnesium analogues of SiOₓ-based glass; spin-on glass; glass formed from sol-gel processing, silane precursor, siloxane precursor, silicate precursor, tetraethyl orthosilicate, silane, siloxane, phosphosilicates, spin-on glass, silicates, sodium silicate, potassium silicate, a glass precursor, a ceramic precursor, silsesquioxane, metallasilsesquioxanes, polyhedral oligomeric silsesquioxanes, halosilane, sol-gel, silicon-oxygen hydrides, silicones, stannoxanes, silathianes, silazanes, polysilazanes, metallocene, titanocene dichloride, vanadocene dichloride; and other types of glasses), conductive ceramics (e.g., conductive oxides and chalcogenides that are optionally doped and transparent, such as metal oxides and chalcogenides that are optionally doped and transparent), and any combination thereof. Additional examples of suitable host materials include electrically conductive materials and semiconductors listed above as suitable materials for conductive structures, such as electrically conductive polymers like poly(aniline), PEDOT, PSS, PEDOT-PSS, and so forth. The host material can be, for example, n-doped, p-doped, or un-doped. Further examples of suitable host materials include polymer-ceramic composite, polymer-wood composite, polymer-carbon composite (e.g., formed of ketjen black, activated carbon, carbon black, graphene, and other forms of carbon), polymer-metal composite, polymer-oxide, or any combination thereof. The host material also can incorporate a reducing agent, a corrosion inhibitor, a moisture barrier material, or other organic or inorganic chemical agent (e.g., PMMA with ascorbic acid, COP with a moisture barrier material, or PMMA with a disulfide-type corrosion inhibitor).

In some embodiments, confining conductive structures to a “planar” or “planar-like” embedded region within at least a portion of a host material can lead to decreased topological disorder of the structures and increased occurrence of junction formation between the structures for improved electrical conductivity. Although an embedded region is sometimes referred as “planar,” it will be understood that such embedded region is typically not strictly two-dimensional, as the structures themselves are typically three-dimensional. Rather, “planar” can be used in a relative sense, with a relatively thin, local concentration of the structures within a certain region of the host material, and with the structures largely or substantially absent from a remainder of the host material. It is noted that the local concentration of structures can be non-planar in the sense that it can be non-flat. For example, the structures can be concentrated in a thin region of the host material that is characterized by curvature with respect to one or more axes, with the structures largely or substantially absent from a remainder of the host material. It will also be understood that an embedded region can be referred as “planar,” even though such an embedded region can have a thickness that is greater than (e.g., several times greater than) a characteristic dimension of the structures. In general, an embedded region can be located adjacent to a side of a host material, adjacent to a middle of the host material, or adjacent to any arbitrary location along a thickness direction of the host material, and multiple embedded regions can be located adjacent to one another or spaced apart from one another within the host material. Each embedded region can include one or more types of conductive structures, and embedded regions (which are located in the same host material) can include different types of conductive structures. In the case of a patterned transparent conductor, multiple embedded regions can be located across a host material according to a pattern to define a set of higher sheet conductance portions, a set of lower sheet conductance portions, or both. In some embodiments, by confining conductive structures to a set of “planar” embedded regions of a host material (as opposed to randomly throughout the host material), a higher electrical conductivity can be achieved for a given amount of the structures per unit of area. Any conductive structures not confined to an embedded region represent an excess amount that can be omitted.

In some embodiments, transparent conductors can have at least one conductive structure embedded or otherwise incorporated in at least a portion of a host material from about 10% (or less, such as from about 0.1%) by volume of the structure into an embedding surface and up to about 100% by volume of the structure into the embedding surface, and can have structures exposed at varying surface area coverage, such as from about 0.1% exposed surface area coverage (or less, such as 0% when an embedded region is entirely below the surface, or when the structures are completely encapsulated by the host material) up to about 99.9% (or more) exposed surface area coverage, such as from about 0.1% to about 10%, about 0.1% to about 8%, or about 0.1% to about 5% exposed surface area coverage. For example, in terms of a volume of a conductive structure embedded below the embedding surface relative to a total volume of the structure, at least one structure can have an embedded volume percentage (or a population of the structures can have an average embedded volume percentage) in the range of about 0% to about 100%, such as from about 10% to about 50%, or from about 50% to about 100%.

Transparent conductors of some embodiments can have an embedded region with a thickness greater than a characteristic dimension of conductive structures used (e.g., for nanowires, greater than a diameter of an individual nanowire or an average diameter across the nanowires), with the structures largely or substantially confined to the embedded region, and with the thickness less than an overall thickness of a host material. For example, the thickness of the embedded region can be no greater than about 95% of the overall thickness of the host material, such as no greater than about 80%, no greater than about 75%, no greater than about 50%, no greater than about 40%, no greater than about 30%, no greater than about 20%, no greater than about 10%, or no greater than about 5% of the overall thickness.

In some embodiments, conductive structures can be surface-embedded or otherwise incorporated in at least a portion of a host material by varying degrees relative to a characteristic dimension of the structures used (e.g., for nanowires, relative to a diameter of an individual nanowire or an average diameter across the nanowires). For example, in terms of a distance of a furthest embedded point on a structure below an embedding surface, at least one structure can be embedded to an extent of more than about 100% of the characteristic dimension, or can be embedded to an extent of not more than about 100% of the characteristic dimension, such as at least about 5% or about 10% and up to about 80%, up to about 50%, or up to about 25% of the characteristic dimension. As another example, a population of the structures, on average, can be embedded to an extent of more than about 100% of the characteristic dimension, or can be embedded to an extent of not more than about 100% of the characteristic dimension, such as at least about 5% or about 10% and up to about 80%, up to about 50%, or up to about 25% of the characteristic dimension. As will be understood, the extent to which conductive structures are embedded in a host material can impact a roughness of an embedding surface, such as when measured as an extent of variation of heights across the embedding surface (e.g., a standard deviation relative to an average height). In some embodiments, a roughness of a surface-embedded substrate is less than a characteristic dimension of embedded structures.

In some embodiments, at least one conductive structure can extend out from an embedding surface of a host material from about 0.1 nm to about 1 cm, such as from about 1 nm to about 100 nm, from about 1 nm to about 50 nm, from about 50 nm to 100 nm, or from about 100 nm to about 100 μm. In other embodiments, a population of structures, on average, can extend out from an embedding surface of a host material from about 0.1 nm to about 1 cm, such as from about 1 nm to about 100 nm, from about 1 nm to about 50 nm, from about 50 nm to 100 nm, or from about 100 nm to about 100 μm. In other embodiments, substantially all of a surface area of a host material (e.g., an area of an embedding surface) is covered or occupied by conductive structures. In other embodiments, up to about 100% or up to about 75% of the surface area is covered or occupied by additives, such as up to about 50% of the surface area, up to about 25% of the surface area, up to about 10%, up to about 5%, up to about than 3% of the surface area, or up to about 1% of the surface area is covered by structures. Conductive structures need not extend out from an embedding surface of a host material, and can be localized entirely below the embedding surface. The degree of embedding and surface area coverage of conductive structures in a transparent conductor can be selected in accordance with a particular application.

In some embodiments, if nanowires are used, characteristics that can influence electrical conductivity and other desirable characteristics include, for example, nanowire concentration, density, or loading level; surface area coverage; nanowire length; nanowire diameter; uniformity of the nanowires; material type; stability of nanowire compositions; wire-wire junction resistance; host material resistance; nanowire conductivity; crystallinity of the nanowire; and purity. There can be a preference for nanowires with a low junction resistance and a low bulk resistance in some embodiments. For attaining higher electrical conductivity while maintaining high transparency, smaller diameter, longer length nanowires can be used (e.g., with relatively high aspect ratios to facilitate nanowire junction formation and in the range of about 50 to about 2,000, such as from about 100 to about 2,000, from about 50 to about 1,000, from about 100 to about 1,000, or from about 100 to about 800), and metallic nanowires, such as silver, copper, and gold nanowires, can be used. In other embodiments, if the nanowires are thin, their bulk conductivity can decrease because of a small cross-sectional area of the nanowires; therefore, in some embodiments, larger diameter wires can be selected. Using nanowires to form nanowire networks, such as silver nanowire networks, can be desirable for some embodiments. Other metallic nanowires, non-metallic nanowires, such as ITO and other oxide and chalcogenide nanowires, also can be used. Nanostructures and microstructures composed of semiconductors with bandgaps outside the visible optical spectrum energies (e.g., <1.8 eV and >3.1 eV) or near this range, can be used to create transparent conductors with high optical transparency in that visible light will typically not be absorbed by the bandgap energies or by interfacial traps therein. Various dopants can be used to tune the conductivity of these aforementioned semiconductors, taking into account the shifted Fermi levels and bandgap edges via the Moss-Burstein effect. The nanowires can be largely or substantially uniform or monodisperse in terms of dimensions (e.g., diameter and length), such as the same within about 5% (e.g., a standard deviation relative to an average diameter or length), the same within about 10%, the same within about 15%, or the same within about 20%. Purity can be, for example, at least about 50%, at least about 75%, at least about 85%, at least about 90%, at least about 95%, at least about 99%, at least about 99.9%, or at least about 99.99%. Surface area coverage of nanowires can be, for example, up to about 100%, less than about 100%, up to about 75%, up to about 50%, up to about 25%, up to about 10%, up to about 5%, up to about 3%, or up to about 1%. Silver nanowires can be particularly desirable for certain embodiments, since silver oxide, which can form (or can be formed) on surfaces of the nanowires as a result of oxidation, is electrically conductive. Also, core-shell nanowires (e.g., silver core with gold or platinum shell) also can decrease junction resistance. Nanowires can be solution synthesized via a number of processes, such as a solution-phase synthesis (e.g., the polyol process), a vapor-liquid-solid (or VLS) synthesis, an electrospinning process (e.g., using a polyvinyl-based polymer and silver nitrate, then annealing in forming gas, and baking), a suspension process (e.g., chemical etching or nano-melt retraction), and so forth.

In some embodiments, if nanotubes are used (whether formed of carbon, a metal, a metal alloy, a metal oxide, or another material), characteristics that can influence electrical conductivity and other desirable characteristics include, for example, nanotube concentration, density, or loading level; surface area coverage; nanotube length; nanotube inner diameter; nanotube outer diameter; whether single-walled or multi-walled nanotubes are used; uniformity of the nanotubes; material type; and purity. There can be a preference for nanotubes with a low junction resistance in some embodiments. For reduced scattering in the context of certain devices such as displays, nanotubes, such as carbon nanotubes, can be used to form nanotube networks. Alternatively, or in combination, smaller diameter nanowires can be used to achieve a similar reduction in scattering relative to the use of larger diameter nanotubes. Nanotubes can be largely uniform or monodisperse in terms of dimensions (e.g., outer diameter, inner diameter, and length), such as the same within about 5% (e.g., a standard deviation relative to an average outer/inner diameter or length), the same within about 10%, the same within about 15%, or the same within about 20%. Purity can be, for example, at least about 50%, at least about 75%, at least about 85%, at least about 90%, at least about 95%, at least about 99%, at least about 99.9%, or at least about 99.99%. Surface area coverage of nanotubes can be, for example, up to about 100%, less than about 100%, up to about 75%, up to about 50%, up to about 25%, up to about 10%, up to about 5%, up to about 3%, or up to about 1%.

In some embodiments, a combination of different types of high aspect ratio conductive structures (e.g., nanowires, nanotubes, or both) can be embedded into at least a portion of a host material, resulting in a transparent conductor. Specifically, the combination can include a first population of conductive structures having a first set of morphological characteristics (e.g., length (average, median, or mode), diameter (average, median, or mode), aspect ratio (average, median, or mode), or a combination thereof) and at least a second population of conductive structures having a second set of morphological characteristics that differ in some manner from the first set of morphological characteristics. Each population of structures can be largely or substantially uniform or monodisperse in terms of its respective set of morphological characteristics, such as the same within about 5% (e.g., a standard deviation relative to an average diameter, length, or aspect ratio), the same within about 10%, the same within about 15%, or the same within about 20%. The resulting combination of structures can be bimodal or multimodal. For example, longer and larger diameter nanowires can promote lower percolation thresholds, thereby achieving higher transparency with lower conductive material usage. On the other hand, shorter and smaller diameter nanowires can promote lower haze and higher transmission of light through a percolating network. However, smaller diameter nanowires may have higher Ohmic resistance compared to larger diameter nanowires of the same material. The use of a combination of longer and larger diameter nanowires and shorter and smaller diameter nanowires provides a practical tradeoff between various factors, including higher transparency (e.g., a lower percolation threshold from the longer nanowires), a lower haze (e.g., a lower scattering from the smaller diameter nanowires), a higher uniformity of coverage for a given sheet resistance or optical haze (e.g., a larger number of smaller diameter nanowires may be involved to reach a given sheet resistance, but if well-dispersed the nanowires can form a more robust network with fewer large-sized, nanowire-free areas), and higher conductivity (e.g., a lower resistance from the larger diameter nanowires) relative to the use of either population of nanowires alone. By way of analogy and not limitation, the longer and larger diameter nanowires can act as larger current arteries, while the shorter and smaller diameter nanowires can act as smaller current capillaries.

It should be understood that the number and types of conductive structures can be varied for a given device or application. For example, any one, or a combination, of silver nanowires, copper nanowires, and gold nanowires can be used along with ITO nanoparticles to yield high optical transparency and high electrical conductivity. Similar combinations include, for example, any one, or a combination, of silver nanowires, copper nanowires, and gold nanowires along with any one or more of ITO nanowires, ZnO nanowires, ZnO nanoparticles, silver nanoparticles, gold nanoparticles, SWNTs, MWNTs, fullerene-based materials (e.g., carbon nanotubes and buckyballs), and ITO nanoparticles. The use of ITO nanoparticles, nanowires, or layers of conductive oxides or ceramics (e.g., ITO, aluminum-doped zinc oxide, or other types of doped or undoped zinc oxides) can provide additional functionality, such as by serving as a buffer layer to adjust a work function in the context of a transparent conductor for use in a solar device, a thin-film solar device, an organic light emitting diode (or OLED) display device, an OLED lighting device, or similar device to provide a conductive path for the flow of an electric current, in place of, or in combination with, a conductive path provided by other conductive structures.

In some embodiments, conductive structures are initially provided as discrete objects. Upon embedding or incorporation in at least a portion of a host material, the host material can envelop or surround the structures such that the structures become aligned or otherwise arranged within a “planar” or “planar-like” embedded region. In some embodiments for the case of structures such as nanowires, nanotubes, microwires, microtubes, or other structures with an aspect ratio greater than 1, the structures become aligned such that their lengthwise or longitudinal axes are largely confined to within a range of angles relative to a horizontal plane, or another plane corresponding, or parallel, to a plane of an embedding surface. For example, the structures can be elongated and can be aligned such that their lengthwise or longest-dimension axes, on average, are confined to a range from about −45° to about +45° relative to the horizontal plane, such as from about −35° to about +35°, from about −25° to about +25°, from about −15° to about +15°, from about −5° to about +5°, from about −1° to about +1°, from about −0.1° to about +0.1°, or from about −0.01° to about +0.01°. Stated in another way, lengthwise axes of the structures can be confined such that θ<SIN⁻¹(t/L), where L=length of a structure, t=thickness of the host material, and θ is an angle relative to a horizontal plane corresponding to the embedding surface. In this example, little or substantially none of the structures can have their lengthwise or longitudinal axes oriented outside of the range from about −45° to about +45° relative to the horizontal plane. Within the embedded region, neighboring structures can contact one another in some embodiments. Such contact can be improved using higher aspect ratio structures, while maintaining a relatively low surface area coverage for desired transparency. In some embodiments, contact between structures, such as nanowires, nanoparticles, microwires, and microparticles, can be increased through pressure (e.g., a calendar press), sintering or annealing, such as low temperature sintering at temperatures of about 50° C., about 125° C., about 150° C., about 175° C., or about 200° C., or in the range of about 50° C. to about 125° C., about 100° C. to about 125° C., about 125° C. to about 150° C., about 150° C. to about 175° C., or about 175° C. to about 200° C., flash sintering, sintering through the use of redox reactions to cause deposits onto structures to grow and fuse the structures together, or any combination thereof. For example, in the case of silver or gold structures, silver ions or gold ions can be deposited onto the structures to cause the structures to fuse with neighboring structures. High temperature sintering at temperatures at or above about 200° C. is also contemplated. It is also contemplated that little or no contact is needed for certain applications and devices, where charge tunneling or hopping provides sufficient electrical conductivity in the absence of actual contact, or where a host material or a coating on top of the host material may itself be electrically conductive or semiconducting. Such applications and devices can operate with a sheet resistance up to about 10⁶ Ω/sq or more. Individual structures can be separated by electrical and quantum barriers for electron transfer.

Transparent conductors described herein can be quite durable. In some embodiments, such durability is in combination with rigidity and robustness, and, in other embodiments, such durability is in combination with the ability to be flexed, rolled, bent, and folded, amongst other physical actions, with, for example, no greater than about 50%, no greater than about 40%, no greater than about 30%, no greater than about 20%, no greater than about 15%, no greater than about 10%, no greater than about 5%, no greater than about 3%, or substantially no decrease in transmittance, and no greater than about 50%, no greater than about 40%, no greater than about 30%, no greater than about 20%, no greater than about 15%, no greater than about 10%, no greater than about 5%, no greater than about 3%, or substantially no increase in resistance (e.g., surface or sheet resistance). In some embodiments, the transparent conductors can survive a standard test for adhesion of coatings (e.g., a Scotch Tape Test) used in the coatings industry and yield substantially no decrease, or no greater than about 5% decrease, no greater than about 10% decrease, no greater than about 15% decrease, no greater than about 20% decrease, no greater than about 30% decrease, no greater than about 40% decrease, or no greater than about 50% decrease in observed transmittance, and yield substantially no increase, or no greater than about 5% increase, no greater than about 10% increase, no greater than about 15% increase, no greater than about 20% increase, no greater than about 30% increase, no greater than about 40% increase, or no greater than about 50% increase in observed resistance (e.g., sheet resistance). In some embodiments, the transparent conductors can also survive rubbing, scratching, flexing, physical abrasion, thermal cycling (e.g., exposure to temperatures up to (or at least) about 600° C., up to (or at least) about 550° C., up to (or at least) about 500° C., up to (or at least) about 450° C., or up to (or at least) about 400° C.), chemical exposure, accelerated life test (“ALT”), and humidity cycling with substantially no decrease, no greater than about 50% decrease, no greater than about 40% decrease, no greater than about 30% decrease, no greater than about 20% decrease, no greater than about 15% decrease, no greater than about 10% decrease, no greater than about 5% decrease, or no greater than about 3% decrease in observed transmittance, and with substantially no increase, no greater than about 50% increase, no greater than about 40% increase, no greater than about 30% increase, no greater than about 20% increase, no greater than about 15% increase, no greater than about 10% increase, no greater than about 5% increase, or no greater than about 3% increase in observed resistance (e.g., sheet resistance). This enhanced durability can result from embedding or incorporation of conductive structures in at least a portion of a host material, such that the structures are physically or chemically held inside the host material by molecular chains or other components of the host material. In some cases, flexing or pressing can be observed to increase conductivity.

Various standard tests can be used to measure durability, such as in terms of abrasion resistance. One such test, among others, is ASTM-F735-06 Standard Test Method for Abrasion Resistance of Transparent Plastics and Coatings Using the Oscillating Sand Method. Another test that can be used is ASTM D1044-08 Standard Test Method for Resistance of Transparent Plastics to Surface Abrasion. Yet another possible standard test is ASTM D4060-10 Standard Test Method for Abrasion Resistance of Organic Coatings by the Taber Abraser. Additional standard tests that can be used include tests for hardness, such as ASTM D3363-05(2011)e1 Standard Test Method for Film Hardness by Pencil Test, ASTM E384, ASTM E10, ASTM B277-95 Standard Test Method for Hardness of Electrical Contact Materials, and ASTM D2583-06 Standard Test Method for Indentation Hardness of Rigid Plastics by Means of a Barcol Impressor. Further details on these tests are available from ASTM International of West Conshohocken, Pa. Other standardized protocols include the ISO 15184, HS K-5600, ECCA-T4-1. BS 3900-E19, SNV 37113, SIS 184187, NCN 5350, and MIL C 27 227.

Another set of tests can be used to measure and evaluate reliability under ALT conditions. Some industry standards include dry heat (e.g., 85° C./dry), moist heat (e.g., 60° C./90% RH, or 85° C./85° RH), dry cold (e.g., −30° C./dry), and thermal shock (e.g., 80° C. 40° C. cycle for 30 minutes each). These ALT conditions can be carried out over hours, days, weeks, or months with samples exposed to those conditions for extended periods of time or number of cycles. In certain embodiments of the transparent conductors disclosed herein, the change in at least one of sheet resistance, transparency, and haze is controlled within ±50%, in other cases within ±25%, in other cases within ±10%, and in other cases within ±5%, or lower.

Another aspect of some embodiments of transparent conductors is that an electrical percolation threshold can be attained using a lesser amount of conductive structures. Stated in another way, electrical conductivity can be attained using less electrically conductive or semiconducting material, thereby saving material and associated cost and increasing transparency. As will be understood, an electrical percolation threshold is typically reached when a sufficient amount of conductive structures is present to allow percolation of electrical charge from one structure to another structure, thereby providing a conductive path across at least portion of a network of structures. In some embodiments, an electrical percolation threshold can be observed via a change in slope of a logarithmic plot of resistance versus loading level of structures. A lesser amount of electrically conductive or semiconducting material can be used since structures are largely confined to a “planar” or “planar-like” embedded region in some embodiments, thereby greatly reducing topological disorder and resulting in a higher probability of inter-structure (e.g., inter-nanowire or inter-nanotube) junction formation. In other words, because the structures are confined to a thin embedded region in at least a portion of a host material, as opposed to dispersed throughout the thickness of the host material, the probability that the structures will interconnect and form junctions can be greatly increased. A lesser amount of electrically conductive or semiconducting material also can be used in embodiments where a host material is itself electrically conductive or semiconducting. In some embodiments, an electrical percolation threshold can be attained at a loading level of structures in the range of about 0.001 μg/cm² to about 100 μg/cm² (or higher), such as from about 0.01 μg/cm² to about 100 μg/cm², from about 10 μg/cm² to about 100 μg/cm², from 0.01 μg/cm² to about 0.4 μg/cm², from about 0.5 μg/cm² to about 5 μg/cm², or from about 0.8 μg/cm² to about 3 μg/cm² for certain structures such as silver nanowires. These loading levels can be varied according to dimensions, material type, spatial dispersion, and other characteristics of structures.

In addition, a lesser amount of conductive structures can be used (e.g., as evidenced by a thickness of an embedded region) to achieve a network-to-bulk transition, which is a parameter representing a transition of a thin layer from exhibiting effective material properties of a sparse two-dimensional conductive network to one exhibiting effective properties of a three-dimensional conductive bulk material. By confining conductive structures to a “planar” or “planar-like” embedded region, a lower sheet resistance can be attained at specific levels of transmittance. Furthermore, in some embodiments, carrier recombination can be reduced due to the reduction or elimination of interfacial defects associated with a separate coating or other secondary material into which conductive structures are included by bulk incorporation.

To expound further on these advantages, a network of conductive structures can be characterized by a topological disorder and by contact resistance. Topologically, above a critical density of structures and above a critical density of structure-structure (e.g., nanowire-nanowire, nanotube-nanotube, or nanotube-nanowire) junctions, electrical current can readily flow from a source to a drain. A “planar” or “planar-like” network of structures can reach a network-to-bulk transition with a reduced thickness, represented in terms of a characteristic dimension of the structures (e.g., for nanowires, relative to a diameter of an individual nanowire or an average diameter across the nanowires). For example, an embedded region can have a thickness up to about 10 times (or more) of the characteristic dimension, such as up to about 9 times, up to about 8 times, up to about 7 times, up to about 6 times, up to about 5 times, up to about 4 times, up to about 3 times, or up to about 2 times the characteristic dimension, and down to about 0.05, about 0.1, about 0.2, about 0.3, about 0.4, or about 0.5 times the characteristic dimension, allowing devices to be thinner while increasing optical transparency and electrical conductivity. Accordingly, the transparent conductors described herein provide, in some embodiments, an embedded region with a thickness up to about n×d (in terms of nm) within which are localized structures having a characteristic dimension of d (in terms of nm), where n=2, 3, 4, 5, or higher.

Another advantage of some embodiments of transparent conductors is that, for a given level of electrical conductivity, the transparent conductors can yield higher transparency. This is because less electrically conductive or semiconducting material can be used to attain that level of electrical conductivity, in view of the efficient formation of junctions for a given loading level of conductive structures, in view of the use of a host material that is itself electrically conductive or semiconducting, or both. As will be understood, a transmittance of a thin conductive material (e.g., in the form of a film) can be expressed as a function of its sheet resistance R_{□} and an optical wavelength, as given by the following approximate relation for a thin film:

$$T ( λ ) = {( 1 + \frac{188.5}{{R}_{•}} \frac{{σ}_{Op} ( λ )}{{σ}_{DC}} )}^{- 2}$$

where σ_{Op} and σ_{DC} are the optical and DC conductivities of the material, respectively. In some embodiments, silver nanowire networks surface-embedded or otherwise incorporated in flexible transparent substrates can have sheet resistances as low as about 3.2 Ω/sq or about 0.2 Ω/sq, or even lower. In other embodiments, transparent conductors can reach up to about 85% (or more) for human vision or photometric-weighted transmittance T (e.g., from about 350 nm to about 700 nm) and sheet resistances as low as about 20 Ω/sq (or below). In still other embodiments, a sheet resistance of ≦10 Ω/sq at ≧85% (e.g., at least about 85%, at least about 90%, or at least about 95%, and up to about 97%, about 98%, or more) human vision transmittance can be obtained with the transparent conductors. It will be understood that transmittance can be measured relative to other ranges of optical wavelength, such as transmittance at a given wavelength or range of wavelengths in the visible range, such as about 550 nm, a solar-flux weighted transmittance, transmittance at a given wavelength or range of wavelengths in the infrared range, and transmittance at a given wavelength or range of wavelengths in the ultraviolet range. It will also be understood that transmittance can be measured relative to a bottom layer of a substrate (if present) (e.g., the transmittance value would not include the transmittance loss from a bottom layer that is below a top layer that includes surface-embedded or incorporated conductive structures), or can be measured relative to air (e.g., the transmittance value would include the transmittance loss from a bottom layer of a substrate). Unless otherwise specified herein, transmittance values are designated relative to a bottom layer of a substrate (if present), although similar transmittance values (albeit with somewhat higher values) are also contemplated when measured relative to air. Also, it will also be understood that transmittance or another optical characteristic can be measured relative to an over-coating, such as an optically clear adhesive (if present) (e.g., the transmittance value would not include the transmittance loss from an over-coating overlying a substrate that includes surface-embedded or incorporated conductive structures), or can be measured relative to air (e.g., the transmittance value would include the transmittance loss from an over-coating). Unless otherwise specified herein, values of optical characteristics are designated relative to an over-coating (if present), although similar values are also contemplated when measured relative to air. For some embodiments, a DC-to-optical conductivity ratio of transparent conductors can be at least about 100, at least about 115, at least about 300, at least about 400, or at least about 500, and up to about 600, up to about 800, or more.

Certain transparent conductors can include nanowires (e.g., silver nanowires) of average diameter in the range of about 1 nm to about 100 nm, about 10 nm to about 80 nm, about 20 nm to about 80 nm, or about 25 nm to about 45 nm, and an average length in the range of about 50 nm to about 1,000 nm, about 50 nm to about 500 nm, about 100 nm to about 100 nm, about 500 nm to 50 nm, about 5 μm to about 50 nm, about 20 μm to about 150 nm, about 5 μm to about 35 nm, about 25 μm to about 80 nm, about 25 μm to about 50 nm, or about 25 μm to about 40 nm. A top of an embedded region can be located about 0 nm to about 100 μm below a top, embedding surface of a host material, such as about 0.0001 nm to about 100 μm below the embedding surface, about 0.01 nm to about 100 μm below the embedding surface, about 0.1 nm to 100 μm below the embedding surface, about 0.1 nm to about 5 μm below the embedding surface, about 0.1 nm to about 3 μm below the embedding surface, about 0.1 nm to about 1 μm below the embedding surface, or about 0.1 nm to about 500 nm below the embedding surface. Nanowires embedded or incorporated in a host material can protrude from an embedding surface from about 0% by volume and up to about 90%, up to about 95%, or up to about 99% by volume. For example, in terms of a volume of a nanowire exposed above the embedding surface relative to a total volume of the nanowire, at least one nanowire can have an exposed volume percentage (or a population of the nanowires can have an average exposed volume percentage) of up to about 1%, up to about 5%, up to about 20%, up to about 50%, or up to about 75% or about 95%. At a transmittance of about 85% or greater (e.g., human vision transmittance or one measured at another range of optical wavelengths), a sheet resistance can be no greater than about 500 Ω/sq, no greater than about 400 Ω/sq, no greater than about 350 Ω/sq, no greater than about 300 Ω/sq, no greater than about 200 Ω/sq, no greater than about 100 Ω/sq, no greater than about 75 Ω/sq, no greater than about 50 Ω/sq, no greater than about 25 Ω/sq, no greater than about 20 Ω/sq, no greater than about 15 Ω/sq, no greater than about 10 Ω/sq, and down to about 1 Ω/sq or about 0.1 Ω/sq, or less. At a transmittance of about 90% or greater, a sheet resistance can be no greater than about 500 Ω/sq, no greater than about 400 Ω/sq, no greater than about 350 Ω/sq, no greater than about 300 Ω/sq, no greater than about 200 Ω/sq, no greater than about 100 Ω/sq, no greater than about 75 Ω/sq, no greater than about 50 Ω/sq, no greater than about 25 Ω/sq, no greater than about 20 Ω/sq, no greater than about 15 Ω/sq, no greater than about 10 Ω/sq, and down to about 1 Ω/sq or less.

Certain transparent conductors can include nanotubes (e.g., either, or both, MWCNT and SWCNT) of average outer diameter in the range of about 1 nm to about 100 nm, about 1 nm to about 10 nm, about 10 nm to about 50 nm, about 10 nm to about 80 nm, about 20 nm to about 80 nm, or about 40 nm to about 60 nm, and an average length in the range of about 50 nm to about 100 μm, about 100 nm to about 100 μm, about 500 nm to 50 μm, about 5 μm to about 50 μm, about 5 μm to about 35 μm, about 25 μm to about 80 μm, about 25 μm to about 50 μm, or about 25 μm to about 40 μm. A top of an embedded region can be located about 0 nm to about 100 μm below a top, embedding surface of a host material, such as about 0.01 nm to about 100 μm below the embedding surface, about 0.1 nm to 100 μm below the embedding surface, about 0.1 nm to about 5 μm below the embedding surface, about 0.1 nm to about 3 μm below the embedding surface, about 0.1 nm to about 1 μm below the embedding surface, or about 0.1 nm to about 500 nm below the embedding surface. Nanotubes embedded or incorporated in a host material can protrude from an embedding surface from about 0% by volume and up to about 90%, up to about 95%, or up to about 99% by volume. For example, in terms of a volume of a nanotube exposed above the embedding surface relative to a total volume of the nanotube (e.g., as defined relative to an outer diameter of a nanotube), at least one nanotube can have an exposed volume percentage (or a population of the nanotubes can have an average exposed volume percentage) of up to about 1%, up to about 5%, up to about 20%, up to about 50%, or up to about 75% or about 95%. At a transmittance of about 85% or greater (e.g., human vision transmittance or one measured at another range of optical wavelengths), a sheet resistance can be no greater than about 500 Ω/sq, no greater than about 400 Ω/sq, no greater than about 350 Ω/sq, no greater than about 300 Ω/sq, no greater than about 200 Ω/sq, no greater than about 100 Ω/sq, no greater than about 75 Ω/sq, no greater than about 50 Ω/sq, no greater than about 25 Ω/sq, no greater than about 20 Ω/sq, no greater than about 15 Ω/sq, no greater than about 10 Ω/sq, and down to about 1 Ω/sq or less. At a transmittance of about 90% or greater, a sheet resistance can be no greater than about 500 Ω/sq, no greater than about 400 Ω/sq, no greater than about 350 Ω/sq, no greater than about 300 Ω/sq, no greater than about 200 Ω/sq, no greater than about 100 Ω/sq, no greater than about 75 Ω/sq, no greater than about 50 Ω/sq, no greater than about 25 Ω/sq, no greater than about 20 Ω/sq, no greater than about 15 Ω/sq, no greater than about 10 Ω/sq, and down to about 1 Ω/sq or about 0.1 Ω/sq, or less.

In the case of a patterned transparent conductor, multiple embedded regions can be located across a single host material or across multiple host materials according to a pattern. The characteristics and ranges set forth herein regarding the nature and extent of surface embedding generally can apply across the multiple embedded regions, although the particular nature and extent of surface embedding can vary across the embedded regions to create a spatially varying contrast in electrical conductivity.

### Surface Embedding and Over-Coating Processes

The transparent conductors described herein can be formed according to manufacturing methods that can be carried out in a highly-scalable, rapid, and low-cost fashion, in which conductive structures are durably incorporated in a wide variety of host materials. Some embodiments of the manufacturing methods are surface embedding processes that can be generally classified into two categories: (1) surface embedding conductive structures into a dry composition to yield a host material with the surface-embedded conductive structures; and (2) surface embedding conductive structures into a wet composition to yield a host material with the surface-embedded conductive structures. It will be understood that such classification is for ease of presentation, and that “dry” and “wet” can be viewed as relative terms (e.g., with varying degrees of dryness or wetness), and that the manufacturing methods can apply to a continuum spanned between fully “dry” and fully “wet.” Accordingly, processing conditions and materials described with respect to one category (e.g., dry composition) can also apply with respect to another category (e.g., wet composition), and vice versa. It will also be understood that hybrids or combinations of the two categories are contemplated, such as where a wet composition is dried or otherwise converted into a dry composition, followed by surface embedding of conductive structures into the dry composition to yield a host material with the surface-embedded conductive structures. It will further be understood that, although “dry” and “wet” sometimes may refer to a level of water content or a level of solvent content, “dry” and “wet” also may refer to another characteristic of a composition in other instances, such as a degree of cross-linking or polymerization.

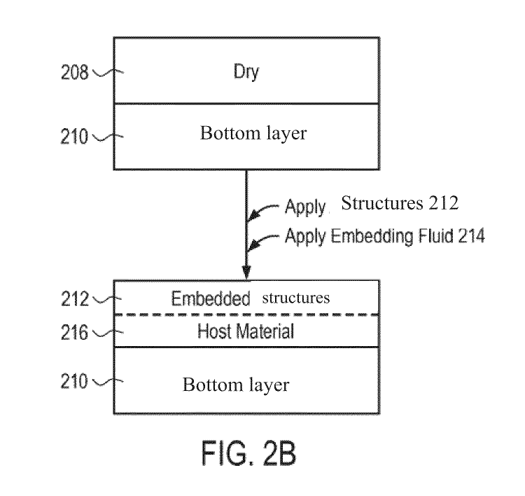

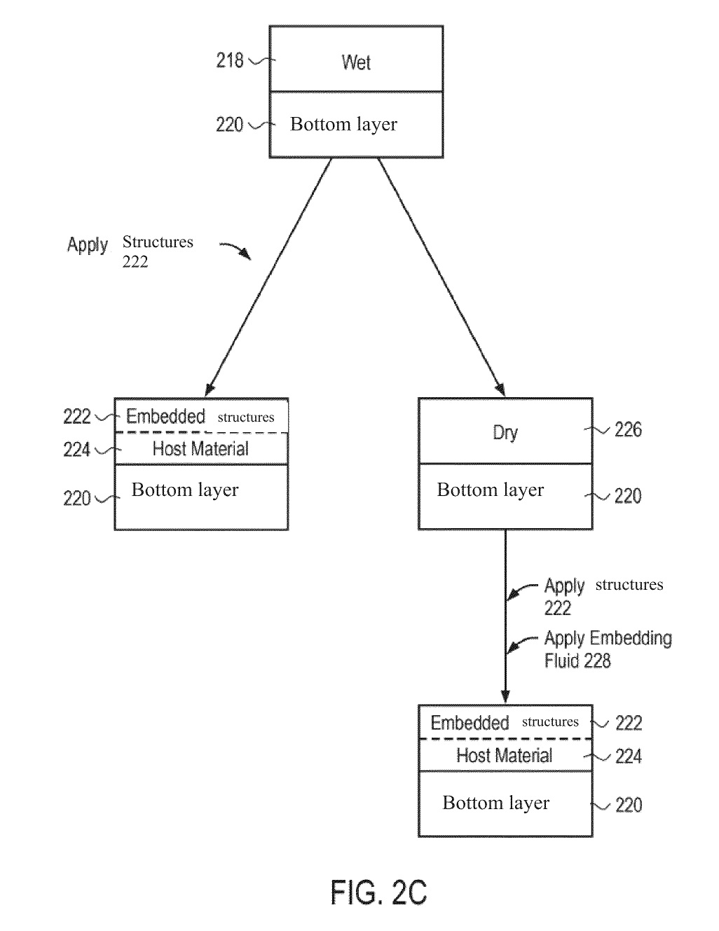

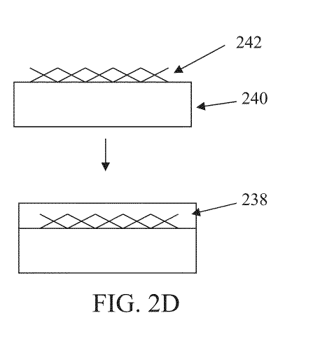

Attention first turns to FIG. 2A and FIG. 2B, which illustrate examples of manufacturing methods for surface embedding structures into dry compositions, according to embodiments of this disclosure.

By way of overview, the illustrated embodiments involve the application of an embedding fluid to allow conductive structures to be embedded into a dry composition. In general, the embedding fluid serves to reversibly alter the state of a polymer or other material included in the dry composition, such as by dissolving, reacting, softening, solvating, swelling, or any combination thereof, thereby facilitating embedding of the structures into the dry composition. For example, the embedding fluid can be specially formulated to act as an effective solvent for a polymer, while possibly also being modified with stabilizers (e.g., dispersants) to help suspend the structures in the embedding fluid. The embedding fluid also can be specially formulated to reduce or eliminate problems with solvent/polymer interaction, such as hazing, crazing, and blushing. The embedding fluid can include a solvent or a solvent mixture that is optimized to be low-cost, Volatile Organic Compound (“VOC”)-free, VOC-exempt or low-VOC, Hazardous Air Pollutant (“HAP”)-free, non-ozone depleting substances (“non-ODS”), low volatility or non-volatile, and low hazard or non-hazardous. As another example, the dry composition can include a ceramic or a ceramic precursor in the form of a gel or a semisolid, and application of the embedding fluid can cause the gel to be swollen by filling pores with the fluid, by elongation of partially uncondensed oligomeric or polymeric chains, or both. As a further example, the dry composition can include a ceramic or a ceramic precursor in the form of an ionic polymer, such as sodium silicate or another alkali metal silicate, and application of the embedding fluid can dissolve at least a portion of the ionic polymer to allow embedding of the structures. The embedding of the structures is then followed by hardening or other change in state of the softened or swelled composition, resulting in a host material having the structures embedded therein. For example, the softened or swelled composition can be hardened by exposure to ambient conditions, or by cooling the softened or swelled composition. In other embodiments, the softened or swelled composition is hardened by evaporating or otherwise removing at least a portion of the embedding fluid (or other liquid or liquid phase that is present), applying airflow, applying a vacuum, or any combination thereof. In the case of a ceramic precursor, curing can be carried out after embedding such that the ceramic precursor is converted into a glass or another ceramic. Curing can be omitted, depending on the particular application. Depending on the particular ceramic precursor (e.g., a silane), more or less heat can be involved to achieve various degrees of curing or conversion into a fully reacted or fully formed glass.

Referring to FIG. 2A, a dry composition 200 can be provided in the form of a sheet, a film, or other suitable form to serve as a substrate. The dry composition 200 can correspond to a host material and, in particular, can include a material previously listed as suitable host materials. It is also contemplated that the dry composition 200 can correspond to a host material precursor, which can be converted into the host material by suitable processing, such as drying, curing, cross-linking, polymerizing, or any combination thereof. Next, and referring to FIG. 2A, conductive structures 202 and an embedding fluid 204 are applied to the dry composition 200. The structures 202 can be in solution or otherwise dispersed in the embedding fluid 204, and can be simultaneously applied to the dry composition 200 via one-step embedding. Alternatively, the structures 202 can be separately applied to the dry composition 200 before, during, or after the embedding fluid 204 treats the dry composition 200. Embedding that involves separate application of the structures 202 and the embedding fluid 204 can be referred as two-step embedding. Subsequently, the resulting host material 206 has at least some of the structures 202 partially or fully embedded into a surface of the host material 206. Optionally, suitable processing can be carried out to convert the softened or swelled composition 200 into the host material 206. During device assembly, the host material 206 with the embedded structures 202 can be laminated or otherwise connected to adjacent device layers, or can serve as a substrate onto which adjacent device layers are formed, laminated, or otherwise applied.

In the case of a patterned transparent conductor, surface embedding according to FIG. 2A can be carried out generally uniformly across the dry composition 200, followed by spatially selective or varying treatment to yield higher conductance and lower conductance portions across the host material 206. Alternatively, or in conjunction, surface embedding according to FIG. 2A can be carried out in a spatially selective or varying manner, such as by applying the structures 202 in a spatially selective or varying manner, by applying the embedding fluid 204 in a spatially selective or varying manner, or both.

FIG. 2B is a process flow similar to FIG. 2A, but with a dry composition 208 provided in the form of a top layer that is disposed on top of a bottom layer 210, which together constitute or serve as a substrate. The dry composition 208 can correspond to a host material, or can correspond to a host material precursor, which can be converted into the host material by suitable processing, such as drying, curing, cross-linking, polymerizing, or any combination thereof. Other characteristics of the dry composition 208 can be similar to those described above with reference to FIG. 2A, and are not repeated below. Referring to FIG. 2B, the bottom layer 210 can be transparent or opaque, can be flexible or rigid, and can be comprised of, for example, a polymer, an ionomer, a coated polymer film (e.g., a PET film with a PMMA hardcoat), ethylene vinyl acetate (or EVA), cyclic olefin polymer (or COP), cyclic olefin copolymer (or COC), polyvinyl butyral (or PVB), thermoplastic olefin (or TPO), thermoplastic polyurethane (or TPU), polyethylene (or PE), polyethylene terephthalate (or PET), polyethylene terephthalate glycol (or PETG), polycarbonate, polyvinyl chloride (or PVC), polypropylene (or PP), an acrylate polymer, acrylonitrile butadiene styrene (or ABS), a ceramic, a glass, silicon, a metal (e.g., stainless steel or aluminum), or any combination thereof, as well as any other material previously listed as suitable host materials. The bottom layer 210 can serve as a temporary layer that is subsequently removed during device assembly, or can be retained in a resulting device as a layer or other component of the device. Next, conductive structures 212 and an embedding fluid 214 are applied to the dry composition 208. The structures 212 can be in solution or otherwise dispersed in the embedding fluid 214, and can be simultaneously applied to the dry composition 208 via one-step embedding. Alternatively, the structures 212 can be separately applied to the dry composition 208 before, during, or after the embedding fluid 214 treats the dry composition 208. As noted above, embedding involving the separate application of the structures 212 and the embedding fluid 214 can be referred as two-step embedding. Subsequently, the resulting host material 216 (which is disposed on top of the bottom layer 210) has at least some of the structures 212 partially or fully embedded into a surface of the host material 216. Optionally, suitable processing can be carried out to convert the softened or swelled composition 208 into the host material 216. During device assembly, the host material 216 with the embedded structures 212 can be laminated or otherwise connected to adjacent device layers, or can serve as a substrate onto which adjacent device layers are formed, laminated, or otherwise applied.

In the case of a patterned transparent conductor, surface embedding according to FIG. 2B can be carried out generally uniformly across the dry composition 208, followed by spatially selective or varying treatment to yield higher conductance and lower conductance portions across the host material 216. Alternatively, or in conjunction, surface embedding according to FIG. 2B can be carried out in a spatially selective or varying manner, such as by disposing or forming the dry composition 208 in a spatially selective or varying manner over the bottom layer 210, by applying the structures 212 in a spatially selective or varying manner across either, or both, of the dry composition 208 and the bottom layer 210, by applying the embedding fluid 214 in a spatially selective or varying manner across either, or both, of the dry composition 208 and the bottom layer 210, or any combination thereof

In some embodiments, conductive structures are dispersed in an embedding fluid, or are dispersed in a carrier fluid and applied to a dry composition separately or along with the embedding fluid. Dispersion can be accomplished by mixing, milling, sonicating, shaking (e.g., wrist action shaking, rotary shaking), vortexing, vibrating, flowing, chemically modifying the structures' surfaces, chemically modifying a fluid, increasing a viscosity of the fluid, adding a dispersing or suspending agent to the fluid, adding a stabilization agent to the fluid, changing the polarity of the fluid, changing the hydrogen bonding of the fluid, changing the pH of the fluid, or otherwise processing the structures to achieve the desired dispersion. The dispersion can be uniform or non-uniform, and can be stable or unstable.

An embedding fluid can include a solvent or a combination of two or more different solvents. Suitable solvents include organic solvents selected from polar aprotic organic solvents, polar protic organic solvents, and non-polar organic solvents. Depending on a particular polymer included in a dry composition, water or another inorganic solvent also can be included. Suitable organic solvents can include from 1-15, 2-15, 3-15, 3-12, 3-10, 4-10, or 5-10 carbon atoms per molecule. Particular classes of suitable organic solvents can include ketones, aldehydes, alcohols, esters, ethers, and arenes. Examples of suitable ketones include cyclohexanone, 4-methyl cyclohexanone, isophorone, methyl isobutyl ketone (or MIBK), methyl ethyl ketone (or MEK), acetylacetone, and acetone, among other cyclic or acyclic ketones including from 1-15, 2-15, 3-15, 3-12, 3-10, 4-10, or 5-10 carbon atoms per molecule. An example of a suitable aldehyde is salicylaldehyde, among other aromatic or aliphatic aldehydes including from 1-15, 2-15, 3-15, 3-12, 3-10, 4-10, or 5-10 carbon atoms per molecule. It will be understood that salicylaldehyde includes a hydroxyl group and, thus, also can be considered an example of a suitable alcohol. Additional examples of suitable alcohols include o-methoxyphenol, m-methoxyphenol, p-methoxyphenol, and diacetone alcohol, among other aromatic or aliphatic alcohols including from 1-15, 2-15, 3-15, 3-12, 3-10, 4-10, or 5-10 carbon atoms per molecule. It will be understood that methoxyphenol also can be considered an example of a suitable ether, and diacetone alcohol also can be considered an example of a suitable ketone. Examples of suitable esters include propylene glycol methyl ether acetate (or PGMEA), n-butyl acetate, methyl salicylate, and ethyl lactate, among other cyclic or acyclic, aliphatic or aromatic esters including from 1-15, 2-15, 3-15, 3-12, 3-10, 4-10, or 5-10 carbon atoms per molecule. It will be understood that propylene glycol methyl ether acetate also can be considered another example of a suitable ether, and methyl salicylate and ethyl lactate also can be considered additional examples of suitable alcohols. Additional examples of suitable ethers include 2-methoxy-1,3-dioxolane, tetrahydrofuran, ethylene glycol monobutyl ether (or EGMBE), diethylene glycol monobutyl ether, and diethylene glycol monoethyl ether (or DEGMEE), among other cyclic or acyclic ethers including from 1-15, 2-15, 3-15, 3-12, 3-10, 4-10, or 5-10 carbon atoms per molecule. It will be understood that ethylene glycol monobutyl ether and diethylene glycol monoethyl ether also can be considered additional examples of suitable alcohols. Examples of suitable arenes include toluene, benzene, ethyl benzene, and xylene, among other monocyclic or polycylic arenes including from 5-15 or 5-10 carbon atoms per molecule. Nitroethane and N-methyl pyrrolidone also can be suitable organic solvents.

As explained above for some embodiments, conductive structures can be in solution or otherwise dispersed in a carrier fluid, and can be applied to a dry composition along with an embedding fluid. The carrier fluid can be included to provide functionality other than softening or swelling a polymer or other material included in the dry composition. Other functionality provided by the carrier fluid can include one or a combination of the following:

(1) Certain coating tools or processes specify a minimum (or other threshold) coating thickness of fluids that are applied to a substrate. Inclusion of an excessive amount of an embedding fluid that interacts with the substrate can result in excessive softening or swelling of the substrate, and can lead to over-embedding of conductive structures deep into the substrate below a surface of the substrate. Inclusion of a certain fraction of a carrier fluid that is inert towards the substrate allows compliance with the minimum coating thickness specified by a coating tool or process, while also controlling an extent of embedding of structures into the substrate.

(2) In some embodiments, a capping agent, such as poly(vinylpyrrolidone) (or PVP), is surface bound or otherwise associated with certain structures, such as nanowires. In such embodiments, an embedding fluid can be optimized towards softening or swelling a substrate, but may lack sufficient compatibility with the capping agent. Inclusion of a certain fraction of a carrier fluid that is compatible with the capping agent addresses the lack of compatibility between the embedding fluid and the capping agent, such that the capping agent, along with the structures to which the capping agent is bound, can be stabilized and remain dispersed in a dispersion.

A carrier fluid can include a solvent or a combination of two or more different solvents. In some embodiments, a carrier fluid is more volatile than an embedding fluid, such that the carrier fluid is present in a dispersion of conductive structures as initially applied to a substrate during a coating process, but evaporates faster than the embedding fluid. In such manner, the carrier fluid is removed from the substrate at a faster rate than the embedding fluid, which remains on the substrate for a longer period of time to soften or swell the substrate and promote embedding of the structures into the substrate. Suitable solvents include organic solvents selected from polar aprotic organic solvents and polar protic organic solvents. A non-polar organic solvent or water or another inorganic solvent also can be included. Suitable organic solvents can include from 1-10, 1-9, 1-8, 1-7, 1-6, 1-5, 1-4, 1-3, 1-2, or 2-3 carbon atoms per molecule. A particular class of suitable organic solvents includes alcohols, and examples of suitable alcohols include methyl alcohol, ethyl alcohol, n-propyl alcohol, isopropyl alcohol, n-butyl alcohol, sec-butyl alcohol, isobutyl alcohol, tert-butyl alcohol, n-pentyl alcohol, neo-pentyl alcohol, and n-hexyl alcohol, among other aromatic or aliphatic alcohols including from 1-10, 1-9, 1-8, 1-7, 1-6, 1-5, 1-4, 1-3, 1-2, or 2-3 carbon atoms per molecule. In some embodiments, a carrier fluid includes a combination of two or more different solvents having different levels of volatility, such as where the carrier fluid includes at least a first solvent and a different, second solvent, the first solvent and the second solvent are different alcohols, the first solvent is selected from aliphatic alcohols including from 1-3, 1-2, or 2-3 carbon atoms per molecule, and the second solvent is selected from aliphatic alcohols including from 4-10, 4-9, 4-8, 4-7, 4-6, or 4-5 carbon atoms per molecule.

Control over surface embedding can be achieved through the proper balancing of the swelling-dispersion-evaporation-application stages. This balance can be controlled by, for example, a solvent-host material interaction parameter, sizes of conductive structures to be embedded, reactivity and volatility of an embedding fluid, impinging structure momentum or velocity, temperature, humidity, pressure, and others factors. More particularly, examples of processing parameters for surface embedding are listed below for some embodiments of this disclosure:

### Embedding Fluid Selection:

Solubility parameter relative to a substrate or other host material (e.g., Hildebrand and Hansen solubility parameters)
Compatibility of embedding fluid with surface (e.g., matching or comparison of dielectric constant, partition coefficient, pKa, and so forth)
Azeotropes, miscibility
Solvent diffusion/mobility
Viscosity
Evaporation (flash point, vapor pressure, cooling, and so forth)
Duration of solvent exposure to substrate or other host material
Dispersants, surfactants, stabilizers, rheology modifiers
Solvent (VOC, VOC-exempt, VOC-free, aqueous based)

### Substrate or Other Host Material:

Solubility parameters (relative to the solvent formulation)
Crystallinity
Degree of crosslinking
Molecular weight
Surface energy
Co-polymers/composite materials
Surface treatment

### Type of Structures:

Concentration of structures
Geometry of structures
Surface modification (e.g., ligands, surfactants) of structures
Stability of structures in the solvent formulation

### Process Operations and Conditions:

Deposition Type/Application method (e.g., spraying, printing, roll coating, gravure coating, slot-die coating, capillary coating, meniscus coating, cup coating, blade coating, airbrushing, immersion, dip coating, and so forth)
Duration of solvent exposure to substrate or other host material
Wetting, surface tension
Volume of solvent
Surface (pre)treatment
Humidity
Surface (post)treatment
Impact/momentum/velocity of structures onto surface (e.g., may influence depth or extent of embedding)
Shear applied to solvent between host material and applicator
Post-processing conditions (e.g., heating, evaporation, fluid removal, air-drying, and so forth)

### Other Factors:

Wetting/surface tension
Capillary forces, wicking
Amount of solvent applied to the surface
Duration of solvent exposure to the surface
Surface (pre)treatment
Stability of formulation
Diffusion of embedding fluid into surface: thermodynamic and kinetics considerations

### Mitigation of Undesired Effects:

Irreversible destruction
Long swelling/solubility time
Blushing, hazing
Cracking, crazing
Environmental conditions (e.g., humidity)
Permanent softening
Wettability/uneven wetting
Solution stability
Surface Roughness

Some, or all, of the aforementioned parameters can be altered or selected to tune a depth or an extent of embedding of conductive structures into a given host material. For example, a higher degree of embedding deep into a surface of a host material can be achieved by increasing a solvency power of an embedding fluid interacting with the host material, matching closely Hansen solubility parameters of the embedding fluid-substrate, prolonging the exposure duration of the embedding fluid in contact with the host material, increasing an amount of the embedding fluid in contact with the host material, elevating a temperature of the system, increasing a momentum of structures impinging onto the host material, increasing a diffusion of either, or both, of the embedding fluid and the structures into the host material, or any combination thereof

Fluids (e.g., embedding fluids and carrier fluids) can also include salts, surfactants, stabilizers, and other additives useful in conferring a particular set of characteristics on the fluids. Stabilizers can be included based on their ability to at least partially inhibit agglomeration of structures. Other stabilizers can be chosen based on their ability to preserve the functionality of the structures. Butylated hydroxytoluene (or BHT), for instance, can act as a good stabilizer and as an antioxidant. Other agents can be used to adjust rheological properties, evaporation rate, and other characteristics.

Fluids and structures can be applied so as to be largely stationary relative to a surface of a dry composition. In other embodiments, application is carried out with relative movement, such as by spraying a fluid onto a surface, by conveying a dry composition through a falling curtain of a fluid, or by conveying a dry composition through a pool or bath of a fluid. Application of fluids and structures can be effected by airbrushing, atomizing, nebulizing, spraying, electrostatic spraying, pouring, rolling, curtaining, wiping, spin casting, dripping, dipping, painting, flowing, brushing, immersing, patterning (e.g., stamping, controlled spraying, controlled ultrasonic spraying, and so forth), flow coating methods (e.g., slot-die, capillary coating, meniscus coating, meyer rod, blade coating, cup coating, draw down, and the like), printing, gravure printing, lithography, screen printing, flexo printing, offset printing, roll coating, ink-jet printing, intaglio printing, or any combination thereof. In some embodiments, structures are propelled, such as by a sprayer, onto a surface, thereby facilitating embedding by impact with the surface. In other embodiments, a gradient is applied to a fluid, structures, or both. Suitable gradients include magnetic and electric fields. The gradient can be used to apply, disperse, or propel the fluid, structures, or both, onto a surface. In some embodiments, the gradient is used to manipulate structures so as to control the extent of embedding. An applied gradient can be constant or variable. Gradients can be applied before a dry composition is softened or swelled, while the dry composition remains softened or swelled, or after the dry composition is softened or swelled. It is contemplated that a dry composition can be heated to achieve softening, and that either, or both, a fluid and structures can be heated to promote embedding. In some embodiments, embedding of structures can be achieved primarily or solely through application of an embedding fluid, without application of gradients or external pressure. In some embodiments, embedding of structures can be achieved through application of pressure (e.g., pressure rollers) in place of, or in conjunction with, an embedding fluid.

Application of fluids and conductive structures and embedding of the structures can be spatially controlled to yield patterns. In some embodiments, spatial control can be achieved with a physical mask, which can be placed between an applicator and a surface to block a segment of applied structures from contacting the surface, resulting in controlled patterning of embedding. In other embodiments, spatial control can be achieved with a photomask. A positive or negative photomask can be placed between a light source and a surface, which can correspond to a photoresist. Light transmitted through non-opaque parts of the photomask can selectively affect a solubility of exposed parts of the photoresist, and resulting spatially controlled soluble regions of the photoresist can permit controlled embedding. In other embodiments, spatial control can be achieved through the use of electric gradients, magnetic gradients, electromagnetic fields, thermal gradients, pressure or mechanical gradients, surface energy gradients (e.g., liquid-solid-gas interfaces, adhesion-cohesion forces, and capillary effects), printing, or any combination thereof. Spatial control can also be achieved by printing a material that differs from a host material and in which embedding does not occur (or is otherwise inhibited).

As noted above, conductive structures can be dispersed in an embedding fluid, and applied to a dry composition along with the embedding fluid via one-step embedding. Structures also can be applied to a dry composition separately from an embedding fluid via two-step embedding. In the latter scenario, the structures can be applied in a wet form, such as by dispersing in a carrier fluid or by dispersing in the same embedding fluid or a different embedding fluid. Still in the latter scenario, the structures can be applied in a dry form, such as in the form of aerosolized powder. It is also contemplated that the structures can be applied in a quasi-dry form, such as by dispersing the structures in a carrier fluid that is volatile, such as methanol, another low boiling point alcohol, or another low boiling point organic solvent, which substantially vaporizes prior to impact with a dry composition.

Attention next turns to FIG. 2C, which illustrates a manufacturing method for surface embedding conductive structures 222 into a wet composition 218, according to an embodiment of this disclosure. Referring to FIG. 2C, the wet composition 218 is applied to a bottom layer 220 in the form of a coating or a top layer that is disposed on top of the bottom layer 220, which together constitute or serve as a substrate. The wet composition 218 can correspond to a dissolved form of a host material and, in particular, can include a dissolved form, a colloidal form, a nanoparticle form, a sol-form of any material previously listed as suitable host materials. It is also contemplated that the wet composition 218 can correspond to a host material precursor, which can be converted into the host material by suitable processing, such as drying, curing, cross-linking, polymerizing, sintering, calcining, or any combination thereof. For example, the wet coating composition 218 can be a coating or a top layer that is not fully cured or set, a cross-linkable coating or top layer that is not fully cross-linked, which can be subsequently cured or cross-linked using suitable polymerization initiators or cross-linking agents, or a coating or a top layer of monomers, oligomers, or a combination of monomers and oligomers, which can be subsequently polymerized using suitable polymerization initiators or cross-linking agents. The wet composition 218 also can be patterned, for instance, with printing methods like screen, reverse offset gravure, flexo, or ink jetprinting, or another method. In some embodiments, the wet composition 218 can include a material with a liquid phase as well as a solid phase, or can include a material that is at least partially liquid or has properties resembling those of a liquid, such as a sol, a semisolid, a gel, and the like. The bottom layer 220 can be transparent or opaque, can be flexible or rigid, and can be composed of, for example, a polymer, an ionomer, EVA, PVB, TPO, TPU, PE, PET, PETG, PMMA, polycarbonate, PVC, PP, an acrylate polymer, ABS, a ceramic, a glass, silicon, a metal (e.g., stainless steel or aluminum), or any combination thereof, as well as any other material previously listed as suitable host materials. The bottom layer 220 can serve as a temporary layer that is subsequently removed during device assembly, or can be retained in a resulting device as a layer or other component of the device.

Next, according to the option on the left-side of FIG. 2C, the structures 222 are applied to the wet composition 218 prior to drying or while it remains in a state that permits embedding of the structures 222 within the wet composition 218. In some embodiments, application of the structures 222 is via a flow coating method (e.g., slot-die, capillary coating, meyer rod, cup coating, draw down, and the like). Although not illustrated on the left-side, it is contemplated that an embedding fluid can be simultaneously or separately applied to the wet composition 218 to facilitate the embedding of the structures 222. In some embodiments, embedding of the structures 222 can be achieved through application of pressure (e.g., pressure rollers) in place of, or in conjunction with, an embedding fluid. Subsequently, the resulting host material 224 has at least some of the structures 222 partially or fully embedded into a surface of the host material 224. Suitable processing can be carried out to convert the wet composition 218 into the host material 224. During device assembly, the host material 224 with the embedded structures 222 can be laminated or otherwise connected to adjacent device layers, or can serve as a substrate onto which adjacent device layers are formed, laminated, or otherwise applied.

Certain aspects regarding the application of the structures 222 and the embedding of the structures 222 on the left-side of FIG. 2C can be carried out using similar processing conditions and materials as described above for FIG. 2A and FIG. 2B, and those aspects are not repeated below.

Referring to the option on the right-side of FIG. 2C, the wet composition 218 can be initially converted into a dry composition 226 by suitable processing, such as by at least partially drying, curing, cross-linking, polymerization, or any combination thereof. Next, the structures 222 and an embedding fluid 228 can be applied to the dry composition 226. The structures 222 can be in solution or otherwise dispersed in the embedding fluid 228, and can be simultaneously applied to the dry composition 226 via one-step embedding. Alternatively, the structures 222 can be separately applied to the dry composition 226 before, during, or after the embedding fluid 228 treats the dry composition 226. As noted above, embedding involving the separate application of the structures 222 can be referred as two-step embedding. Subsequently, the resulting host material 224 has at least some of the structures 222 partially or fully embedded into the surface of the host material 224. Optionally, suitable processing can be carried out to convert the dry composition 226 into the host material 224, such as by additional drying, curing, cross-linking, polymerization, or any combination thereof. Any, or all, of the manufacturing stages illustrated in FIG. 2C can be carried out in the presence of a vapor environment of a suitable fluid (e.g., an embedding fluid or other suitable fluid) to facilitate the embedding of the structures 222, to slow drying of the wet composition 218, or both.

Certain aspects regarding the application of the structures 222 and the embedding fluid 228 and the embedding of the structures 222 on the right-side of FIG. 2C can be carried out using similar processing conditions and materials as described above for FIG. 2A and FIG. 2B, and those aspects are not repeated below. In particular, and in at least certain aspects, the processing conditions for embedding the structures 222 into the dry composition 226 on the right-side of FIG. 2C can be viewed as largely parallel to those used when embedding the structures 212 into the dry composition 208 of FIG. 2B.

In the case of a patterned transparent conductor, surface embedding according to FIG. 2C can be carried out generally uniformly across the wet composition 218 or the dry composition 226, followed by spatially selective or varying treatment to yield higher conductance and lower conductance portions across the host material 224. Alternatively, or in conjunction, surface embedding according to FIG. 2C can be carried out in a spatially selective or varying manner, such as by disposing or forming the wet composition 218 in a spatially selective or varying manner over the bottom layer 220, by applying the structures 222 in a spatially selective or varying manner across either, or both, of the wet composition 218 and the bottom layer 220, by applying the structures 222 in a spatially selective or varying manner across either, or both, of the dry composition 226 and the bottom layer 220, by applying the embedding fluid 228 in a spatially selective or varying manner across either, or both, of the dry composition 226 and the bottom layer 220, or any combination thereof.

Attention next turns to FIG. 2D, which illustrates a manufacturing method for incorporating conductive structures 242 into a wet composition 238, according to an embodiment of this disclosure. Referring to FIG. 2D, the structures 242 are applied to a bottom layer 240, such as in a substantially dry form or dispersed in a suitable carrier fluid, and then the wet composition 238 is applied to the bottom layer 240 in the form of an over-coating or a top layer that is disposed on top of the bottom layer 240 and at least partially surrounding the structures 242. The wet composition 238 can correspond to a dissolved form of a host material and, in particular, can include a dissolved form, a colloidal form, a nanoparticle form, a sol-form of any material previously listed as suitable host materials. It is also contemplated that the wet composition 238 can correspond to a host material precursor, which can be converted into the host material by suitable processing, such as drying, curing, cross-linking, polymerizing, sintering, calcining, or any combination thereof. For example, the wet coating composition 238 can be an over-coating or a top layer that is not fully cured or set, a cross-linkable over-coating or top layer that is not fully cross-linked, which can be subsequently cured or cross-linked using suitable polymerization initiators or cross-linking agents, or an over-coating or a top layer of monomers, oligomers, or a combination of monomers and oligomers, which can be subsequently polymerized using suitable polymerization initiators or cross-linking agents. The wet composition 238 also can be patterned, for instance, with printing methods like screen, reverse offset gravure, flexo, or ink jetprinting, or another method. In some embodiments, the wet composition 238 can include a material with a liquid phase as well as a solid phase, or can include a material that is at least partially liquid or has properties resembling those of a liquid, such as a sol, a semisolid, a gel, and the like. The bottom layer 240 can be transparent or opaque, can be flexible or rigid, and can be composed of, for example, a polymer, an ionomer, EVA, PVB, TPO, TPU, PE, PET, PETG, PMMA, polycarbonate, PVC, PP, an acrylate polymer, ABS, a ceramic, a glass, silicon, a metal (e.g., stainless steel or aluminum), or any combination thereof, as well as any other material previously listed as suitable host materials. The bottom layer 240 can serve as a temporary layer that is subsequently removed during device assembly, or can be retained in a resulting device as a layer or other component of the device.

Next, the wet composition 238 is converted into the host material, which has at least some of the structures 242 partially or fully incorporated within the host material. Suitable processing can be carried out to convert the wet composition 238 into the host material. During device assembly, the host material with the incorporated structures 242 can be laminated or otherwise connected to adjacent device layers, or can serve as a substrate onto which adjacent device layers are formed, laminated, or otherwise applied.

### Patterning of Transparent Conductors

Patterned transparent conductors can be used in, for example, touch sensors, liquid crystal display (or LCD) pixel electrodes, and other electronic and optoelectronic devices. Adequate electrical isolation between conductive traces is desirable to isolate electrical signals to achieve spatial resolution in touch sensing or pixel switching. Adequate transparency of the transparent conductors is desirable to achieve higher display brightness, contrast ratio, image quality, and power consumption efficiency, while adequate electrical conductivity is desirable to maintain high signal-to-noise ratios, switching speeds, refresh rates, response time, and uniformity. For applications where electrical patterning is desirable but optically (e.g., visible to the human eye) observable patterning is undesirable, adequate pattern invisibility or low pattern visibility is desirable. Electrically isolated patterns that are nearly or substantially indistinguishable by the human eye are particularly desirable. Patterning methods that largely or substantially remove conductive material from portions of a substrate generally are not desirable because portions with material removed can be visually distinguished by the human eye from portions without material removal, either under typical room illumination or under high intensity light illumination, such as sunlight exposure or exposure to high intensity visible light from other sources. Additionally, a low-cost, solution-processable patterning method or composition is desired, such as to provide compatibility with ink-jet printing, screen printing, or gravure printing.

In some embodiments, a patterned transparent conductor can include higher sheet conductance portions that are laterally adjacent and spaced apart by lower sheet conductance portions. It will be understood that “lower conductance” or “lower sheet conductance” can encompass an insulating nature in an absolute sense, but need not necessarily refer to such absolute sense. Rather, “lower conductance” more generally can refer to a portion that is sufficiently insulating for purposes of electrical isolation, or can be relative to another portion having a higher sheet conductance. In some embodiments, an electrical contrast between the higher and lower conductance portions can be such that a surface or sheet resistance of the lower conductance portions can be at least about 2 times a sheet resistance of the higher conductance portions, such as at least about 5 times, at least about 10 times, at least about 20 times, at least about 50 times, at least about 100 times, at least about 500 times, at least about 1,000 times, at least about 10,000 times, or at least about 100,000 times, and up to about 1,000,000 times, up to about 10,000,000 times, or more. In some embodiments, a surface or sheet resistance of the lower conductance portions can be at least or greater than about 200 Ω/sq, such as at least about 250 Ω/sq, at least about 300 Ω/sq, at least about 350 Ω/sq, at least about 400 Ω/sq, at least about 500 Ω/sq, at least about 1,000 Ω/sq, at least about 10,000 Ω/sq, or at least about 100,000 Ω/sq, and up to about 1,000,000 Ω/sq, up to about 10,000,000 Ω/sq, or more, while a surface or sheet resistance of the higher conductance portions can be no greater than or less than about 200 Ω/sq, such as no greater than about 150 Ω/sq, no greater than about 100 Ω/sq, no greater than about 75 Ω/sq, no greater than about 50 Ω/sq, no greater than about 25 Ω/sq, no greater than about 20 Ω/sq, no greater than about 15 Ω/sq, or no greater than about 10 Ω/sq, and down to about 1 Ω/sq, down to about 0.1 Ω/sq, or less.

To reduce an optical contrast between higher conductance and lower conductance portions, optical characteristics of the lower conductance portions can sufficiently match optical characteristics of the higher conductance portions. In such manner, the higher and lower conductance portions can yield low visibility patterning, while an electrical contrast is maintained between the higher and lower conductance portions. By sufficiently matching optical characteristics of the higher and lower conductance portions, these portions can be rendered substantially visually indistinguishable or undetectable to the human eye. The extent to which a patterning of the higher and lower conductance portions is visually indistinguishable can be evaluated, for example, across a group of normally sighted human subjects (e.g., in the young to middle adult age range) and under photopic conditions. In some embodiments, the patterning of the higher and lower conductance portions can be deemed substantially visually indistinguishable if the patterning is undetected by at least about 90% of the human subjects, such as at least about 93%, at least about 95%, at least about 97%, at least about 98%, at least about 99%, or more. In some embodiments, the patterning of the higher and lower conductance portions can be deemed substantially visually indistinguishable if a luster of the higher conductance portions and a luster of the lower conductance portions are deemed to be the same by at least about 90% of the human subjects, such as at least about 93%, at least about 95%, at least about 97%, at least about 98%, at least about 99%, or more, where the luster can be evaluated along a scale of, for example, adamantine luster, dull luster, greasy luster, metallic luster, pearly luster, resinous luster, silky luster, submetallic luster, vitreous luster, and wavy luster.

In some embodiments, a difference in light transmittance values (e.g., an absolute difference between transmittance values each expressed as a percentage) of the higher and lower conductance portions can be no greater than about 10%, such as no greater than about 5%, no greater than about 4%, no greater than about 3%, no greater than about 2%, no greater than about 1%, no greater than about 0.5%, no greater than about 0.4%, no greater than about 0.3%, or no greater than about 0.2%, and down to about 0.1%, down to about 0.01%, down to about 0.001%, or less, where the transmittance values can be expressed in terms of human vision or photometric-weighted transmittance, transmittance at a given wavelength or range of wavelengths in the visible range, such as about 550 nm, solar-flux weighted transmittance, transmittance at a given wavelength or range of wavelengths in the infrared range, or transmittance at a given wavelength or range of wavelengths in the ultraviolet range. In some embodiments, a difference in haze values (e.g., transmitted and reflected and expressed as an absolute difference between haze values each expressed as a percentage) of the higher and lower conductance portions can be no greater than about 5%, such as no greater than about 4%, no greater than about 3%, no greater than about 2%, no greater than about 1%, no greater than about 0.5%, no greater than about 0.4%, no greater than about 0.3%, no greater than about 0.2%, or no greater than 0.1%, and down to about 0.05%, down to about 0.01%, down to about 0.001%, or less, where the haze values can be expressed as human vision or photometric-weighted haze, haze at a given wavelength or range of wavelengths in the visible range, such as about 550 nm, solar-flux weighted haze, haze at a given wavelength or range of wavelengths in the infrared range, or haze at a given wavelength or range of wavelengths in the ultraviolet range. In some embodiments, a difference in light absorbance values (e.g., an absolute difference between absorbance values each expressed as a percentage) of the higher and lower conductance portions can be no greater than about 10%, such as no greater than about 5%, no greater than about 4%, no greater than about 3%, no greater than about 2%, no greater than about 1%, no greater than about 0.5%, no greater than about 0.4%, no greater than about 0.3%, or no greater than about 0.2%, and down to about 0.1%, down to about 0.01%, down to about 0.001%, or less, where the absorbance values can be expressed as human vision or photometric-weighted absorbance, absorbance at a given wavelength or range of wavelengths in the visible range, such as about 550 nm, solar-flux weighted absorbance, absorbance at a given wavelength or range of wavelengths in the infrared range, or absorbance at a given wavelength or range of wavelengths in the ultraviolet range. In some embodiments, a difference in reflectance values (e.g., an absolute difference between diffuse reflectance values each expressed as a percentage) of the higher and lower conductance portions can be no greater than about 10%, such as no greater than about 5%, no greater than about 4%, no greater than about 3%, no greater than about 2%, no greater than about 1%, no greater than about 0.5%, no greater than about 0.4%, no greater than about 0.3%, or no greater than about 0.2%, and down to about 0.1%, down to about 0.01%, down to about 0.001%, or less, where the reflectance values can be expressed as human vision or photometric-weighted reflectance, reflectance at a given wavelength or range of wavelengths in the visible range, such as about 550 nm, solar-flux weighted reflectance, reflectance at a given wavelength or range of wavelengths in the infrared range, or reflectance at a given wavelength or range of wavelengths in the ultraviolet range. In some embodiments, a difference between corresponding pairs of color stimulus values of the higher and lower conductance portions (e.g., an absolute difference between a corresponding pair of color stimulus values expressed as a percentage relative to either of the color stimulus values) can be no greater than about 10%, such as no greater than about 5%, no greater than about 4%, no greater than about 3%, no greater than about 2%, no greater than about 1%, no greater than about 0.5%, no greater than about 0.4%, no greater than about 0.3%, or no greater than about 0.2%, and down to about 0.1%, down to about 0.01%, down to about 0.001%, or less, where the color stimulus values can be parameters in a suitable color space, such as the International Commission on Illumination (or CIE) 1931 RGB and CIE 1931 XYZ color spaces.

In some embodiments, patterning of transparent conductors can be carried out by applying a spatially selective or varying treatment to inhibit or disrupt percolation over portion or potions where electrical conductivity is not desired, such as by inhibiting the formation of a percolating network, inhibiting electrical conductivity of the percolating network, or rendering a percolating network non-percolating by some mechanism or action, such as breaking or severing individual conductive structures of a pre-formed percolating network to render the network non-percolating, or any combination thereof. It should be understood that inhibition of percolation can encompass full or substantially full inhibition of percolation as well as partial inhibition of percolation (or a reduction in percolation). Thus, for example, a percolation-inhibition treatment or composition as characterized herein also can encompass a percolation-reducing treatment or composition. Also, a percolation-inhibition treatment or composition as characterized herein also can encompass an electrical conductivity modifying treatment or composition (e.g., a paste or an ink), in which one or more electrical conductivity modifying agents are applied to inhibit or disrupt percolation.

In physical inhibition of percolation, conductive structures embedded or incorporated in portions intended to become lower conductance portions are treated to inhibit effective physical contact with one another to form a percolating network, whereas conductive structures embedded or incorporated in higher conductance portions can contact one another, resulting in a percolating network of the conductive structures in the higher conductance portions. Physical inhibition of percolation can involve introducing spacer agents between the structures in the portions intended to become lower conductance portions to inhibit effective contact and electron conduction across junctions. In chemical inhibition of percolation, conductive structures embedded or incorporated in portions intended to become lower conductance portions are exposed to a chemical agent or otherwise chemically treated to inhibit effective contact with one another to form a percolating network, whereas conductive structures embedded or incorporated in higher conductance portions can contact one another, resulting in a percolating network in the higher conductance portions. Chemical inhibition of percolation can involve introducing chemical agents that chemically bind to, or surface functionalize, or react with, the structures in the lower conductance portions to inhibit effective contact and electron conduction across junctions. In inhibition of percolation through degradation, conductive structures embedded or incorporated in portions intended to become lower conductance portions are exposed to a chemical agent or otherwise chemically treated to inhibit or inactivate electron conduction across different structures. Inhibition of percolation through degradation can involve degrading junctions between conductive structures, degrading the structures themselves, such as by dissolving or fragmenting the structures or converting the structures into structures with higher resistivity, or both. It will be understood that the classification of “physical,” “chemical,” and “degradation” manners of inhibiting percolation is for ease of presentation, and that certain treatments can inhibit percolation through a combination of two or more of “physical,” “chemical,” and “degradation” manners of inhibiting percolation. Inhibition of percolation also can be accomplished through interaction between an electrical conductivity modifying agent with a component of a percolating network of conductive structures other than the structures themselves, to reduce a conductivity of the network.

In the case of physical inhibition of percolation, suitable spacer agents can be nano-sized or micron-sized, and can be formed of, or can include, insulating materials, such as ceramics (e.g., in the form of nanoparticles or other nano-sized objects formed of metal and non-metal oxides and chalcogenides, such as fumed silica or other forms of silica, and titanium dioxide) and organic materials (e.g., in the form of molecules, monomers, oligomers, and low molecular weight polymers). One or more spacer agents can be dispersed in a suitable composition, which can include a thickener (or a viscosity modifier) and a solvent or other carrier fluid, and the composition can be applied in a substantially uniform manner or in a spatially selective or varying manner. In some embodiments, the composition also can include an embedding fluid to promote surface embedding of the spacer agents, such that the spacer agents are at least partially embedded into a host material, and at least some of the spacer agents are located between conductive structures in the host material to inhibit effective contact and electron conduction across junctions. A relatively small size of the spacer agents can promote their embedding into the host material and localization of at least some of the spacer agents in between structures. The composition also can include an anti-oxidant to protect the spacer agents during storage.

For example, nanoparticles or other nano-sized objects formed of an insulating material can be suitable spacer agents. In the case of nanoparticles or other nano-sized objects formed of titanium dioxide, the nanoparticles can serve a dual function of physically spacing apart structures as well as a degradation function, such as by photo-catalyzing the conversion of water into oxygen that can oxidize surfaces of the structures. As another example, suitable spacer agents can include one or more of organic molecules, organic monomers, organic oligomers, and low molecular weight organic polymers (e.g., having a number or a weight average molecular weight of about 20,000 or less, about 10,000 or less, about 5,000 or less, or about 1,000 or less) having substantially the same or a similar chemical composition as a host material in which structures are embedded or incorporated, having substantially the same or a similar solubility parameter as the host material, or both. Inorganic analogs of organic molecules, organic monomers, organic oligomers, and low molecular weight organic polymers also can be used as spacer agents. Monomers, oligomers, and polymers can be ultraviolet-curable or polymerizable, and examples of polymers and associated monomers and oligomers include those previously listed as suitable host materials. Starches and other polysaccharides also can be suitable spacer agents. Further examples of suitable spacer agents include foaming agents that can yield gas bubbles, and materials that can expand when heated or otherwise energized.

In the case of chemical inhibition of percolation, suitable chemical agents can be sub-nano-sized, nano-sized, or micron-sized, and can be in the form of molecules, monomers, oligomers, and low molecular weight polymers that are terminated, derivatized, or substituted with one or more types of functional groups having an affinity with, or are capable of forming a chemical bond with, conductive structures. One or more chemical agents can be dispersed in a suitable composition, which can include a thickener (or a viscosity modifier) and a solvent or other carrier fluid, and the composition can be applied in a substantially uniform manner or in a spatially selective or varying manner. In some embodiments, the composition also can include an embedding fluid to promote surface embedding of the chemical agents, such that the chemical agents are at least partially embedded into a host material, and at least some of the chemical agents are chemical bound to, or surface functionalize, conductive structures in the host material to inhibit effective contact and electron conduction across junctions. A relatively small size of the chemical agents can promote their embedding into the host material and localization of at least some of the chemical agents surrounding the conductive structures. The composition also can include an anti-oxidant to protect the chemical agents during storage, as well as anti-colorants or anti-yellowing agents to protect against possible discoloration resulting from the chemical agents.

Examples of chemical bonds include covalent, ionic, and coordination bonds, and examples of suitable functional groups include:

(1) thiol group, which refers to —SH;

(2) amino group, which refers to —NH₂;

(3) N-substituted amino group, which refers to an amino group that has a set of its hydrogen atoms replaced by a set of substituent groups. Examples of N-substituted amino groups include —NRR′, where R and R′ are selected from hydride groups, alkyl groups, alkenyl groups, alkynyl groups, and aryl groups, and at least one of R and R′ is not a hydride group;

(4) hydroxyl group, which refers to —OH;

(5) cyano group, which refers to —CN;

(6) nitro group, which refers to —NO₂;

(7) amide group, which refers to —(C═O)NH₂;

(8) N-substituted amide group, which refers to an amide group that has a set of its hydrogen atoms replaced by a set of substituent groups. Examples of N-substituted amide groups include —(C═O)NRR′, where R and R′ are selected from hydride groups, alkyl groups, alkenyl groups, alkynyl groups, and aryl groups, and at least one of R and R′ is not a hydride group;

(9) carboxy group, which refers to —(C═O)OH;

(10) urea group, which refers to —NH(C═O)NH₂;

(11) ether group, which refers to —O—;

(12) functional groups that act as electron donors (e.g., Lewis bases) and electron acceptors (e.g., Lewis acids);

(13) phosphorus-containing groups, such as phosphines;

(14) carbonyl group, which refers to —(C═O)—; and

(15) combinations of two or more of the foregoing.

For example, suitable chemical agents can include one or more of thiol-terminated small molecules, oligomers, or polymers; surfactants; molecular ligands (e.g., crown ethers); and oligomers and polymers that include electron donating functional groups (e.g., poly(ethylene oxide)). In the case of chemical agents that are terminated, derivatized, or substituted with thiol groups, the chemical agents can serve a dual function of surface functionalizing conductive structures to physically space apart the structures as well as a degradation function, such as by sulfidation of surfaces of the structures, such as promoting the formation of silver sulfide in the case of silver nanowires. Examples of suitable thiol-containing chemical agents include those having the formula: R—SH where R is an alkyl, alkenyl, alkynyl, or aryl group, a polysiloxane group, or a derivative thereof. Examples of suitable phosphorus-containing chemical agents include those having the formula: P(R)(R′)(R″) where P is phosphorus, and R, R′ and R″ are independently selected from hydride, alkyl, alkenyl, alkynyl, aryl, and polysiloxane groups, or derivatives thereof. For example, a suitable phosphorus-containing chemical agent is triphenyl phosphine.

Suitable chemical agents can have substantially the same or a similar chemical composition as a host material in which conductive structures are embedded or incorporated, can have substantially the same or a similar solubility parameter as the host material, or both. Inorganic analogs of organic molecules, organic monomers, organic oligomers, and low molecular weight organic polymers also can be used as chemical agents. Monomers, oligomers, and polymers can be ultraviolet-curable or polymerizable, and examples of polymers and associated monomers and oligomers include those previously listed as suitable host materials that include or are terminated, derivatized, or substituted with suitable functional groups.

Inhibition of percolation through degradation can be accomplished by chemical agents or other treatments that chemically react with, degrade, or otherwise modify surfaces of conductive structures to render the surfaces less electrically conductive, or damage, break, fragment, etch, or dissolve the structures (selectively, preferentially, partially, or wholly). To attain low visibility patterning, inhibition of percolation through degradation can involve a balance between sufficient degradation to reduce an electrical conductivity of a percolating network in lower conductance portions without excessive degradation that would result in undesirable optical contrast between the lower conductance portions and higher conductance portions.

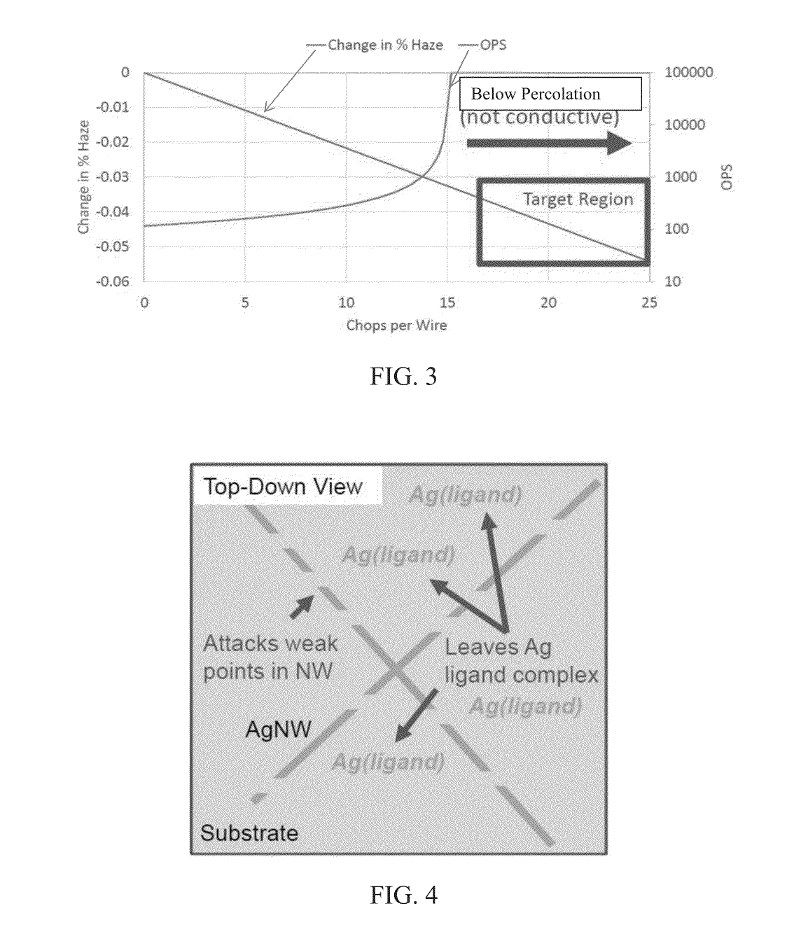

In some embodiments for the case of nanowires or other high aspect ratio nanostructures, inhibition of percolation through degradation can attain such a balance through a chopping or cleaving mechanism or action, in which nanowires are severed at one or more locations along their lengths to result in shorter or lower aspect ratio nanowires or other nanostructures. FIG. 3 illustrates an example of modeling a cleaving mechanism, in which a change in haze and a change in sheet resistance (in terms of Ω/sq or OPS) are plotted versus a number of breaks introduced per nanowire in an initially percolating network of nanowires. Electrical percolation depends on nanowire length. Above a percolation threshold, the network is electrically conductive, while the network is insulating or non-percolating below the percolation threshold. Shorter nanowires typically have a higher percolation threshold, in terms of a surface area coverage or a loading level of the nanowires in the network. As shown in FIG. 3, the cleaving mechanism can increase a sheet resistance of the network of nanowires by introducing breaks in the nanowires and thereby decreasing a length of the nanowires. The cleaving mechanism causes a percolation threshold to rise to a level equal to or above a surface area coverage or a loading level of the nanowires, at which point the sheet resistance increases sharply. A material of the nanowires is removed from the breaks, thereby reducing a surface area coverage or a loading level of the nanowires and reducing haze compared to the initially percolating network of nanowires in the absence of the breaks. In the example of FIG. 3, low visibility patterning can be attained by controlling the number of breaks per nanowire (and the size of the breaks) to within a target region that yields a sufficiently high sheet resistance for high electrical contrast while maintaining a sufficiently small change in haze for low optical contrast.

FIG. 4 illustrates an example schematic of metallic nanowires, here silver nanowires (or AgNWs), subjected to a chopping or cleaving mechanism or action, in which the nanowires are severed at one or more locations along their lengths. Without wishing to be bound by a particular theory, certain chemical agents can act by preferentially or selectively degrading silver nanowires at locations including a silver halide, such as silver chloride or silver bromide, which is included in the silver nanowires as synthesized. For example, silver nanowires, or other silver-containing nanostructures or microstructures, can include a weight percentage of a halide, such as in the form of chlorine or bromine, in the range of about 0.05% to about 20%, such as from about 0.05% to about 15%, from about 0.05% to about 10%, from about 0.05% to about 5%, from about 0.05% to about 4%, from about 0.05% to about 3%, from about 0.05% to about 2%, from about 0.1% to about 20%, from about 0.1% to about 15%, from about 0.1% to about 10%, from about 0.1% to about 5%, from about 0.1% to about 4%, from about 0.1% to about 3%, from about 0.1% to about 2%, from about 1% to about 20%, from about 1% to about 15%, from about 1% to about 10%, from about 1% to about 5%, from about 1% to about 4%, from about 1% to about 3%, from about 1% to about 2%, from about 5% to about 20%, from about 5% to about 15%, from about 5% to about 10%, about 10% to about 20%, from about 10% to about 15%, or from about 15% to about 20%. Certain chemical agents can act as ligands that solubilize a silver halide included in the silver nanowires by forming complexes with silver ion, thereby severing the silver nanowires at locations including the silver halide. Alternatively, or in combination, certain chemical agents can act by preferentially or selectively degrading the silver nanowires at locations including another oxidized form of silver, such as silver oxide (or Ag₂O) or silver sulfide, or at defects, dislocations, or other locations along the silver nanowires.

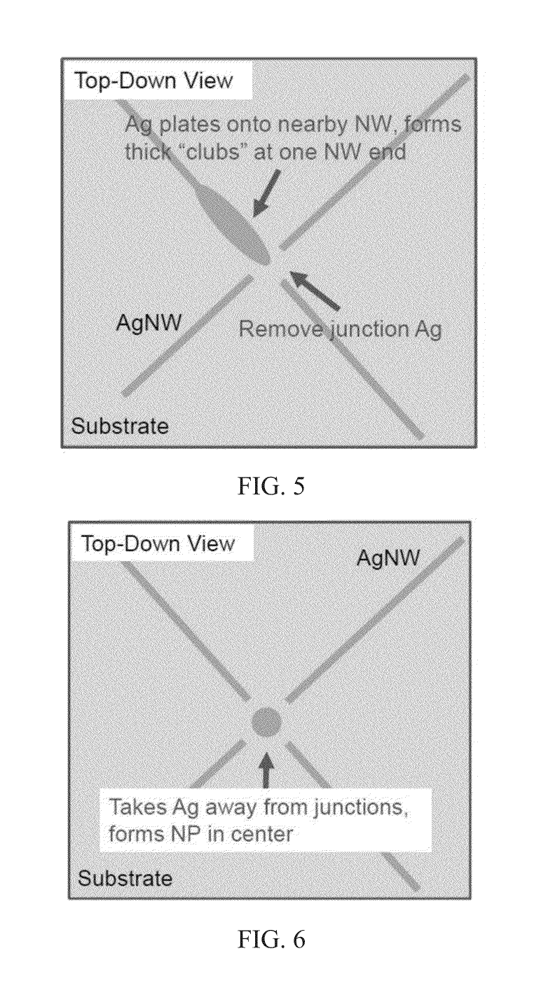

FIG. 5 illustrates an example schematic of metallic nanowires, here silver nanowires (or AgNWs), subjected to a chopping or cleaving mechanism or action, in which junctions between the nanowires are preferentially or selectively degraded to sever the nanowires at the junctions and to remove silver from the junctions, along with a migration or re-deposition of silver onto intact or severed nanowires adjacent to the junctions. Without wishing to be bound by a particular theory, certain chemical agents can act by preferentially or selectively degrading silver nanowires at locations including a silver halide, such as silver chloride or silver bromide, which is included in the silver nanowires as synthesized, although the cleaving mechanism also can include degradation of the silver nanowires at locations including another oxidized form of silver, such as silver oxide (or Ag₂O) or silver sulfide, or at defects, dislocations, or other locations along the silver nanowires. Certain chemical agents can act as ligands that solubilize a silver halide included in the silver nanowires by forming complexes with silver ion, thereby severing the silver nanowires at locations including the silver halide; in combination, the same or additional chemical agents can act as reductants that reduce silver ion in the complexes to yield a migration or re-deposition of silver. This migration or re-deposition of silver can increase haze to at least partially offset haze reduction that results from the removal of silver from the junctions, and can result in at least some severed or intact nanowires having larger diameters at their end portions or along other portions of their lengths, as compared to their original diameters prior to percolation-inhibiting treatment.

FIG. 6 illustrates an example schematic of metallic nanowires, here silver nanowires (or AgNWs), subjected to a chopping or cleaving mechanism or action, in which junctions between the nanowires are preferentially or selectively degraded to sever the nanowires at the junctions and to remove silver from the junctions, along with a migration or re-deposition of silver as silver nanoparticles (or AgNPs) or other silver-containing nanostructures at the junctions. This migration or re-deposition of silver also can occur elsewhere beyond the junctions. Without wishing to be bound by a particular theory, certain chemical agents can act by preferentially or selectively degrading silver nanowires at locations including a silver halide, such as silver chloride or silver bromide, which is included in the silver nanowires as synthesized, although the cleaving mechanism also can include degradation of the silver nanowires at locations including another oxidized form of silver, such as silver oxide (or Ag₂O) or silver sulfide, or at defects, dislocations, or other locations along the silver nanowires. Certain chemical agents can act as ligands that solubilize a silver halide included in the silver nanowires by forming complexes with silver ion, thereby severing the silver nanowires at locations including the silver halide; in combination, the same or additional chemical agents can act as reductants that reduce silver ion in the complexes to yield a migration or re-deposition of silver as silver nanoparticles. This migration or re-deposition of silver can increase haze to at least partially offset haze reduction that results from the removal of silver from the junctions.

Combinations of two or more of the foregoing cleaving mechanisms can be attained in some embodiments. For example, nanowires can be severed at one or more locations along their lengths, along with a migration or re-deposition of silver onto intact or severed nanowires as well as a migration or re-deposition of silver as silver nanoparticles or other silver-containing nanostructures.

By subjecting conductive structures to balanced or partial degradation according to a cleaving mechanism, low visibility patterning can be attained. For example, a surface area coverage (e.g., expressed as a percentage) of conductive structures in lower conductance portions can be less than, or no greater than, a corresponding surface area coverage of conductive structures in higher conductance portions, but the surface area coverage of the conductive structures in the lower conductance portions can be maintained to within at least about 5% of the surface area coverage of the conductive structures in the higher conductance portions, such as at least about 10%, at least about 13%, at least about 15%, at least about 17%, at least about 20%, at least about 23%, at least about 25%, at least about 27%, at least about 30%, at least about 33%, at least about 35%, at least about 37%, at least about 40%, at least about 43%, at least about 45%, at least about 47%, at least about 50%, at least about 53%, at least about 55%, at least about 57%, at least about 60%, at least about 63%, at least about 65%, at least about 67%, at least about 70%, at least about 73%, at least about 75%, at least about 77%, or at least about 80%, and up to about 85%, up to about 87%, up to about 90%, up to about 93%, up to about 95%, or more. Surface area coverage can be based on image analysis of one or more images, such as one or more scanning electron microscopy (or SEM) images, with an area occupied by conductive structures in an image corresponding to pixels having brightness or other intensity values at or above a threshold value (or at or below a threshold value in other implementations), and can be calculated relative to an area sample size of, for example, at least about 200 μm×about 200 μm, at least about 250 μm×about 250 μm, or at least about 500 μm×about 500 μm.

As another example, a loading level of an electrically conductive or semiconducting material, such as silver or another metal in the case of metallic nanowires, in lower conductance portions can be less than, or no greater than, a corresponding loading level of the electrically conductive or semiconducting material in higher conductance portions, but the loading level in the lower conductance portions can be maintained to within at least about 5% of the loading level in the higher conductance portions, such as at least about 10%, at least about 13%, at least about 15%, at least about 17%, at least about 20%, at least about 23%, at least about 25%, at least about 27%, at least about 30%, at least about 33%, at least about 35%, at least about 37%, at least about 40%, at least about 43%, at least about 45%, at least about 47%, at least about 50%, at least about 53%, at least about 55%, at least about 57%, at least about 60%, at least about 63%, at least about 65%, at least about 67%, at least about 70%, at least about 73%, at least about 75%, at least about 77%, or at least about 80%, and up to about 85%, up to about 87%, up to about 90%, up to about 93%, up to about 95%, or more. Loading levels can be expressed in terms of weight of an electrically conductive or semiconducting material per unit area, and can be derived based on input coating solution and method parameters (e.g., a material loading in solution, a solution injection rate, or a coated wet thickness), microscopic analysis (e.g., by scanning electron microscopy, atomic force microscopy, or other techniques), or spectroscopic analysis, such as Rutherford backscattering spectroscopy.

As another example, among nanowires in higher and lower conductance portions, an average, a median, or a mode length of nanowires in the lower conductance portions can be less than an average, a median, or a mode length of nanowires in the higher conductance portions, but can be kept within about 1/200 of the average, median, or mode length of the nanowires in the higher conductance portions, such as within about 1/150, within about 1/130, within about 1/100, within about 1/70, within about 1/50, within about 1/45, within about 1/40, within about 1/35, within about 1/30, within about 1/25, within about 1/20, within about 1/15, within about 1/10, within about 1/9, within about ⅛, within about 1/7, within about ⅙, within about ⅕, within about ¼, within about ⅓, or within about ½. For example, an average, a median, or a mode length of the nanowires in the lower conductance portions can be less than an average, a median, or a mode length of the nanowires in the higher conductance portions, but can be kept in the range of about 1/200 to about 9/10 of the average, median, or mode length of the nanowires in the higher conductance portions, such as about 1/200 to about ⅘, about 1/150 to about ⅘, about 1/130 to about ⅘, about 1/100 to about ⅘, about 1/70 to about ⅘, about 1/50 to about ⅘, about 1/45 to about ⅘, about 1/40 to about ⅘, about 1/35 to about ⅘, about 1/30 to about ⅘, about 1/25 to about ⅘, about 1/20 to about ⅘, about 1/15 to about ⅘, about 1/10 to about ⅘, about 1/9 to about ⅘, about ⅛ to about ⅘, about 1/7 to about ⅘, about ⅙ to about ⅘, about ⅕ to about ⅘, about ¼ to about ⅘, about ⅓ to about ⅘, or about ½ to about ⅘. Nanowire lengths can be based on image analysis of one or more images, such as one or more SEM images, and can be calculated relative to a sample size of nanowires in the images of, for example, at least 50 nanowires, at least 100 nanowires, at least 200 nanowires, or at least 500 nanowires.

As another example, among nanowires in higher and lower conductance portions, an average, a median, or a mode aspect ratio of nanowires in the lower conductance portions can be less than an average, a median, or a mode aspect ratio of nanowires in the higher conductance portions, but can be kept within about 1/200 of the average, median, or mode aspect ratio of the nanowires in the higher conductance portions, such as within about 1/150, within about 1/130, within about 1/100, within about 1/70, within about 1/50, within about 1/45, within about 1/40, within about 1/35, within about 1/30, within about 1/25, within about 1/20, within about 1/15, within about 1/10, within about 1/9, within about ⅛, within about 1/7, within about ⅙, within about ⅕, within about ¼, within about ⅓, or within about ½. For example, an average, a median, or a mode aspect ratio of the nanowires in the lower conductance portions can be less than an average, a median, or a mode aspect ratio of the nanowires in the higher conductance portions, but can be kept in the range of about 1/200 to about 9/10 of the average, median, or mode aspect ratio of the nanowires in the higher conductance portions, such as about 1/200 to about ⅘, about 1/150 to about ⅘, about 1/130 to about ⅘, about 1/100 to about ⅘, about 1/70 to about ⅘, about 1/50 to about ⅘, about 1/45 to about ⅘, about 1/40 to about ⅘, about 1/35 to about ⅘, about 1/30 to about ⅘, about 1/25 to about ⅘, about 1/20 to about ⅘, about 1/15 to about ⅘, about 1/10 to about ⅘, about 1/9 to about ⅘, about ⅛ to about ⅘, about 1/7 to about ⅘, about ⅙ to about ⅘, about ⅕ to about ⅘, about ¼ to about ⅘, about ⅓ to about ⅘, or about ½ to about ⅘. Nanowire aspect ratios can be based on image analysis of one or more images, such as one or more SEM images, and can be calculated relative to a sample size of nanowires in the images of, for example, at least 50 nanowires, at least 100 nanowires, at least 200 nanowires, or at least 500 nanowires.

As a further example for the case where a cleavage mechanism involves re-deposition of silver or another material as nanoparticles, a percentage by number of nanoparticles relative to all nanostructures in a lower conductance portion can be greater than a percentage by number of nanoparticles relative to all nanostructures in a higher conductance portion, such as where the percentage by number of nanoparticles in the lower conductance portion is at least about 1.1 times, at least about 1.2 times, at least about 1.3 times, at least about 1.5 times, at least about 1.7 times, at least about 2 times, at least about 2.5 times, at least about 3 times, at least about 4 times, at least about 5 times, at least about 10 times, at least about 15 times, or at least about 20 times the corresponding percentage by number of nanoparticles in the higher conductance portion, and where the percentage by number of nanoparticles in the lower conductance portion is at least about 0.3%, at least about 0.5%, at least about 0.7%, at least about 1%, at least about 2%, at least about 3%, at least about 4%, at least about 5%, at least about 6%, at least about 7%, at least about 8%, at least about 9%, at least about 10%, at least about 11%, at least about 12%, at least about 13%, at least about 14%, at least about 15%, at least about 20%, at least about 25%, or at least about 30%, and up to about 35%, up to about 40%, up to about 45%, or more.

In the case of inhibition of percolation through degradation, suitable chemical agents can include at least one complexing agent (or ligand), or a combination of at least one complexing agent and at least one reducing agent (or reductant or an anti-oxidant).

In some embodiments for the case of metallic nanowires or other conductive structures formed of, or including, a metal, a suitable complexing agent for the metal can solubilize an oxidized form of the metal, such as an ionic form of the metal as metal ions, by forming complexes with the metal ions. The oxidized form of the metal can be included in the conductive structures as synthesized, can be formed in situ as part of surface embedding or otherwise incorporating the conductive structures into a host material, can be formed in situ as part of percolation-inhibition treatment, such as through action of water or dissolved oxygen, or a combination of two or more of the foregoing. By solubilizing the oxidized form of the metal, the complexing agent can dissolve or sever the conductive structures at locations including the oxidized form of the metal.

A suitable complexing agent (designated as L) for a metal (an ionic form of the metal designated as M, where the metal has an oxidation state such as 1+, 2+, 3+, and so forth) can drive a reaction or an equilibrium towards the formation of a metal-ligand complex (designated as ML), such as according to:

M+L→ML (1)

M+nL→MLₙ, n is an integer≧2 (2)

where a metal-ligand stability parameter (or constant) can be used to characterize an extent to which the reactions (1) and (2) are driven towards the formation of a metal-ligand complex and, hence, a strength of binding or affinity of the complexing agent for the metal, and, in the case of reaction (1), the metal-ligand stability parameter can be designated as K₁=[ML]/[M][L], and, in the case of reaction (2), the metal-ligand stability parameter can be designated as βₙ=[MLₙ]/[M][L]ⁿ. Values for metal-ligand stability parameters and associated test conditions can be obtained from, for example, the International Union of Pure and Applied Chemistry (or IUPAC) Stability Constants Database, available from Academic Software. For example, where M is Ag⁺, thiosulfate has a value for log₁₀K₁ of about 9.47 and a value for log₁₀β₂ of about 13.15, ethylenediaminetetraacetic acid has a value for log₁₀K₁ of about 7.3, thiocyanate has a value for log₁₀K₁ of about 3.64 and a value for log₁₀β₂ of about 5.56, ethylenediamine has a value for log₁₀K₁ of about 5.05 and a value for log₁₀β₂ of about 11.12, chloride has a value for log₁₀K₁ of about 3.23 and a value for log₁₀β₂ of about 5.15, and ammonia has a value for log₁₀K₁ of about 3.22 and a value for log₁₀β₂ of about 7.21. More generally, and with respect to the metal M, suitable complexing agents of some embodiments can have at least one, or both, of log₁₀K₁ and log₁₀β₂ greater than 1, such as at least or greater than about 2, at least about 2.5, at least about 3, at least about 3.5, at least about 4, at least about 4.5, at least about 5, at least about 5.5, or at least about 6. In embodiments in which a complexing agent is used in combination with a reducing agent, selection of the complexing agent can involve a balance between sufficient strength of binding or affinity of the complexing agent for a metal without excessive or largely irreversible binding or affinity for the metal that would impede a reduction function of the reducing agent. In such embodiments, suitable complexing agents can have log₁₀K₁ within the above-stated ranges but no greater than about 9.4, such as no greater than about 9, no greater than about 8.5, no greater than about 8, no greater than about 7.5, or no greater than about 7, and can have log₁₀β₂ within the above-stated ranges but no greater than about 13, such as no greater than about 12.5 or no greater than about 12.

Examples of suitable chemical agents that can act as complexing agents (or as sources of complexing agents or ligands) include Group 15 element-containing (e.g., nitrogen-containing) compounds or Lewis bases, and can be in the form of small molecules, monomers, oligomers, and polymers that are terminated, derivatized, or substituted with one or more types of Group 15 element-containing functional groups or that include one or more Group 15 element atoms or Group 15 element-containing groups, such as in backbone structures of oligomers or polymers. Examples of suitable Group 15 element-containing compounds include organic and inorganic amines, such as ammonia, primary organic amines (cyclic or acyclic, unsaturated or saturated) and polyamines (linear, branched, or dendritic), secondary organic amines (cyclic or acyclic, unsaturated or saturated) and polyamines (linear, branched, or dendritic), and tertiary organic amines (cyclic or acyclic, unsaturated or saturated) and polyamines (linear, branched, or dendritic), such as polylysine, aziridine, aziridine-based compounds, derivatized aziridine-based compounds, polyethylenimine (linear, branched, or dendritic), and phosphorus, arsenic, antimony, and bismuth analogues of the foregoing compounds as well as derivatized versions of the foregoing compounds.

Examples of suitable amines include those having the formula: N(R)(R′)(R″) where R, R′ and R″ are independently selected from hydride groups, alkyl groups, alkenyl groups, alkynyl groups, aryl groups, other unsaturated or saturated, linear or branched hydrocarbon groups (e.g., hydrocarbon groups including from 1-20, 1-15, 1-10, 1-8, or 1-5 carbon atoms), poly(alkylene oxide) groups, siloxane or polysiloxane groups, and derivatives thereof. Phosphorus, arsenic, antimony, and bismuth analogues of the foregoing compounds are also contemplated, such as where nitrogen is replaced by phosphorus, arsenic, antimony, or bismuth.

Examples of suitable polyamines include those having the formula: R₂N((CₙR₂ₙ)ₓNR)ₐ(CₘR₂ₘ)_{y}NR₂, where R is a hydride group, an alkyl group, an alkenyl group, an alkynyl group, an aryl group, another unsaturated or saturated, linear or branched hydrocarbon group (e.g., hydrocarbon groups including from 1-20, 1-15, 1-10, 1-8, or 1-5 carbon atoms), a poly(alkylene oxide) group, a siloxane or a polysiloxane group, or a derivative thereof, and n, m, x, y, a are integers each independently ≧0 or ≧1 (e.g., 0 or more, 1 or more, 2 or more, 3 or more, 4 or more, 5 or more, or 6 or more). The formula also can be generalized as RR′N((CₙR″₂ₙ)ₓNR′″)ₐ(CₙR″″₂ₘ)_{y}NR′″″R″″″, where the various R groups are independently selected from hydride groups, alkyl groups, alkenyl groups, alkynyl groups, aryl groups, other unsaturated or saturated, linear or branched hydrocarbon groups (e.g., hydrocarbon groups including from 1-20, 1-15, 1-10, 1-8, or 1-5 carbon atoms), poly(alkylene oxide) groups, siloxane or polysiloxane groups, and derivatives thereof, and n, m, x, y, a are integers each independently ≧0 or ≧1 (e.g., 0 or more, 1 or more, 2 or more, 3 or more, 4 or more, 5 or more, or 6 or more). Additional examples of suitable polyamines include those having the formula: RR′N—[(R″)ₓ—NR′″—(R″″)_{y}]_{z}—NR′″″R″″″, where the R, R′, R′″, R′″″, and R″″″ groups are independently selected from hydride groups, alkyl groups, alkenyl groups, alkynyl groups, aryl groups, other unsaturated or saturated, linear or branched hydrocarbon groups (e.g., hydrocarbon groups including from 1-20, 1-15, 1-10, 1-8, or 1-5 carbon atoms), poly(alkylene oxide) groups, siloxane or polysiloxane groups, and derivatives thereof, and the R″ and R″″ groups are independently selected from alkylene groups (e.g., methylene or —CH₂— and ethylene or —CH₂—CH₂—), alkenylene groups, alkynylene groups, arylene groups, other unsaturated or saturated, linear or branched hydrocarbon groups (e.g., hydrocarbon groups including from 1-20, 1-15, 1-10, 1-8, or 1-5 carbon atoms), poly(alkylene oxide) groups, siloxane or polysiloxane groups, and derivatives thereof, and x, y, z are integers each independently ≧0 or ≧1 (e.g., 0 or more, 1 or more, 2 or more, 3 or more, 4 or more, 5 or more, or 6 or more). Phosphorus, arsenic, antimony, and bismuth analogues of the foregoing compounds are also contemplated, such as where at least one nitrogen in the foregoing formulas are replaced by phosphorus, arsenic, antimony, or bismuth.

Additional examples of suitable polyamines and Group 15 element analogues of polyamines include those having the formula:

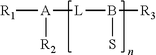

where R₁, R₂, R₃, and S are independently selected from hydride groups, alkyl groups, alkenyl groups, alkynyl groups, aryl groups, other unsaturated or saturated, linear or branched hydrocarbon groups (e.g., hydrocarbon groups including from 1-20, 1-15, 1-10, 1-8, or 1-5 carbon atoms), poly(alkylene oxide) groups, siloxane or polysiloxane groups, and derivatives thereof, L is selected from alkylene groups, alkenylene groups, alkynylene groups, arylene groups, other unsaturated or saturated, linear or branched hydrocarbon groups (e.g., hydrocarbon groups including from 1-20, 1-15, 1-10, 1-8, or 1-5 carbon atoms), poly(alkylene oxide) groups, siloxane or polysiloxane groups, and derivatives thereof, A and B are independently selected from nitrogen, phosphorus, arsenic, antimony, and bismuth, and n is an integer≧0 or ≧1 (e.g., 0 or more, 1 or more, 2 or more, 3 or more, 4 or more, 5 or more, or 6 or more), and
where for n>1:

L in different ones of the n units can be the same or different, and are independently selected from alkylene groups, alkenylene groups, alkynylene groups, arylene groups, other unsaturated or saturated, linear or branched hydrocarbon groups, poly(alkylene oxide) groups, siloxane or polysiloxane groups, and derivatives thereof,

S in different ones of the n units can be the same or different, and are independently selected from hydride groups, alkyl groups, alkenyl groups, alkynyl groups, aryl groups, other unsaturated or saturated, linear or branched hydrocarbon groups, poly(alkylene oxide) groups, siloxane or polysiloxane groups, and derivatives thereof, and

B in different ones of the n units can be the same or different, and are independently selected from nitrogen, phosphorus, arsenic, antimony, and bismuth.

Specific examples of amines and polyamines include ammonia, bis(hexamethylene)triamine (or H₂N—(CH₂)₆—NH—(CH₂)₆—NH₂), ethylenediamine (or H₂N—(CH₂)₂—NH₂), diethylenetriamine (or H₂N—(CH₂)₂—NH—(CH₂)₂—NH₂), octylamine (or CH₃—(CH₂)₇—NH₂), decylamine (or CH₃—(CH₂)₉—NH₂), triethylenetetraamine (or H₂N—(CH₂)₂—NH—(CH₂)₂—NH—(CH₂)₂—NH₂), N-methylethylenediamine (or CH₃—NH—(CH₂)₂—NH₂), N,N′-dimethylethylenediamine (or (CH₃)₂N—(CH₂)₂—NH₂), N,N,N′-trimethylethylenediamine (or CH₃—NH—(CH₂)₂—N(CH₃)₂), N,N′-diisopropylethylenediamine (or (CH₃)₂CH—NH—(CH₂)₂—N—CH(CH₃)₂), and tetraethylpentaamine (or H₂N—(CH₂)₂—NH—(CH₂)₂—NH—(CH₂)₂—NH—(CH₂)₂—NH₂). Other specific examples of amines and polyamines include ethylenediamine tetraacetic acid, imidazoles (e.g., di-imidazole and tri-imidazole), pyrimidine, purine, spermine, urea, lysine, ethanolamine hydrochloride, hydantoin, thiourea, and amine-oxides (or oxidized amines). Further examples include aminated polymers, such as poly(vinylamine) and related copolymers. In some embodiments, suitable amines and polyamines include those lacking a carboxy group (or lacking a carbonyl group or lacking —(C═S)—), or including no more than 2 carboxy groups per molecule (or no more than 2 carbonyl groups or no more 2 —(C═S)— per molecule), or no more than 1 carboxy group per molecule (or no more than 1 carbonyl group or no more 1 —(C═S)— per molecule).

Additional specific examples of polyamines include polyethylenimine, which also can be referred as polyaziridine or poly(iminoethylene). Polyethylenimine can be used in several molecular weights, can be branched, linear, or dendritic, and can be used as derivatives, such as polyethylenimine derivatized with various side chains or functional groups. Suitable molecular weights for polyethylenimine include about 800 and about 25,000 (number or weight average), although other molecular weights are contemplated, such as about 100,000 or less, about 50,000 or less, about 25,000 or less, about 20,000 or less, about 10,000 or less, about 5,000 or less, or about 1,000 or less, and down to about 500 or less. A suitable concentration of polyethylenimine (or another chemical agent) in a percolation-inhibition composition can be, for example, about 1.0 mg/ml, but can be adjusted according to a coating thickness of the composition that is applied to a substrate. An amount of polyethylenimine deposited on a surface may drive a cleaving mechanism or action, such as about 1.0 mg/ml for about 0.75 mil drawdown bar (about 10 μm wet thickness), and about 0.2 mg/ml for about 4 mil drawdown bar (about 50 μm wet thickness). These example amounts correspond to about 10 nm of polyethylenimine deposited on a surface. More generally for some embodiments, a loading level of polyethylenimine (or another chemical agent) can be at least about 1 ng/cm² of surface area, which corresponds to at least about 0.01 nm of polyethylenimine deposited on the surface (assuming density of about 1 g/cm³), such as at least about 10 ng/cm² of surface area, as at least about 50 ng/cm² of surface area, as at least about 100 ng/cm² of surface area, or as at least about 500 ng/cm² of surface area. Treatment can include using multiple passes at lower loading levels, wherein a cumulative loading level is at least about 1 ng/cm² of surface area. It is contemplated that polyethylenimine can be deposited or otherwise applied to a surface as monomers, followed by polymerization of the monomers to form polyethylenimine.

In terms of low visibility patterning, polyethylenimine is closely index-matched to various substrates to reduce a change in haze after treatment, where an index of refraction of polyethylenimine is about 1.52, an index of refraction of PMMA is about 1.49, an index of refraction of PET is about 1.57, and an index of refraction of polycarbonate is about 1.59. More generally for some embodiments, polyethylenimine (or another chemical agent) can have an index of refraction that is within ±0.3, ±0.2, ±0.18, ±0.15, ±0.13, ±0.1, ±0.8, or ±0.5 of a polymer or other host material in which conductive structures are embedded. In other embodiments, a rinsing operation is carried out to remove polyethylenimine (or another chemical agent) subsequent to treatment, such that close index-matching is not required.

Further examples of suitable chemical agents that can act as complexing agents (or as sources of complexing agents or ligands) include transition metal or ammonium halides (e.g., silver halides such as silver chloride or silver bromide), transition metal or ammonium oxides (e.g., silver oxide), transition metal or ammonium sulfides (e.g., silver sulfide), other silver (e.g., Ag⁺)-containing chemical agents, alkali metal (e.g., sodium or potassium) or ammonium thiocyanates, alkali metal (e.g., sodium or potassium) or ammonium polysulfides, alkali metal (e.g., sodium or potassium) sulfides, alkali metal (e.g., sodium or potassium) or ammonium thiosulfates, alkali metal (e.g., sodium or potassium) halides (e.g., chloride or bromide), metal or ammonium cyanides, ammonium carbonate, and ammonium carbamate.

Certain chemical agents can serve a dual function as a complexing agent as well as a reducing agent, in which case an additional or a separate reducing agent can be omitted from a percolation-inhibition composition of some embodiments. For example, certain amines and polyamines, such as bis(hexamethylene)triamine and polyethylenimine, among others listed above, can serve a dual function as a complexing-reducing agent. In other embodiments, a reducing agent can be included in combination with a complexing agent. For example, an alkali metal, an alkali metal thiocyanate (e.g., sodium thiocyanate), or ammonium thiocyanate can be used in combination with a reducing agent, such as hydroquinone, hydroquinone derivatives, ascorbic acid, or combinations of reducing agents including superadditive mixtures such as phenidone/hydroquinone mixtures.

In some embodiments for the case of metallic nanowires or other conductive structures formed of, or including, a metal, a suitable reducing agent for the metal can reduce an oxidized form of the metal, which is bound to a complexing agent, by driving a reduction of the metal to its elemental form. This reduction of the metal can yield a migration of the metal away from breaks along the conductive structures and re-deposition of the metal elsewhere.

A strength of a reducing agent with respect to reducing a metal can be characterized in terms of a relative placement of the reducing agent and the metal in the electrochemical series, with reducing agents of greater reducing strengths being placed higher than the metal in the electrochemical series. As will be understood, the electrochemical series is an arrangement of materials in order of their electrode potentials (redox potentials), with the more negative electrode potentials placed at the top of the electrochemical series, and the more positive electrode potentials placed at the bottom. Electrode potentials can be specified relative a reference electrode, and, in the case of the standard hydrogen electrode, electrode potentials are referred to as standard electrode potentials. A material that is higher in the electrochemical series can be more readily oxidized than a material lower in the electrochemical series and thus is effective as a reducing agent, while a material that is lower in the electrochemical series can be more readily reduced than a material higher in the electrochemical series and thus is effective as an oxidizing agent. With respect to reducing a metal, suitable reducing agents of some embodiments can have a more negative electrode potential than the metal, and a difference (e.g., an absolute difference) in electrode potentials of a reducing agent and the metal can be at least about 0.1 Volts, such as at least about 0.2 Volts, at least about 0.3 Volts, at least about 0.4 Volts, at least about 0.5 Volts, at least about 0.7 Volts, at least about 1 Volts, at least about 1.3 Volts, or at least about 1.5 Volts, and up to about 1.7 Volts, up to about 2 Volts, or more.

Examples of suitable chemical agents that can act as reducing agents (or as sources of reducing agents or reductants) include inorganic compounds, such as sodium borohydride, and organic compounds, such as citrates, amines and polyamines (e.g., phenidone, 4-(methylamino)phenol sulfate (or metol), and others listed above as suitable complexing agents), aldehydes (e.g., gluteraldehyde or formaldehyde), sulfites, and alcohols (e.g., polyols, hydroquinone, hydroquinone derivatives, such as hydroquinone with substituents like 2-hydroxy or tetramethyl, ascorbic acid, others listed above as suitable embedding and carrier fluids), and derivatives and combinations of the foregoing.

As explained above for some embodiments in the case of metallic nanowires or other conductive structures formed of, or including, a metal, an oxidized form of the metal can be included in the conductive structures as synthesized or can be formed in situ, in which case an oxidizing agent can be omitted from a percolation-inhibition composition of some embodiments. Further, the omission of an oxidizing agent can mitigate against excessive oxidation of the conductive structures, which can result in excessive degradation of the conductive structures and undesired optical contrast of treated and untreated portions of a patterned transparent conductor. It will be understood that the omission of an oxidizing agent can encompass an absence of any oxidizing agent in an absolute sense, but need not necessarily refer to such absolute sense. Rather, a percolation-inhibition composition that omits or is devoid of an oxidizing agent more generally can encompass a sufficiently small or a trace amount of the oxidizing agent, such that an amount of any oxidizing agent (e.g., expressed in terms of a concentration (weight or moles per unit volume) or a weight or volume percentage relative to a total weight or volume) in the percolation-inhibition composition relative to an amount of a complexing agent in the percolation-inhibition composition is no greater than about 1/20, no greater than about 1/30, no greater than about 1/40, no greater than about 1/50, no greater than about 1/100, no greater than about 1/500, or no greater than about 1/1,000, or such that the amount of any oxidizing agent in the percolation-inhibition composition relative to an amount of a reducing agent in the percolation-inhibition composition is no greater than about 1/20, no greater than about 1/30, no greater than about 1/40, no greater than about 1/50, no greater than about 1/100, no greater than about 1/500, or no greater than about 1/1,000. Thus, for example, a percolation-inhibition composition that omits or is devoid of an oxidizing agent can encompass un-intentional contaminants or impurities, such as environmental oxygen or moisture or low level impurities.

It should be understood that environmental oxygen, environmental moisture, other environmental contaminants or impurities, and combinations thereof may affect an oxidation state of a metal included in surfaces of conductive structures. As such, control of environmental contaminant level (e.g., by treatment in a water-free or oxygen-free or reduced water or reduced oxygen environment) can be used to control or modify the effect of a percolation-inhibition composition. In particular, certain complexing agents act solely or preferentially on an oxidized form of a metal (e.g., sodium thiocyanate complexes readily with Ag+ in AgCl or Ag₂O, but is substantially inert to elemental silver or Ag(0)). For example, removal of substantially all environmental oxygen and dissolved oxygen in the percolation-inhibition composition can reduce the rate or extent of percolation-inhibition.

In other embodiments, an oxidizing agent can be included in a percolation-inhibition composition. Examples of suitable oxidizing agents include inorganic peroxides, such as hydrogen peroxide and ammonium peroxide; organic peroxides, such as benzoyl peroxide, 2-butanone peroxide, cumene hydroperoxide, and alkoyl peroxides like lauryl peroxide; inorganic and organic hypohalites (e.g., hypochlorites), inorganic and organic acids, inorganic and organic persulfates, organic complexes of iron (III), potassium iodate, ferric nitrate, and other etchants. Oxidation also can be accomplished by ozone or ultraviolet-ozone treatment.

Inhibition of percolation through degradation can be accomplished in other manners, such as through sulfidation. Sulfidation can be accomplished by one or more of organic and inorganic sulfides (e.g., hydrogen sulfide, sodium sulfide, and others), Group 16 analogs of organic and inorganic sulfides (e.g., selenides and tellurides), and other sulfidizing agents. Surface modification of conductive structures can be accomplished by one or more of surface alloying and galvanic treatments to form layers or shells of a metal or a metal alloy of lower electrical conductivity at least partially surrounding the structures.

One or more degradation chemical agents can be dispersed in a suitable composition, which can include a thickener (or a viscosity modifier) and a solvent or other carrier fluid, and the composition can be applied in a substantially uniform manner or in a spatially selective or varying manner. A complexing agent can be included in a percolation-inhibition composition in an amount of at least about 0.01 wt. %, such as at least about 0.05 wt. %, at least about 0.1 wt. %, at least about 0.5 wt. %, at least about 1 wt. %, at least about 2 wt. %, at least about 3 wt. %, at least about 4 wt. %, or at least about 5 wt. %, and up to about 10 wt. %, up to about 15 wt. %, up to about 20 wt. %, or more, and, in some embodiments, even up to about 90%, up to about 95%, or up to about 100 wt. %. In embodiments where two or more complexing agents are included in a percolation-inhibition composition, a combined amount of the complexing agents can be within the above-stated ranges. In embodiments where a reducing agent is included in a percolation-inhibition composition in combination with a complexing agent, an amount of the reducing agent can be at least about 0.01 wt. %, such as at least about 0.05 wt. %, at least about 0.1 wt. %, at least about 0.5 wt. %, at least about 1 wt. %, at least about 2 wt. %, at least about 3 wt. %, at least about 4 wt. %, or at least about 5 wt. %, and up to about 10 wt. %, up to about 15 wt. %, up to about 20 wt. %, or more. In embodiments where two or more reducing agents are included in a percolation-inhibition composition, a combined amount of the reducing agents can be within the above-stated ranges. In some embodiments, an amount of a reducing agent (e.g., in terms of wt. %) in a percolation-inhibition composition can be no greater than, or less than, an amount of a complexing agent in the percolation-inhibition composition, although a greater relative amount of a reducing agent is contemplated for other embodiments.

In some embodiments, a suitable solvent is one that is substantially inert towards a polymer or other material included in a transparent conductor to be treated, so as to mitigate against undesired degradation of the transparent conductor through solubilizing the polymer. Examples of suitable solvents include water and alcohols, among others listed above as suitable carrier fluids. Thus, for example, a percolation-inhibition composition of some embodiments can be water-based or can be an aqueous composition. For such embodiments, degradation chemical agents and other components of the aqueous composition should be sufficiently water-soluble or miscible, such as having a solubility, at room temperature, of at least about 0.5 g, at least about 1 g, at least about 1.1 g, at least about 1.5 g, at least about 2 g, at least about 2.5 g, at least about 3 g, at least about 3.5 g, at least about 4 g, at least about 4.5 g, at least about 5 g, at least about 10 g, at least about 15 g, or at least about 20 g, per 100 g of water. Similar ranges of solubility can be applicable for an alcohol or another solvent that is used in place of water. Solubility of degradation chemical agents and other components in water or another solvent can also facilitate their removal subsequent to percolation-inhibition treatment, through a rinsing operation using water or another solvent. Suitable solvents can also be pH-adjusted, such as with potassium hydroxide or acetic acid, in order to alter or improve the functionality of the overall composition.

Examples of suitable thickeners include polymer binders, including water-soluble polymer binders such as poly(vinylpyrrolidone), polyvinyl alcohol, poly(vinyl alcohol-co-vinylamine), ethylene-vinyl alcohol copolymer, sodium polyacrylate, and carbohydrates, such as water-soluble cellulose derivatives like methylcellulose, hydroxyethylcellulose, and sodium carboxymethylcellulose, and water-soluble natural polymers like starch, starch paste, soluble starch, and dextrin. Polystyrene also can be a suitable thickener. In some embodiments, an amount of a polymer binder in a percolation-inhibition composition can be in the range of about 0.01 wt. % to about 50 wt. %, such as about 0.1 wt. % to about 45 wt. %, about 1 wt. % to about 40 wt. %, about 5 wt. % to about 40 wt. %, about 10 wt. % to about 40 wt. %, about 10 wt. % to about 35 wt. %, or about 15 wt. % to about 35 wt. %, although a polymer binder can be omitted for other embodiments. A percolation-inhibition composition also can include one or more of a humectant, a defoamer (or an anti-foaming agent), a surfactant (or a wetting agent), a rheological filler (e.g., a clay such as bentonite or other solid filler such as barium sulfate), a pH modifier, and an anti-colorant (or anti-yellowing agent).

Suitable degradation chemical agents of some embodiments can have a low volatility to mitigate against evaporation of the chemical agents during treatment away from portions intended to become lower conductance portions and adversely affecting portions intended to become higher conductance portions. For example, suitable complexing agents, such as amines and polyamines, can have a boiling point, at 1 atmosphere, of at least about 80° C., at least about 90° C., at least about 100° C., at least about 110° C., at least about 120° C., at least about 130° C., at least about 140° C., at least about 150° C., at least about 160° C., at least about 170° C., or at least about 180° C., and up to about 220° C., up to about 240° C., or more. In other embodiments, a gas phase or otherwise volatile (low boiling point) degradation chemical agent (either, or both, a complexing agent and a reducing agent) can be used, for example, if portions of a substrate are covered by a protective mask, and unprotected portions are treated by exposure to volatile chemical agents. In this case, a solvent may or may not be included. The substrate can optionally be cooled to below a boiling point of the volatile chemical agents in order to condense the volatile agents onto the substrate. Additionally, in embodiments where a percolation-inhibition composition is patterned directly onto a substrate, such as via screen printing or other printing methods, it may be desirable for a complexing agent and, optionally, a reducing agent to have low volatility, through the selection of chemical agents which are non-volatile salts or otherwise have low volatility (e.g., solids or semi-solids at room temperature). Low volatility or non-volatile complexing agents can have a specific advantage that they are less likely to spread to areas of a substrate which are to remain untreated. The phenomenon of unwanted spread of a percolation-inhibition composition beyond an intended treatment area can be referred to as “overkill,” and can be significantly mitigated or eliminated by careful selection of one or more of a low volatility (e.g., boiling point above about 100° C.) complexing agent, appropriate activation temperature (e.g., below the boiling point of the complexing agent), and appropriate treatment time.

Additionally, in other embodiments, metal ion sources can be added to, or included in, a percolation-inhibition composition in order to further facilitate or control a loading level of a metal (e.g., silver) remaining on a substrate after treatment. Suitable metal ion sources can include, for example, silver nitrate, silver lactate, tetrachloroauric acid, palladium nitrate, silver acetate, palladium chloride, gold ethylene diamine complex, and other metal-containing salts or metal-ligand complexes. A metal ion source can be added to a composition in the range of about 0.0001 wt. % to about 5 wt. %. The metal ion source can be a source of the same metal as a metal of a percolating network, or can be a source of a different metal.

Sequential deposition of components of a percolation-inhibition composition can also be practiced in some embodiments. For example, a conductive structure-containing substrate can be treated with a metal complexing agent in one process operation, the complexing agent can then be removed from a surface of the substrate in another process operation, and the surface can be treated with a reducing agent in a further process operation, optionally in the presence of a metal ion source.

In some embodiments, a solvent may not be necessary for the function of a percolation-inhibition composition. For example, certain metal complexing agents can be melted or otherwise deposited onto a substrate surface and can inhibit percolation in their native state.

An electrical conductivity of a percolating network of conductive structures can be reduced by applying any combination of the above methods—physical, chemical, and degradation, by applying the appropriate chemical agents or treatments as described above to the network of conductive structures, before or after percolation is achieved, either sequentially or simultaneously.

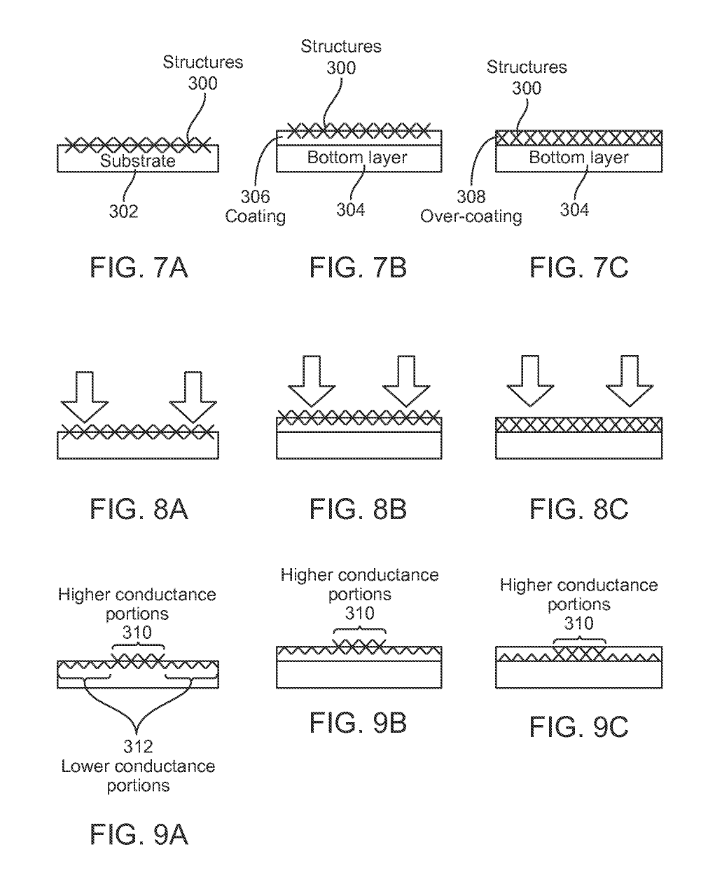

FIG. 7 through FIG. 9 illustrate manufacturing methods of patterned transparent conductors, according to embodiments of this disclosure. As shown in FIG. 7A, a substrate 302 is provided, and conductive structures 300 are at least partially embedded into a surface of the substrate 302. As shown in FIG. 7B, a bottom layer 304 is provided, a coating or a top layer 306 is applied on top of the bottom layer 304, and conductive structures 300 are at least partially embedded into a surface of the coating 306. As shown in FIG. 7C, a bottom layer 304 is provided, conductive structures 300 are applied on top of the bottom layer 304, and an over-coating or a top layer 308 is applied on top of the bottom layer 304 and at least partially surrounding the structures 300.

Next, a percolation-inhibiting treatment is applied in a spatially selective or varying manner as shown in FIG. 8A through FIG. 8C. For example, a percolation-inhibiting composition can be applied in a pattern through printing, such as screen, ink-jet, aerosol-jet, flexographic, ultrasonic spray, continuous deposition, slot die, doctor bar, patch, gravure, intaglio, pad, roll, offset, mimeography, or imprint. The percolation-inhibiting composition can be adjusted to aid in printing, such as a relatively high viscosity (e.g., greater than about 100 centipoise, such as at least about 200, about 300, about 400, about 500, or about 600 centipoise) with shear thinning behavior in the case of screen printing, and a relatively low viscosity in the case of ink jetprinting. In the case of the over-coated implementation of FIG. 8C, a thickness of the over-coating 308 can be adjusted as relatively thin to aid in exposing the structures 300 to the percolation-inhibiting composition, the over-coating 308 can be formed of, or can include, a host material sufficiently permeable to, or is otherwise sufficiently susceptible to, the percolation-inhibiting composition to allow permeation of the composition into the over-coating 308, or both. Portions exposed to the percolation-inhibiting composition form lower conductance portions 312 as shown in FIG. 9A through FIG. 9C, while portions not exposed to the percolation-inhibiting composition remain electrically conductive, forming higher conductance portions 310 as shown in FIG. 9A through FIG. 9C. Optionally, an activating or annealing operation can be carried out to promote reaction or other activity of the percolation-inhibiting composition, such as through application of heat or other thermal or energizing treatment at a temperature above room temperature or above about 25° C., at least about 30° C., at least about 40° C., at least about 50° C., at least about 60° C., at least about 70° C., or at least about 80° C., and up to about 200° C., up to about 150° C., up to about 140° C., up to about 130° C., up to about 120° C., up to about 110° C., or up to about 100° C., and for a duration of at least about 1 minute, at least about 2 minutes, at least about 3 minutes, at least about 4 minutes, or at least about 5 minutes, and up to about 2 hours, up to about 1.5 hour, up to about 1 hour, up to about 50 minutes, up to about 45 minutes, up to about 40 minutes, or up to about 35 minutes. The activation operation can include, for example, thermal treatment (e.g., an oven), exposure to ultraviolet light, flash annealing, exposure to electron beam, or chemical activation. The percolation-inhibiting composition can be viewed as an “active” mask, since it actively performs the function of inhibiting percolation in the portions exposed to the “active” mask. Optionally, a cleaning, washing, or rinsing operation can be carried out to remove any remaining percolation-inhibiting composition, such as through the use of pressurized water or other suitable solvents, and a quenching operation can be carried out to quench further reaction or other activity of the percolation-inhibiting composition.

For applications in which low visibility patterning is desired, the percolation-inhibiting composition can have the effect of degrading or reducing electrical conductivity of the structures 300 in the lower conductance portions 312, while maintaining optical characteristics (e.g., haze, transmittance, reflectance, absorbance, luster, and color) of the lower conductance portions 312 as sufficiently matching optical characteristics of the higher conductance portions 310. In cases where inhibition of percolation affects or alters one or more optical properties, the percolation-inhibiting composition can include optical matching additives that can compensate for the alteration in the one or more optical properties. Examples of optical matching additives include nanoparticles or other fillers formed of insulating or lower conductivity materials, liquid crystal materials, and photochromic materials (e.g., silver halides for glass substrates or organic photochromic molecules such as oxazines, or naphthopyrans for polymer substrates). Optical matching additives can be surface embedded through the inclusion of a suitable embedding fluid in the percolation-inhibiting composition.

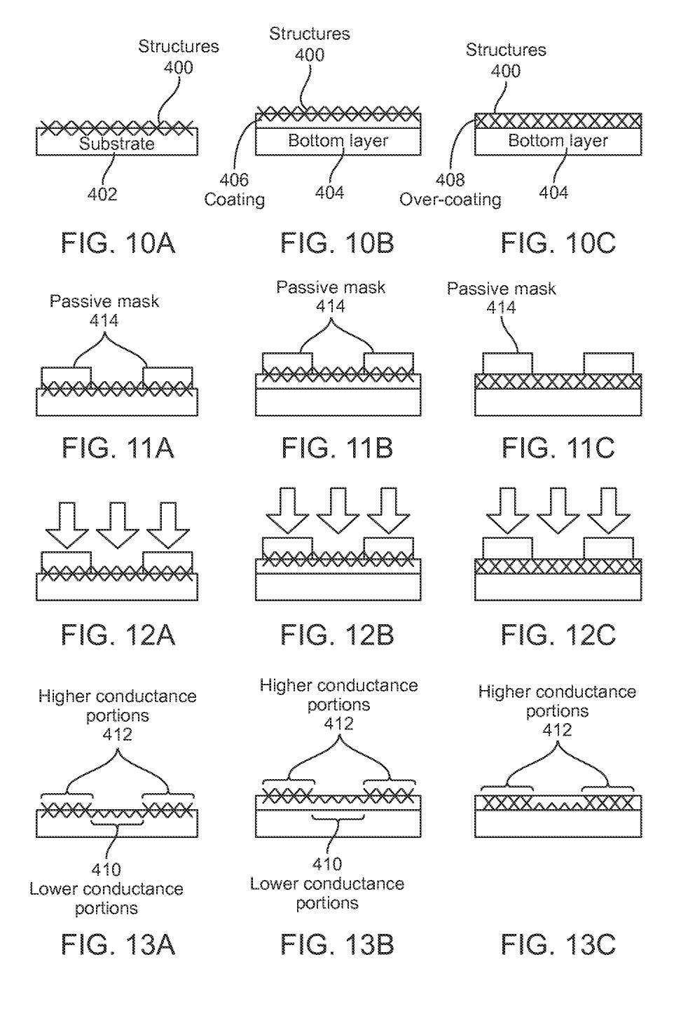

FIG. 10 through FIG. 14 illustrate manufacturing methods of patterned transparent conductors, according to embodiments of this disclosure. As shown in FIG. 10A, a substrate 402 is provided, and conductive structures 400 are at least partially embedded into a surface of the substrate 402. As shown in FIG. 10B, a bottom layer 404 is provided, a coating or a top layer 406 is applied on top of the bottom layer 404, and conductive structures 400 are at least partially embedded into a surface of the coating 406. As shown in FIG. 10C, a bottom layer 404 is provided, conductive structures 400 are applied on top of the bottom layer 404, and an over-coating or a top layer 408 is applied on top of the bottom layer 404 and at least partially surrounding the structures 400.

Next, a physical mask, a patterned photoresist layer, a particulate-based mask (e.g., silica or titania), or other type of “passive” mask 414 having a low permeability for a percolation-inhibiting composition can be placed or applied on top of the devices as shown in FIG. 11A through FIG. 11C. The mask 414 can be viewed as a “passive” mask, since it performs a passive, protective function instead of actively affecting percolation. The mask 414 has a pattern that covers selected portions of the devices while leaving other portions uncovered or exposed.

Next, as shown in FIG. 12A through FIG. 12C, a percolation-inhibiting treatment is applied in a substantially uniform manner, such as by applying a percolation-inhibiting composition through the use of a coating process or tool (e.g., dip coating), spraying, or other low viscosity, solution-phase application method. The inclusion of the mask 414 results in spatially selective or varying application of the percolation-inhibiting composition through gaps or openings in the mask 414. In the case of the over-coated implementation of FIG. 12C, a thickness of the over-coating 408 can be adjusted as relatively thin to aid in exposing the structures 400 to the percolation-inhibiting composition, the over-coating 408 can be formed of, or can include, a host material sufficiently permeable to, or is otherwise sufficiently susceptible to, the percolation-inhibiting composition to allow permeation of the composition into the over-coating 408, or both. Portions exposed to the percolation-inhibiting composition (and are not covered by the mask 414) form lower conductance portions 410, while portions not exposed to the percolation-inhibiting composition (and are covered by the mask 414) remain conductive, forming higher conductance portions 412. Optionally, an activating or annealing operation can be carried out to promote reaction or other activity of the percolation-inhibiting composition, such as through application of heat or other thermal or energizing treatment at a temperature above room temperature or above about 25° C., at least about 30° C., at least about 40° C., at least about 50° C., at least about 60° C., at least about 70° C., or at least about 80° C., and up to about 150° C., up to about 140° C., up to about 130° C., up to about 120° C., up to about 110° C., or up to about 100° C., and for a duration of at least about 1 minute, at least about 2 minutes, at least about 3 minutes, at least about 4 minutes, or at least about 5 minutes, and up to about 2 hours, up to about 1.5 hour, up to about 1 hour, up to about 50 minutes, up to about 45 minutes, up to about 40 minutes, or up to about 35 minutes. Optionally, a cleaning, washing, or rinsing operation can be carried out to remove any remaining percolation-inhibiting composition, such as through the use of pressurized water or other suitable solvents, and a quenching operation can be carried out to quench further reaction or other activity of the percolation-inhibiting composition.

For applications in which low visibility patterning is desired, the percolation-inhibiting composition can have the effect of degrading or reducing electrical conductivity of the structures 400 in the lower conductance portions 410, while maintaining optical characteristics (e.g., haze, transmittance, reflectance, absorbance, luster, and color) of the lower conductance portions 410 as sufficiently matching optical characteristics of the higher conductance portions 412. In cases where inhibition of percolation affects or alters one or more optical properties, the percolation-inhibiting composition can include optical matching additives that can compensate for the alteration in the one or more optical properties. Optical matching additives can be surface embedded through the inclusion of a suitable embedding fluid in the percolation-inhibiting composition.

As shown in FIG. 13A through FIG. 13C, the mask 414 can be removed, such as by dissolving the mask or other suitable physical or chemical treatment. Alternatively, as shown in FIG. 14A through FIG. 14C, the mask 414 can be retained. For applications in which low visibility patterning is desired, a planarization coating or layer 416 can be applied on top of the devices as shown in FIG. 14A through FIG. 14C, so as to planarize the resulting devices as an aid to lamination or formation of additional layers over the devices, and so that optical characteristics (e.g., haze, transmittance, reflectance, absorbance, luster, and color) of the lower conductance portions 410 (not covered by the mask 414) sufficiently match optical characteristics of the higher conductance portions 412 (covered by the mask 414). As shown in FIG. 14A through FIG. 14C, the planarization layer 416 is applied to cover both the lower conductance portions 410 (not covered by the mask 414) and the higher conductance portions 412 (covered by the mask 414); in other embodiments, the planarization layer 416 can be applied to selectively cover the lower conductance portions 410 (not covered by the mask 414). For example, the planarization layer 416 can be formed of, or can include, an optically clear adhesive or other polymer, optionally including optical matching additives to compensate for the presence of the mask 414 over the higher conductance portions 412. To reduce visibility of the mask 414, a refractive index of the mask 414 can sufficiently match that of the planarization layer 416. In some embodiments, a difference between the refractive indices of the mask 414 and the planarization layer 416 (e.g., an absolute difference between the values expressed as a percentage relative to either of the values) can be no greater than about 10%, such as no greater than about 5%, no greater than about 4%, no greater than about 3%, no greater than about 2%, no greater than about 1%, or no greater than about 0.5%, and down to about 0.1%, down to about 0.01%, down to about 0.001%, or less. Also, the planarization layer 416 can be sufficiently thin to reduce additional effects related to either, or both, haze and color. In some embodiments, a thickness of the planarization layer 416 can be no greater than about 5 times a thickness of the mask 414, such as no greater than about 4.5 times, no greater than about 4 times, no greater than about 3.5 times, no greater than about 3 times, no greater than about 2.5 times, no greater than about 2 times, no greater than about 1.5 times, no greater than about 1.4 times, no greater than about 1.3 times, no greater than about 1.2 times, or no greater than about 1.1 times.

In other embodiments, an optically clear adhesive or other index matching material can be used to reduce or hide surface roughness differences between treated and untreated portions of a substrate as patterned or otherwise treated with a percolation-inhibition composition. These surface roughness differences may arise due to one or more of the following list, which are provided by way of example: residues from surfactants, polymer binders, solid fillers, or other percolation-inhibition composition components; preferential effect of a percolation-inhibition composition on an exposed metal (e.g., exposed silver nanowires or portions thereof affected more than embedded silver nanowires or portions thereof); and interaction of a percolation-inhibition composition with a treated substrate surface.

Other embodiments of manufacturing methods of patterned transparent conductors are contemplated. For example, in some embodiments, a percolation-inhibition composition is applied substantially uniformly over a network of conductive structures, and an activating operation can be carried out in a spatially selective or varying manner, such as by heating or otherwise energizing the network of conductive structures in a spatially localized or varying manner to cause the percolation-inhibition composition to act locally to form lower conductance portions. Energizing can be provided by electromagnetic radiation, such as by a laser, thermally, such as by contact with a heated patterned stamp, or a combination of the foregoing.

### Devices Including Transparent Conductors

The transparent conductors described herein can be used as transparent conductive electrodes in a variety of devices. Examples of suitable devices include solar cells (e.g., thin-film solar cells and crystalline silicon solar cells), display devices (e.g., flat panel displays, liquid crystal displays (or LCDs), plasma displays, organic light emitting diode (or OLED) displays, electronic-paper (or e-paper), quantum dot displays (e.g., QLED Displays), and flexible displays), solid-state lighting devices (e.g., OLED lighting devices), touch sensor devices (e.g., projected capacitive touch sensor devices, touch-on-glass sensor devices, touch-on-lens projected capacitive touch sensor devices, on-cell or in-cell projected capacitive touch sensor devices, self capacitive touch sensor devices, surface capacitive touch sensor devices, and resistive touch sensor devices), smart windows (or other windows), windshields, aerospace transparencies, electromagnetic interference shields, charge dissipation shields, and anti-static shields, as well as other electronic, optical, optoelectronic, quantum, photovoltaic, and plasmonic devices. The transparent conductors can be tuned or optimized depending on the particular application, such as work function matching in the context of photovoltaic devices or tuning of the transparent conductors to form Ohmic contacts with other device components or layers.

In some embodiments, the transparent conductors can be used as electrodes in touch sensor devices. A touch sensor device is typically implemented as an interactive input device integrated with a display, which allows a user to provide inputs by contacting a touch screen. The touch screen is typically transparent to allow light and images to transmit through the device.

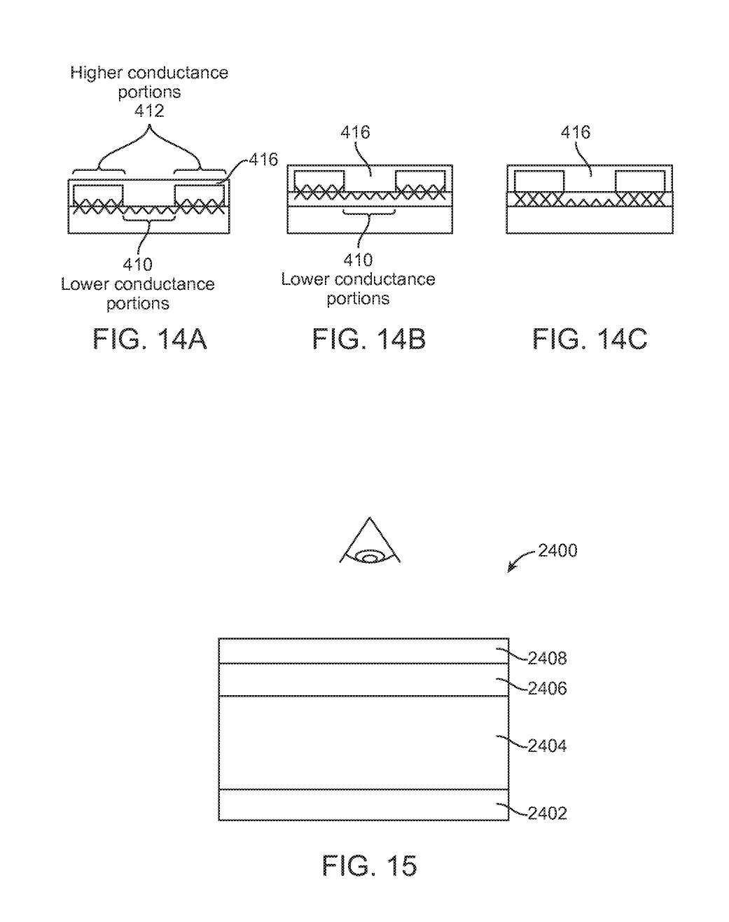

FIG. 15 illustrates an example of a projected capacitive touch sensor device 2400 according to an embodiment of this disclosure. The touch sensor device 2400 includes a thin-film separator 2404 that is disposed between a pair of patterned transparent conductive electrodes 2402 and 2406, as well as a rigid touch screen 2408 that is disposed adjacent to a top surface of the transparent conductive electrode 2406. A change in capacitance occurs when a user contacts the touch screen 2408, and a controller (not illustrated) senses the change and resolves a coordinate of the user contact. Advantageously, either, or both, of the transparent conductive electrodes 2402 and 2406 can be implemented using the transparent conductors described herein. It is also contemplated that the transparent conductors can be included in resistive touch sensor devices (e.g., 4-wire, 5-wire, and 8-wire resistive touch sensor devices), which include a flexible touch screen and operate based on electrical contact between a pair of transparent conductive electrodes when a user presses the flexible touch screen.

### EXAMPLES

The following examples describe specific aspects of some embodiments of this disclosure to illustrate and provide a description for those of ordinary skill in the art. The examples should not be construed as limiting this disclosure, as the examples merely provide specific methodology useful in understanding and practicing some embodiments of this disclosure.

### Example 1

A network of silver nanowires embedded in a surface of a polycarbonate (or PC) film is formed by draw down coating of a silver nanowire dispersion, containing silver nanowires, a carrier solvent, and an embedding solvent, on a sheet of PC. An electrical conductivity of the dried film is about 100 Ω/sq when measured by a non-contact, eddy current-based sheet resistance measurement device, such as a Napson EC-80P, after thermal treatment of the film at about 100° C. for about 20 minutes. A solution of about 40 wt. % 2-mercapto ethanol, about 20 wt. % isopropyl alcohol (or IPA), and about 40 wt. % methyl isobutyl ketone (or MIBK) is applied to the pre-heat treated film by doctor bar with a gap set at about 25-100 μm. After drying the film and thermal treatment at about 100° C. for about 20 minutes, the measured OPS is off-scale using the sheet resistance measurement device (the Napson EC-80P reaches off-scale measurement at 1,300 OPS, but further measurement shows that the OPS is well above 1,300 OPS), indicating that the nanowire network is rendered non-percolating. Optical microscopy reveals no visible damage to the nanowires.

### Example 2

A network of silver nanowires embedded in a surface of a poly(methyl methacrylate) (or PMMA) film coated at about 1 μm thickness on a poly(ethylene terephthalate) (or PET) layer is formed by draw down coating of a silver nanowire dispersion, containing silver nanowires, a carrier solvent, and an embedding solvent, on a sheet of the PMMA-coated PET. An electrical conductivity of the dried film is about 100 Ω/sq when measure by a non-contact, eddy current-based sheet resistance measurement device, such as a Napson EC-80P, after thermal treatment of the film at about 100° C. for about 20 minutes. After this thermal treatment, a solution of polyethylenimine in IPA is applied to the film using a doctor bar with a gap of about 25 μm. After a further thermal treatment at about 100° C. for about 20 minutes, the film is rendered insulating as measured by an off-scale Napson EC-80P reading (the Napson EC-80P reaches off-scale measurement at 1,300 OPS, but further measurement shows that the OPS is well above 1,300 OPS). Optical microscopy reveals that the silver nanowires are severed along their lengths during the further thermal treatment, by the action of the polyethylenimine.

### Example 3

A network of silver nanowires embedded in a surface of a PMMA film coated at about 1 μm thickness on a PET layer is formed by draw down coating of a silver nanowire dispersion, containing silver nanowires, a carrier solvent, and an embedding solvent, on a sheet of the PMMA-coated PET. An electrical conductivity of the dried film is about 100 Ω/sq when measured by a non-contact, eddy current-based sheet resistance measurement device, such as a Napson EC-80P, after thermal treatment of the film at about 100° C. for about 20 minutes. A solution of 2-butanone peroxide in IPA is applied to the pre-heat treated film by doctor bar with a gap set at about 25-100 μm. After drying the film and thermal treatment at about 100° C. for about 20 minutes, the measured OPS is off-scale using the sheet resistance measurement device (the Napson EC-80P reaches off-scale measurement at 1,300 OPS, but further measurement shows that the OPS is well above 1,300 OPS), indicating that the nanowire network is rendered non-percolating. Optical microscopy reveals that the silver nanowires are etched or partially etched by the action of the organic peroxide.

### Example 4

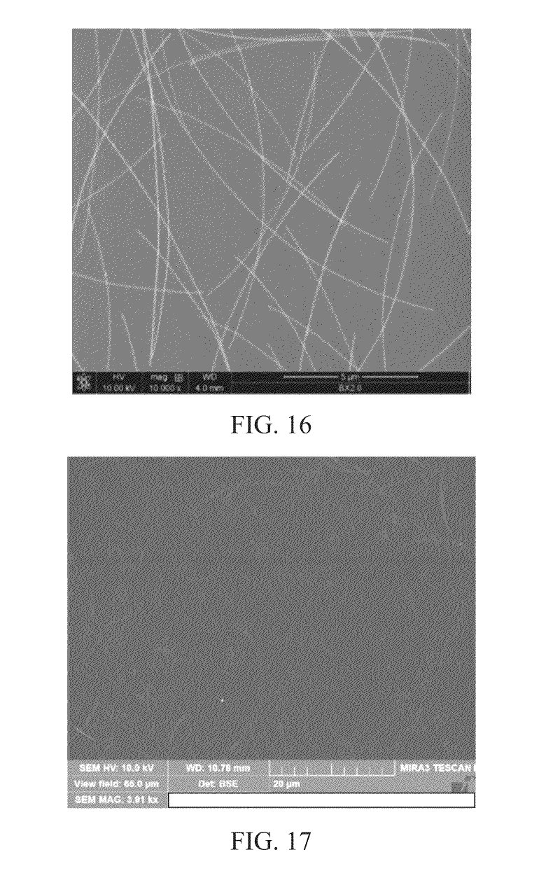

FIG. 16 is a scanning electron microscopy (or SEM) image of a network of silver nanowires embedded in a substrate, without or prior to application of an electrical conductivity modifying agent. FIG. 17 is a SEM image of a silver nanowire-embedded substrate subsequent to application of hydrogen peroxide. As can be observed, silver nanowires are largely removed or degraded, with some silver-containing material remaining in the substrate. In this case, the treated portion of the substrate is readily distinguished from an untreated portion by the human eye.

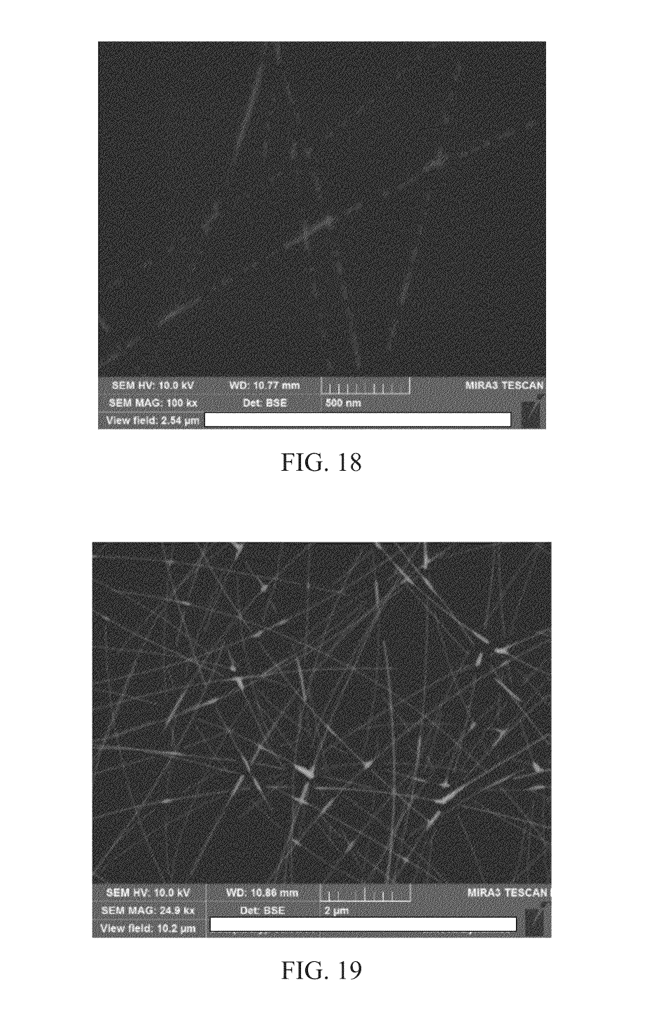

By comparison, FIG. 18 is a SEM image of a silver nanowire-embedded substrate subsequent to application of ammonia. As can be observed, silver nanowires are severed along their lengths. Without wishing to be bound by a particular theory, ammonia can act by preferentially or selectively degrading silver nanowires at locations including silver halide, which is included in the silver nanowires as synthesized.

Also by comparison, FIG. 19 is a SEM image of a silver nanowire-embedded substrate subsequent to application of polyethylenimine. As can be observed, junctions between silver nanowires are preferentially or selectively degraded to sever silver nanowires at the junctions and to remove silver from the junctions, along with a migration or re-deposition of silver onto intact or severed silver nanowires adjacent to the junctions.

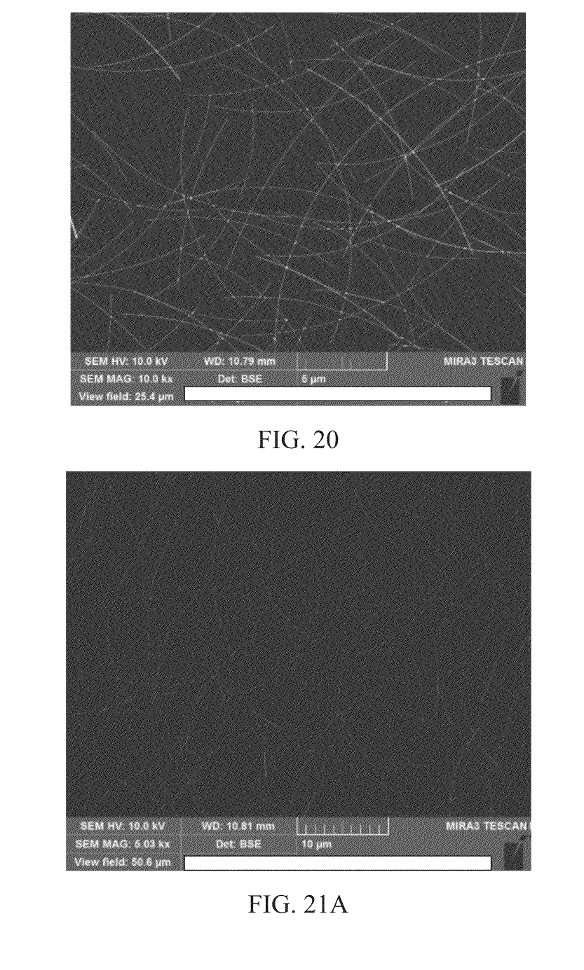

Also by comparison, FIG. 20 is a SEM image of a silver nanowire-embedded substrate subsequent to application of bis(hexamethylene)triamine. As can be observed, junctions between silver nanowires are preferentially or selectively degraded to sever silver nanowires at the junctions and to remove silver from the junctions, along with a migration or re-deposition of silver as silver nanoparticles at the junctions, although a final morphology can be affected or varied by composition and processing parameters.

### Example 5

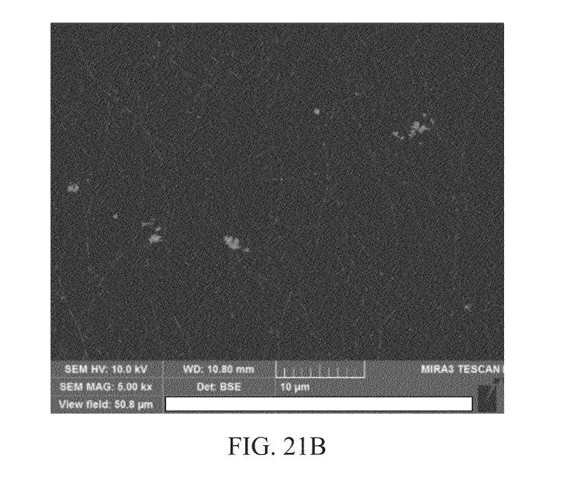

To evaluate the role of a silver halide in the activity of an electrical conductivity modifying agent, silver nanowires containing different amounts of a silver halide, here silver chloride, are embedded in substrates, and the silver-nanowire embedded substrates are treated with bis(hexamethylene)triamine FIG. 21A is a SEM image of a substrate embedded with silver nanowires containing about 0.6 wt. % of silver chloride, subsequent to application of bis(hexamethylene)triamine, and FIG. 21B is a SEM image of a substrate embedded with silver nanowires containing about 3.41 wt. % of silver chloride, subsequent to application of bis(hexamethylene)triamine. As can be observed, a greater number of nanowire breaks is evident for silver nanowires containing a greater amount of silver chloride.

### Example 6

Various amines were tested by drop-casting onto a spin-coated network of silver nanowires on silicon and activating by annealing at about 100° C. for about 15 minutes.

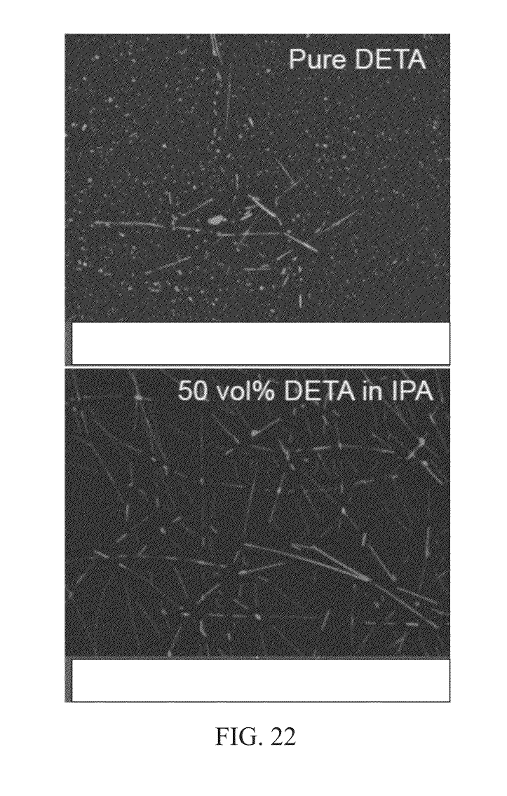

In the case of diethylenetriamine (or DETA), FIG. 22 (top panel) is a SEM image of silver nanowires treated with 100 vol. % DETA, and FIG. 22 (bottom panel) is a SEM image of silver nanowires treated with 50 vol. % DETA in IPA. As can be observed, silver nanowires are largely converted to nanoparticles when using 100 vol. % DETA after activation, while use of 50 vol. % DETA results in nanowire breaks and a migration or re-deposition of silver onto severed silver nanowires.

FIG. 23 is a SEM image of silver nanowires treated with octylamine. As can be observed, junctions between silver nanowires are preferentially or selectively degraded to sever silver nanowires at the junctions and to remove silver from the junctions, along with a migration or re-deposition of silver as silver nanoparticles at the junctions and a migration or re-deposition of silver onto severed silver nanowires.

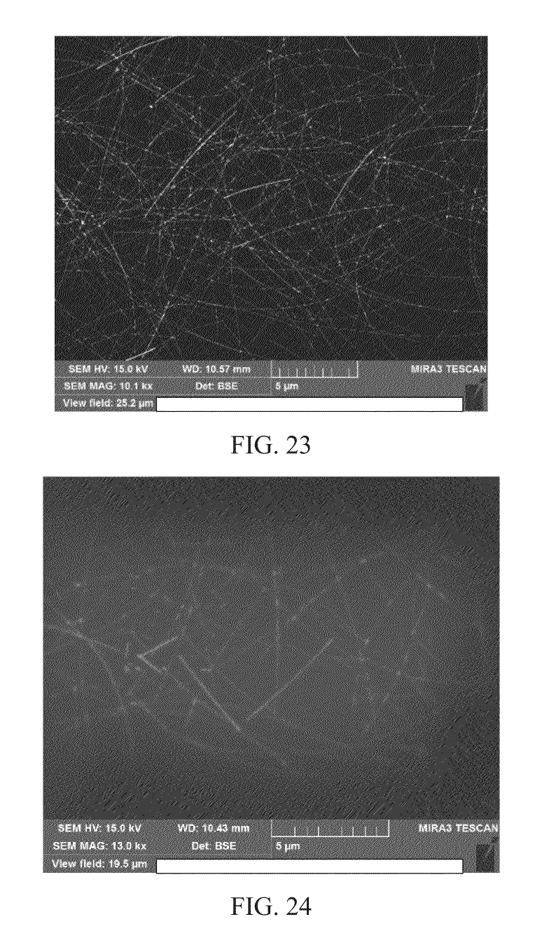

FIG. 24 is a SEM image of silver nanowires treated with decylamine. As can be observed, junctions between silver nanowires are preferentially or selectively degraded to sever silver nanowires at the junctions and to remove silver from the junctions, along with a migration or re-deposition of silver as silver nanoparticles at the junctions and a migration or re-deposition of silver onto severed silver nanowires.

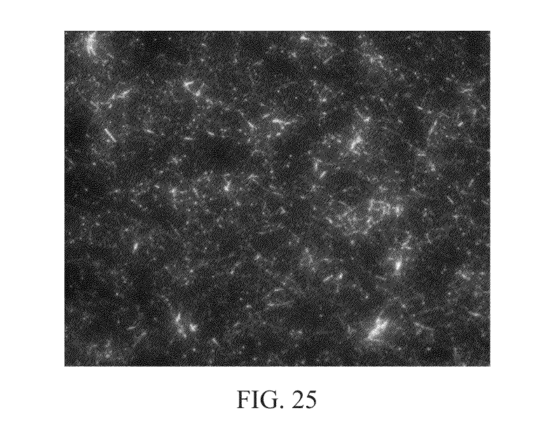

FIG. 25 is a SEM image of silver nanowires treated with triethylenetetramine. As can be observed, silver nanowires are severed to remove silver, along with a migration or re-deposition of silver.

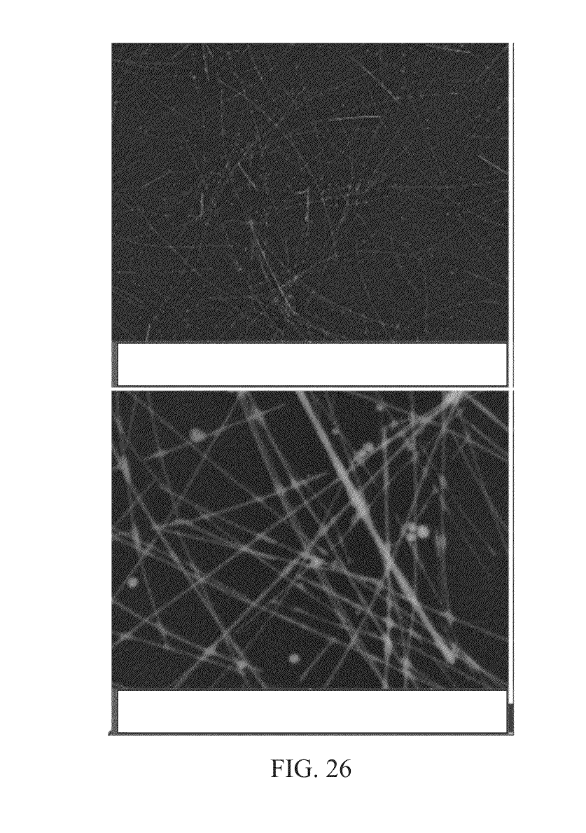

FIG. 26 (top panel) is a SEM image of silver nanowires treated with N-methylethylenediamine, and FIG. 26 (bottom panel) is a magnified view of the image. As can be observed, junctions between silver nanowires are preferentially or selectively degraded to sever silver nanowires at the junctions and to remove silver from the junctions, along with a migration or re-deposition of silver as silver nanoparticles at the junctions as well as elsewhere beyond the junctions.

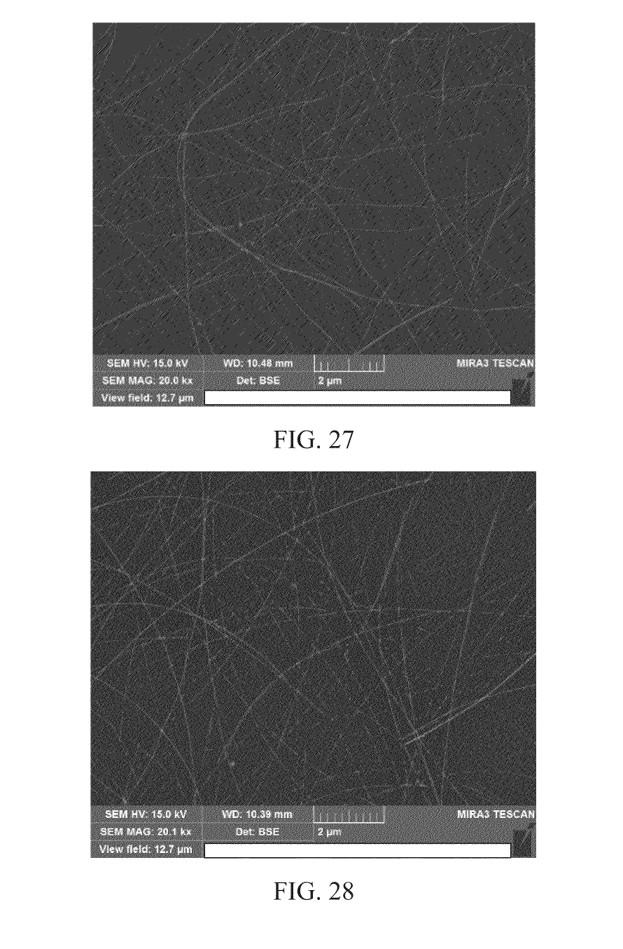

FIG. 27 is a SEM image of silver nanowires treated with N,N′-dimethylethylenediamine. As can be observed, junctions between silver nanowires are preferentially or selectively degraded to sever silver nanowires at the junctions and to remove silver from the junctions, along with a migration or re-deposition of silver as silver nanoparticles at the junctions.

FIG. 28 is a SEM image of silver nanowires treated with N,N′-diisopropylethylenediamine. As can be observed, silver nanowires are severed along their lengths.

### Example 7

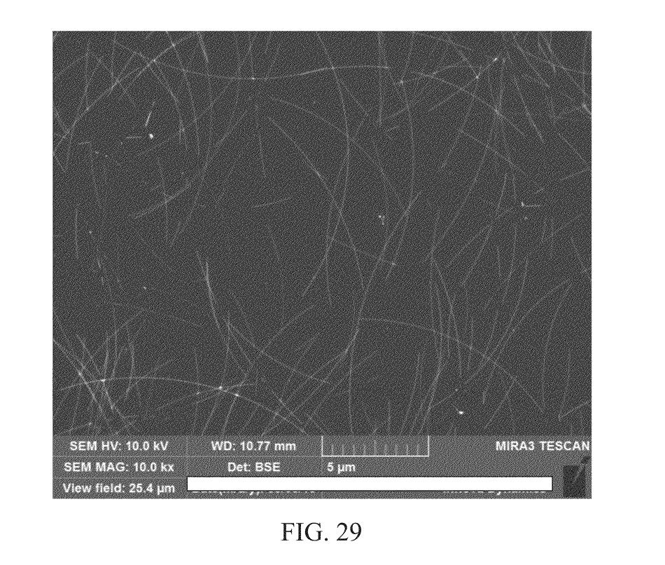

FIG. 29 is a SEM image of silver nanowires treated with sodium thiosulfate. As can be observed, silver nanowires are severed along their lengths.

### Example 8

To demonstrate the ability to render a network of silver nanowires insulating while reducing changes in surface area coverage and haze for low optical contrast, samples treated with bis(hexamethylene)triamine and sodium thiosulfate were evaluated relative to untreated samples.

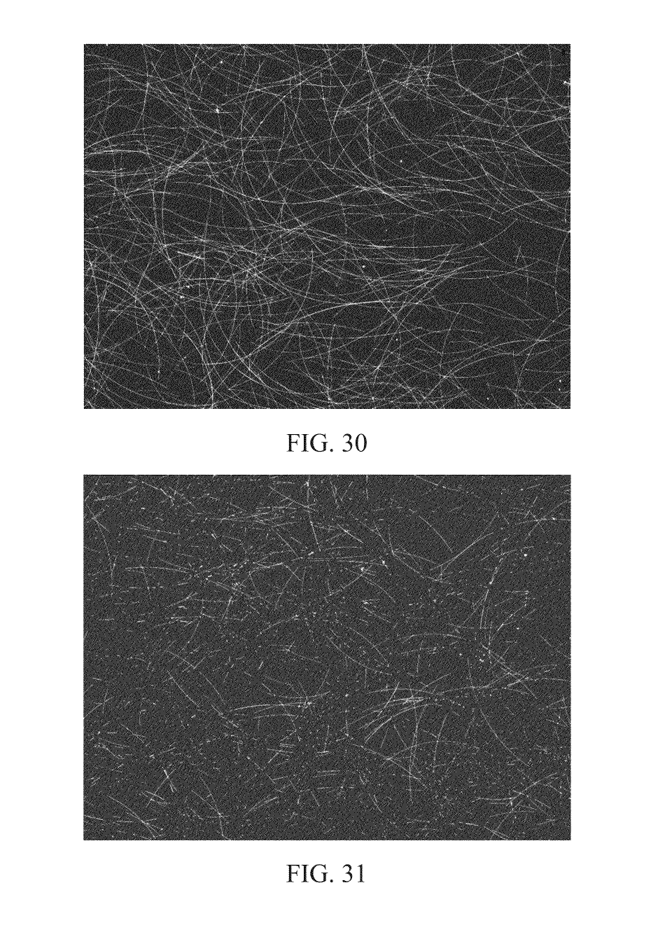

FIG. 30 is a SEM image of untreated silver nanowires, FIG. 31 is a SEM image of silver nanowires treated with bis(hexamethylene)triamine, and FIG. 32 is a SEM image of silver nanowires treated with sodium thiosulfate. As can be observed, treated silver nanowires are severed along their lengths, effectively rendering a network of the silver nanowires to be non-percolating.

Measurements of surface area coverage, haze, and electrical conductivity are performed for the treated and untreated samples, and results are set forth below, where values for surface area coverage are derived over an area of 250 μm×250 nm.

| Bis(hexamethylene) | Surface area | | |
|---|---|---|---|
| triamine | coverage | Haze | Ohms per square |
| Untreated | 7.4% | 1.35% | 91 |
| treated | 3.1% | 1.22% | Off-scale |

| | Surface area | | |
|---|---|---|---|
| Sodium thiosulfate | coverage | Haze | Ohms per square |
| untreated | 7.9% | 1.33% | 164 |
| treated | 4.2% | 1.15% | Off-scale |

### Example 9

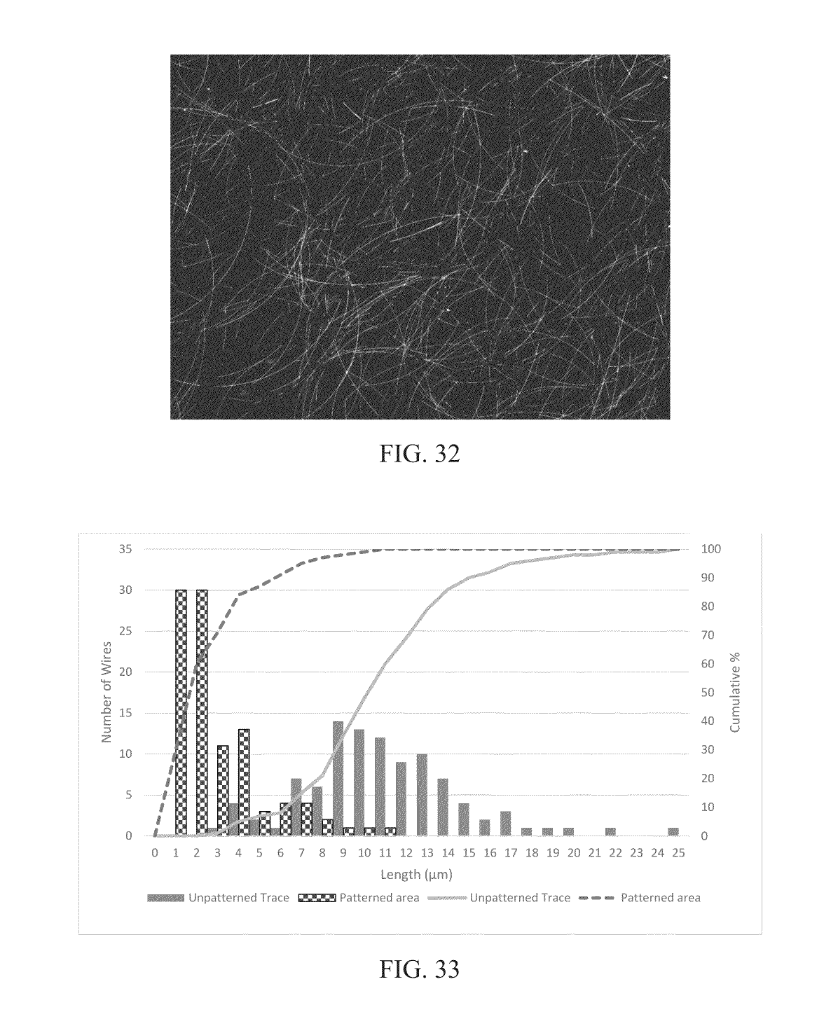

To evaluate the impact of an electrical conductivity modifying agent on lengths of silver nanowires, measurements of lengths were performed from SEM images of a sample of a patterned transparent conductor. The measurements were performed for 100 silver nanowires in an untreated (or unpatterned) region and 100 silver nanowires in a treated (or patterned) region. Results are set forth in FIG. 33. As a result of breaks along lengths of silver nanowires, an average length of treated silver nanowires is reduced to about 2.4 μm, from about 10.5 μm for untreated silver nanowires. Also, a 30^{th} percentile length shifts from less than about 9 μm for untreated silver nanowires to less than about 1 μm for treated silver nanowires.

### Example 10

Percolation-inhibition compositions are prepared with components and amounts as follows:

(1) about 15 wt. % of a polymer binder as a viscosity modifier (poly(vinylalcohol-co-vinylamine)), about 0.15 wt. % of an oil-based defoamer (available as Rhodoline® 646), about 1 wt. % of an electrical conductivity modifying agent (bis(hexamethylene)triamine), and balance de-ionized (or DI) water.

(2) about 18 wt. % of a polymer binder as a viscosity modifier (poly(vinylalcohol-co-vinylamine)), about 0.15 wt. % of an oil-based defoamer (available as Rhodoline® 646), about 10 wt. % of a humectant (glycerol), about 2.5 wt. % of an electrical conductivity modifying agent (polyethyleneimine), and balance DI water.

(3) about 14.98 wt. % of a polymer binder as a viscosity modifier (poly(vinylalcohol-co-vinylamine)), about 0.15 wt. % of an oil-based defoamer (available as Rhodoline® 646), about 20 wt. % of a humectant (triacetin), about 0.1 wt. % of a non-ionic fluorosurfactant (available as Capstone® FS-35), about 10 wt. % of an electrical conductivity modifying agent (bis(hexamethylene)triamine), and balance DI water.

(4) about 23.14 wt. % of a polymer binder as a viscosity modifier (poly(vinylalcohol-co-vinylamine)), about 0.15 wt. % of an oil-based defoamer (available as Rhodoline® 646), about 10 wt. % of a humectant (D-sorbitol), about 5 wt. % of an electrical conductivity modifying agent (triethylenetetramine), and balance DI water.

(5) about 21.25 wt. % of a polymer binder as a viscosity modifier (poly(vinylalcohol-co-vinylamine)), about 0.15 wt. % of an oil-based defoamer (available as Rhodoline® 646), about 0.1 wt. % of a non-ionic fluorosurfactant (available as Capstone® FS-35), about 5 wt. % of an electrical conductivity modifying agent (bis(hexamethylene)triamine), and balance DI water.

### Example 11

A series of percolation-inhibition compositions are prepared and are composed of about 5 wt. % sodium thiocyanate, and 0 wt. %, about 0.1 wt. %, about 0.5 wt. %, about 1 wt. %, about 5 wt. %, and about 10 wt. % ascorbic acid each in DI water. Each composition is pipetted into a separate vial, and the vials are capped. The capped vials are then placed in an oven at about 80° C. for about 45 minutes to equilibrate. The vials are removed from the oven. An about 1″×1″ square of film composed of silver nanowires embedded into a PMMA top layer on a PET bottom layer is placed into each vial. The film-containing vials are then incubated for about 60 minutes at about 80° C. in an oven. The films are then removed from the vials, rinsed with DI water, and dried prior to measurement and characterization.

All compositions, including the control sample with 0 wt. % ascorbic acid, show sheet resistance increase from about 100 OPS prior to treatment to over about 800,000 OPS after treatment with the percolation-inhibition composition for points as measured by an automated 4-point probe sheet resistance mapping tool.

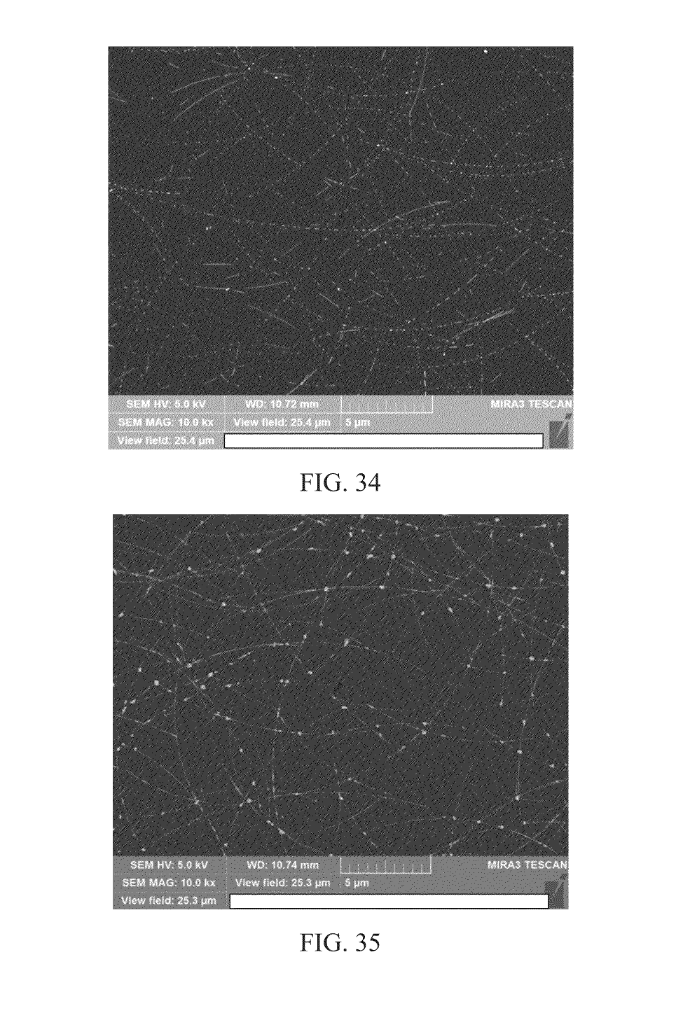

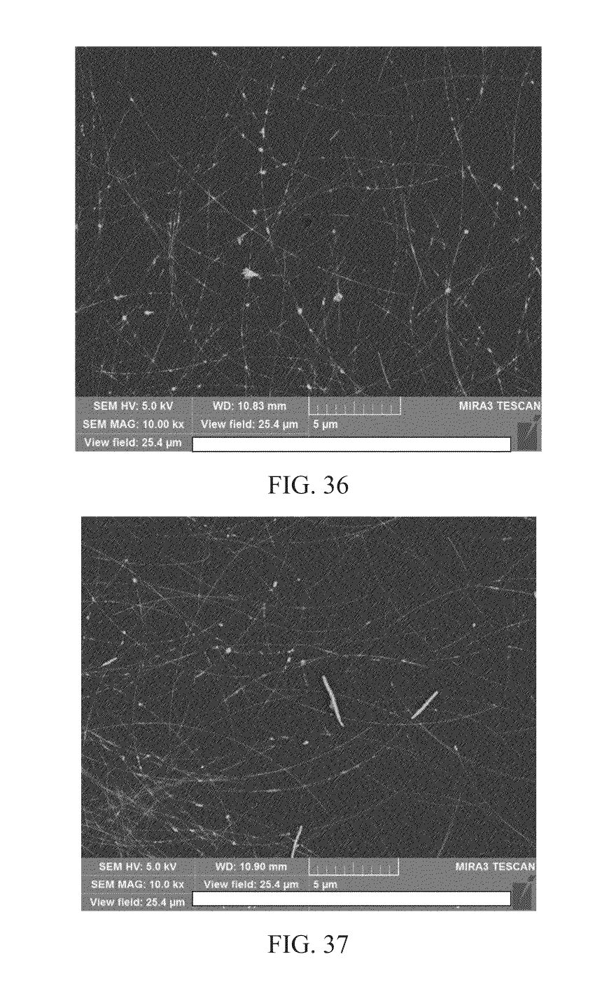

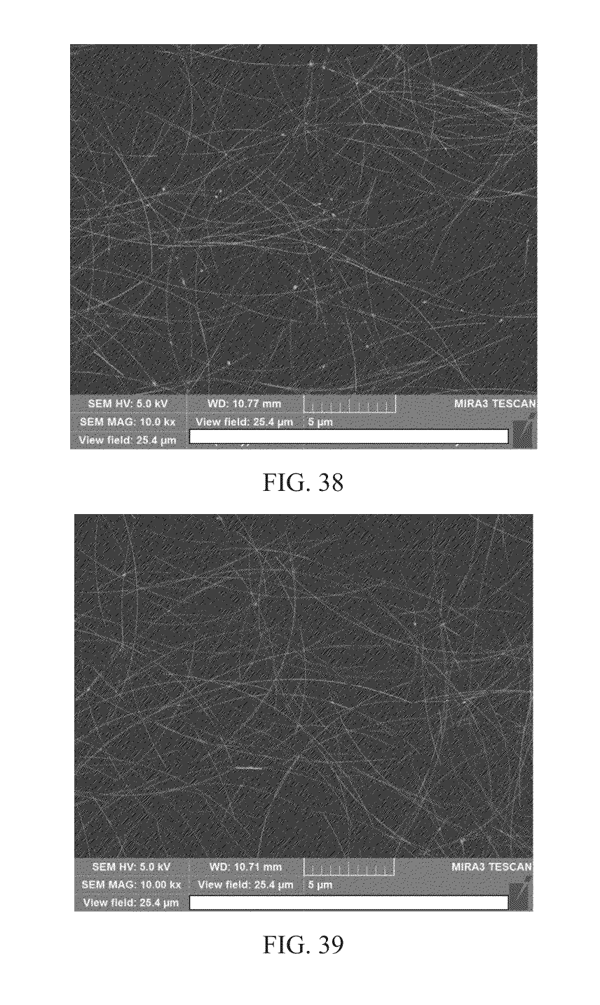

Optical and scanning electron microscopy analysis of the treated films show the following observations:

| Ascorbic Acid wt. % | Microscopy Observation |
|---|---|
| 0 | Chopping of silver nanowires without |
| | observable re-deposition of silver, significant |
| | loss of silver from surface (see FIG. 34) |
| 0.1 | Fewer chops of silver nanowires and |
| | increased re-deposition of silver versus 0 |
| | wt. % ascorbic acid composition (see FIG. 35) |
| 0.5 | Fewer chops of silver nanowires and |
| | increased re-deposition of silver versus 0.1 |
| | wt. % ascorbic acid composition (see FIG. 36) |
| 1 | Fewer chops of silver nanowires and |
| | increased re-deposition of silver versus 0.5 |
| | wt. % ascorbic acid composition (see FIG. 37) |
| 5 | Fewer chops of silver nanowires and |
| | increased re-deposition of silver versus 1 |
| | wt. % ascorbic acid composition (see FIG. 38) |
| 10 | Chopping is barely visible, most closely |
| | resembles untreated film (see FIG. 39) |

### Example 12

A percolation-inhibition composition composed of about 5 wt. % bis(hexamethylene)triamine, about 0.1 wt. % silver nitrate, and DI water is pipetted into a vial and equilibrated at room temperature. An about 1″×1″ square of film composed of silver nanowires embedded into a PMMA top layer on a PET bottom layer is then placed into the vial. The vial is incubated at about 80° C. for about 60 minutes in an oven prior to removal from the oven. The film is then removed from the vial, rinsed with DI water, dried, measured, and analyzed. The film sheet resistance is increased, and silver re-deposition on the film can be increased versus a control sample without silver nitrate.

### Example 13

A percolation-inhibition composition composed of about 100 wt. % bis(hexamethylene)triamine is placed on a film composed of silver nanowires embedded into a PMMA top layer on a PET bottom layer. The bis(hexamethylene)triamine powder is sprinkled and spread onto a portion of the film surface. The film is then placed in an oven at about 80° C. for about 60 minutes. The bis(hexamethylene)triamine is observed to melt. After removal from the oven, the film is washed in DI water to remove excess bis(hexamethylene)triamine. Optical microscopy and sheet resistance measurement demonstrate that the sheet resistance of the treated film portion (and nearby portions due to volatility of bis(hexamethylene)triamine) is increased significantly, and silver nanowires are chopped. Some silver appeared to be re-deposited as nanoparticles on the film.

A practitioner of ordinary skill in the art may find some helpful guidance in implementing certain embodiments in U.S. patent application Ser. No. 13/594,758, filed on Aug. 24, 2012 (published as US 2013/0056244 on Mar. 7, 2013), the disclosure of which is incorporated herein by reference in its entirety.

While this disclosure has been described with reference to the specific embodiments thereof, it should be understood by those skilled in the art that various changes may be made and equivalents may be substituted without departing from the true spirit and scope of this disclosure as defined by the appended claims. In addition, many modifications may be made to adapt a particular situation, material, composition of matter, method, or process to the objective, spirit and scope of this disclosure. All such modifications are intended to be within the scope of the claims appended hereto. In particular, while the methods disclosed herein have been described with reference to particular operations performed in a particular order, it will be understood that these operations may be combined, sub-divided, or re-ordered to form an equivalent method without departing from the teachings of this disclosure. Accordingly, unless specifically indicated herein, the order and grouping of the operations are not limitations of this disclosure.

What is claimed is:

1. A manufacturing method of a patterned transparent conductor, comprising:
providing a transparent conductor including nanowires formed of a metal; and
applying a percolation-inhibition composition to a portion of the transparent conductor to partially degrade nanowires included in the portion,
wherein the percolation-inhibition composition includes a complexing agent for the metal.

2. The manufacturing method of claim 1, wherein applying the percolation-inhibition composition includes printing the percolation-inhibition composition over the transparent conductor.

3. The manufacturing method of claim 2, wherein printing the percolation-inhibition composition is via screen printing, gravure printing, or ink-jet printing.

4. The manufacturing method of claim 1, wherein applying the percolation-inhibition composition includes applying a mask over the transparent conductor, and applying the percolation-inhibition composition to the portion through an opening in the mask.

5. The manufacturing method of claim 1, wherein at least one nanowire included in the portion is severed at one or more locations along a length of the nanowire.

6. The manufacturing method of claim 1, wherein the complexing agent is an amine or a polyamine.

7. The manufacturing method of claim 1, wherein the complexing agent is selected from ammonia, bis(hexamethylene)triamine, ethylenediamine, diethylenetriamine, octylamine, decylamine, triethylenetetraamine, N-methylethylenediamine, N,N′-dimethylethylenediamine, N,N,N′-trimethylethylenediamine, N,N′-diisopropylethylenediamine, tetraethylpentaamine, polyethylenimine, lysine, ethanolamine hydrochloride, hydantoin, and thiourea.

8. The manufacturing method of claim 1, wherein the complexing agent is an aminated polymer.

9. The manufacturing method of claim 1, wherein the complexing agent is selected from halides, sulfides, thiocyanates, polysulfides, and thiosulfates.

10. The manufacturing method of claim 1, wherein the percolation-inhibition composition further includes a reducing agent for the metal.

11. The manufacturing method of claim 1, further comprising activating the percolation-inhibition composition by thermal treatment.

12. A percolation-inhibition composition for application to conductive structures formed of a metal, comprising:
a complexing agent for the metal;
a polymer binder; and
a solvent,
wherein the complexing agent has the formula: 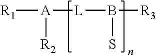
where R₁, R₂, R₃, and S are independently selected from hydride groups, alkyl groups, alkenyl groups, alkynyl groups, aryl groups, poly(alkylene oxide) groups, siloxane groups, and polysiloxane groups, L is selected from alkylene groups, alkenylene groups, alkynylene groups, arylene groups, poly(alkylene oxide) groups, siloxane groups, and polysiloxane groups, A and B are independently selected from nitrogen, phosphorus, arsenic, antimony, and bismuth, and n is an integer≧0, and
where for n>1:
L in different ones of the n units can be the same or different, and are independently selected from alkylene groups, alkenylene groups, alkynylene groups, arylene groups, poly(alkylene oxide) groups, siloxane groups, and polysiloxane groups,
S in different ones of the n units can be the same or different, and are independently selected from hydride groups, alkyl groups, alkenyl groups, alkynyl groups, aryl groups, poly(alkylene oxide) groups, siloxane groups, and polysiloxane groups, and
B in different ones of the n units can be the same or different, and are independently selected from nitrogen, phosphorus, arsenic, antimony, and bismuth.

13. The percolation-inhibition composition of claim 12, wherein at least one of A and B is nitrogen.

14. The percolation-inhibition composition of claim 12, wherein the complexing agent is selected from ammonia, bis(hexamethylene)triamine, ethylenediamine, diethylenetriamine, octylamine, decylamine, triethylenetetraamine, N-methylethylenediamine, N,N′-dimethylethylenediamine, N,N,N′-trimethylethylenediamine, N,N′-diisopropylethylenediamine, tetraethylpentaamine, and polyethylenimine.

15. The percolation-inhibition composition of claim 12, wherein the complexing agent has a boiling point of at least 100° C.

16. The percolation-inhibition composition of claim 12, wherein the solvent is water, and the polymer binder is a water-soluble polymer binder.

17. The percolation-inhibition composition of claim 12, wherein the percolation-inhibition composition is devoid of an oxidizing agent for the metal.

18. A percolation-inhibition composition for application to conductive structures formed of a metal, comprising:
a complexing agent for the metal;
a reducing agent for the metal;
a polymer binder; and
a solvent.

19. The percolation-inhibition composition of claim 18, wherein the complexing agent is selected from halides, sulfides, thiocyanates, and polysulfides.

20. The percolation-inhibition composition of claim 18, wherein the reducing agent is selected from sodium borohydride, citrates, amines, polyamines, and alcohols.

21. The percolation-inhibition composition of claim 18, wherein the solvent is water, and the polymer binder is a water-soluble polymer binder.

22. The percolation-inhibition composition of claim 18, further comprising at least one of a surfactant, a humectant, and a solid filler.

23. A patterned transparent conductor comprising:
a substrate;
first conductive structures disposed within a first area of the substrate corresponding to a lower conductance portion; and
second conductive structures disposed within a second area of the substrate corresponding to a higher conductance portion,
wherein a sheet resistance of the lower conductance portion is at least 100 times a sheet resistance of the higher conductance portion, and
wherein a surface area coverage of the first conductive structures in the lower conductance portion is less than and is at least 20% of a surface area coverage of the second conductive structures in the higher conductance portion.

24. The patterned transparent conductor of claim 23, wherein the surface area coverage of the first conductive structures in the lower conductance portion is at least 30% of the surface area coverage of the second conductive structures in the higher conductance portion.

25. The patterned transparent conductor of claim 23, wherein the first conductive structures include first metallic nanowires, the second conductive structures include second metallic nanowires, and an average length of the first metallic nanowires is less than an average length of the second metallic nanowires.

26. The patterned transparent conductor of claim 25, wherein the average length of the first metallic nanowires is at least 1/100 of the average length of the second metallic nanowires.

27. The patterned transparent conductor of claim 23, wherein a percentage by number of nanoparticles among the first conductive structures in the lower conductance portion is greater than a percentage by number of nanoparticles among the second conductive structures in the higher conductance portion.

28. The patterned transparent conductor of claim 23, wherein a difference in haze values of the higher conductance portion and the lower conductance portion is no greater than 0.4%, with respect to a wavelength of 550 nm.
